(19) United States
(12) Patent Application Publication
(10) Pub. No.: US 2025/0024737 A1
(43) Pub. Date: Jan. 16, 2025

(54) ELECTRONIC DEVICE

(71) Applicant: Semiconductor Energy Laboratory Co., Ltd., Atsugi-shi, Kanagawa-ken (JP)

(72) Inventors: Ryo HATSUMI, Hadano (JP); Hisao IKEDA, Zama (JP); Daiki NAKAMURA, Atsugi (JP); Takeya HIROSE, Atsugi (JP); Yosuke TSUKAMOTO, Atsugi (JP)

(21) Appl. No.: 18/712,749

(22) PCT Filed: Dec. 9, 2022
(86) PCT No.: PCT/IB2022/061953

§ 371 Date: May 23, 2024

(30) Foreign Application Priority Data
Dec. 17, 2021 (JP) 2021-205374

(51) Int. Cl. H10K 59/80; G02B 27/01; G09G 3/3275; H10K 59/65

(52) U.S. Cl. CPC H10K 59/878; G02B 27/0172; G09G 3/3275; H10K 59/65; H10K 59/879

(57) ABSTRACT

An electronic device with low power consumption is provided. The electronic device includes a first pixel portion and a second pixel portion. A plurality of first pixels are arranged in the first pixel portion. The second pixel portion includes a first region where a plurality of second pixels are arranged and a second region where a plurality of third pixels are arranged. The second region is provided to surround the first region. The first pixel includes a first light-emitting element, the second pixel includes a light-receiving element, and the third pixel includes a second light-emitting element. The area occupied by one of the first pixels is smaller than the area occupied by one of the third pixels.

### TECHNICAL FIELD

One embodiment of the present invention relates to an electronic device. One embodiment of the present invention relates to a wearable electronic device including a display device.

Note that one embodiment of the present invention is not limited to the above technical field. Examples of a technical field of one embodiment of the present invention disclosed in this specification and the like include a semiconductor device, a display device, a light-emitting apparatus, a power storage device, a memory device, an electronic device, a lighting device, an input device, an input/output device, a driving method thereof, and a manufacturing method thereof.

### BACKGROUND ART

In recent years, HMD (Head Mounted Display)-type electronic devices suitable for applications such as virtual reality (VR) and augmented reality (AR) have been widely used. HMDs are capable of displaying an image showing 360-degree view of the user's surroundings in accordance with the motion of the user's head or the user's gaze or operation; thus, the user can have a high sense of immersion and a high realistic sensation.

A display device included in an HMD has a structure in which an image enlarged through lenses is viewed, for example. In this case, the size of a housing is liable to increase because of the presence of the lenses or the user is liable to easily see pixels and strongly sense graininess; hence, the display device is required to have high resolution and a smaller size. For example, Patent Document 1 discloses an HMD in which minute pixels are achieved using transistors capable of high-speed driving.

An HMD having a variety of functions as well as an image display function has been developed. For example, an HMD having a gaze tracking (eye tracking) function has been developed. In addition, an HMD having a function of detecting a user's health condition such as a fatigue level has been developed. For example, Patent Document 2 discloses an HMD that performs gaze tracking by irradiating a user's cornea with infrared light from an infrared light source and detecting the reflected infrared light.

### REFERENCES

### Patent Documents

[Patent Document 1] Japanese Published Patent Application No. 2000-2856
[Patent Document 2] Japanese Translation of PCT International Application No. 2019-512726

### SUMMARY OF THE INVENTION

### Problems to be Solved by the Invention

As a display device has higher resolution, the number of pixels per unit area provided in a pixel portion increases. Thus, high-speed driving is required to ensure a frame frequency, for example. In addition, the capacity of image data representing an image displayed on the pixel portion is increased. Accordingly, the power consumption of an electronic device including the display device is increased.

A gaze tracking function, a function of detecting a user's health condition such as a fatigue level, or the like can be achieved by providing an optical sensor in the electronic device, for example. However, when the optical sensor is provided outside the pixel portion, the size of the electronic device is increased in some cases.

An object of one embodiment of the present invention is to provide an electronic device with low power consumption. Another object of one embodiment of the present invention is to provide a small electronic device. Another object of one embodiment of the present invention is to provide an electronic device capable of displaying an image that appears in high resolution. Another object of one embodiment of the present invention is to provide a multifunctional electronic device. Another object of one embodiment of the present invention is to provide an electronic device capable of performing detection with high accuracy. Another object of one embodiment of the present invention is to provide a highly reliable electronic device. Another object of one embodiment of the present invention is to provide a novel electronic device.

Note that the description of these objects does not preclude the existence of other objects. Note that one embodiment of the present invention does not need to achieve all the objects. Note that objects other than these can be derived from the descriptions of the specification, the drawings, the claims, and the like.

### Means for Solving the Problems

One embodiment of the present invention is an electronic device including a first pixel portion and a second pixel portion; a plurality of first pixels are arranged in the first pixel portion; the second pixel portion includes a first region where a plurality of second pixels are arranged and a second region where a plurality of third pixels are arranged; the second region is provided to surround the first region; the first pixel includes a first light-emitting element; the second pixel includes a light-receiving element; the third pixel includes a second light-emitting element; and an area occupied by one of the first pixels is smaller than an area occupied by one of the third pixels.

Alternatively, in the above embodiment, the electronic device may include an optical combiner, and the optical combiner may have a function of reflecting light emitted from the first light-emitting element and transmitting light emitted from the second light-emitting element.

Alternatively, in the above embodiment, the optical combiner may be a half mirror.

Alternatively, in the above embodiment, the electronic device may include a first lens and a second lens; the first lens may be provided between the first region and the optical combiner; and the second lens may be provided at a position facing the second pixel portion with the optical combiner therebetween so as to include regions overlapping with the first region and the second region.

Alternatively, in the above embodiment, the second region may include a region not overlapping with the first lens.

Alternatively, in the above embodiment, the electronic device may include a communication circuit, a control circuit, a first source driver circuit, and a second source driver circuit; the first source driver circuit may be electrically connected to the first pixel; the second source driver circuit may be electrically connected to the third pixel; the communication circuit may have a function of receiving image data; and the control circuit may have a function of generating first data representing luminance of the light emitted from the first light-emitting element and second data representing luminance of the light emitted from the second light-emitting element on the basis of the image data and supplying the first data to the first source driver circuit and the second data to the second source driver circuit.

Alternatively, in the above embodiment, the electronic device may include a column driver circuit; the column driver circuit may have a function of reading imaging data obtained by the light-receiving element; and the control circuit may have a function of generating at least one of the first data and the second data on the basis of the imaging data in addition to the image data.

Alternatively, in the above embodiment, the first light-emitting element may include a first pixel electrode and a first EL layer over the first pixel electrode; the first EL layer may cover an end portion of the first pixel electrode; the second light-emitting element may include a second pixel electrode and a second EL layer over the second pixel electrode; and an insulating layer covering an end portion of the second pixel electrode may be provided between the second pixel electrode and the second EL layer.

Alternatively, in the above embodiment, the light-receiving element may include a third pixel electrode and a PD layer over the third pixel electrode, and the insulating layer covering an end portion of the third pixel electrode may be provided between the third pixel electrode and the PD layer.

Alternatively, in the above embodiment, the second pixel may include a third light-emitting element, and the third light-emitting element may have a function of emitting infrared light.

Alternatively, one embodiment of the present invention is an electronic device including a first pixel portion and a second pixel portion; a plurality of first pixels are arranged in the first pixel portion; the second pixel portion includes a first region where a plurality of second pixels are arranged and a second region where a plurality of third pixels are arranged; the second region is provided to surround the first region; the first pixel includes a first light-emitting element; the second pixel includes a second light-emitting element having a function of emitting infrared light; the third pixel includes a third light-emitting element and a first light-receiving element; and an area occupied by one of the first pixels is smaller than an area occupied by one of the third pixels.

Alternatively, in the above embodiment, the electronic device may include an optical combiner, and the optical combiner may have a function of reflecting light emitted from the first light-emitting element and transmitting light emitted from the second light-emitting element and light emitted from the third light-emitting element.

Alternatively, in the above embodiment, the optical combiner may be a half mirror.

Alternatively, in the above embodiment, the electronic device may include a communication circuit, a control circuit, a first source driver circuit, and a second source driver circuit; the first source driver circuit may be electrically connected to the first pixel; the second source driver circuit may be electrically connected to the third pixel; the communication circuit may have a function of receiving image data; the control circuit may have a function of generating first data representing luminance of the light emitted from the first light-emitting element, second data representing luminance of the light emitted from the second light-emitting element, and third data representing luminance of the light emitted from the third light-emitting element; the first data and the third data may be generated on the basis of the image data; and the control circuit may have a function of supplying the first data to the first source driver circuit and the second data and the third data to the second source driver circuit.

Alternatively, in the above embodiment, the electronic device may include a column driver circuit; the column driver circuit may have a function of reading imaging data obtained by the first light-receiving element; and the control circuit may have a function of generating at least one of the first data and the third data on the basis of the imaging data in addition to the image data.

Alternatively, in the above embodiment, the first light-emitting element may include a first pixel electrode and a first EL layer over the first pixel electrode; the first EL layer may cover an end portion of the first pixel electrode; the second light-emitting element may include a second pixel electrode and a second EL layer over the second pixel electrode; the third light-emitting element may include a third pixel electrode and a third EL layer over the third pixel electrode; and an insulating layer covering an end portion of the second pixel electrode and an end portion of the third pixel electrode may be provided between the second pixel electrode and the second EL layer and between the third pixel electrode and the third EL layer.

Alternatively, in the above embodiment, the first light-receiving element may include a fourth pixel electrode and a PD layer over the fourth pixel electrode, and the insulating layer covering an end portion of the fourth pixel electrode may be provided between the fourth pixel electrode and the PD layer.

Alternatively, in the above embodiment, the second pixel may include a second light-receiving element.

### Effect of the Invention

According to one embodiment of the present invention, an electronic device with low power consumption can be provided. According to another embodiment of the present invention, a small electronic device can be provided. According to another embodiment of the present invention, an electronic device capable of displaying an image that appears in high resolution can be provided. According to another embodiment of the present invention, a multifunctional electronic device can be provided. According to another embodiment of the present invention, an electronic device capable of performing detection with high accuracy can be provided. According to another embodiment of the present invention, a highly reliable electronic device can be provided. According to another embodiment of the present invention, a novel electronic device can be provided.

Note that the description of these effects does not preclude the presence of other effects. Note that one embodiment of the present invention does not need to have all the effects. Note that effects other than these can be derived from the descriptions of the specification, the drawings, the claims, and the like.

### BRIEF DESCRIPTION OF THE DRAWINGS

FIG. 1A is a perspective view illustrating a structure example of an electronic device. FIG. 1B1 and FIG. 1B2 are schematic views illustrating examples of an optical system.

FIG. 2A and FIG. 2B are block diagrams each illustrating a structure example of a display device.

FIG. 3A1 to FIG. 3A3, FIG. 3B1 to FIG. 3B6, and FIG. 3C1 to FIG. 3C4 are plan views illustrating structure examples of pixels.

FIG. 4A is a schematic view illustrating an example of an optical system. FIG. 4B is a perspective view illustrating a structure example of a display device.

FIG. 5 is a schematic view illustrating an example of an optical system.

FIG. 6 is a block diagram illustrating a structure example of an electronic device.

FIG. 7A to FIG. 7C are cross-sectional views illustrating structure examples of a display device.

FIG. 8A to FIG. 8C are cross-sectional views illustrating structure examples of a display device.

FIG. 9A to FIG. 9D are cross-sectional views illustrating structure examples of a display device.

FIG. 10A to FIG. 10D are cross-sectional views illustrating an example of a method for fabricating a display device.

FIG. 11A to FIG. 11F are cross-sectional views illustrating an example of a method for fabricating a display device.

FIG. 12A to FIG. 12C are cross-sectional views illustrating an example of a method for fabricating a display device.

FIG. 13A to FIG. 13C are cross-sectional views illustrating an example of a method for fabricating a display device.

FIG. 14A and FIG. 14B are cross-sectional views illustrating an example of the method for fabricating a display device.

FIG. 15A to FIG. 15G are plan views illustrating structure examples of pixels.

FIG. 16A to FIG. 16I are plan views illustrating structure examples of a pixel.

FIG. 17A to FIG. 171 are plan views illustrating structure examples of a pixel.

FIG. 18A to FIG. 18K are plan views illustrating structure examples of a pixel.

FIG. 19A and FIG. 19B are perspective views illustrating a structure example of a display module.

FIG. 20A and FIG. 20B are cross-sectional views illustrating structure examples of display devices.

FIG. 21 is a cross-sectional view illustrating a structure example of a display device.

FIG. 22 is a cross-sectional view illustrating a structure example of a display device FIG. 23 is a cross-sectional view illustrating a structure example of a display device FIG. 24 is a cross-sectional view illustrating a structure example of a display device.

FIG. 25 is a cross-sectional view illustrating a structure example of a display device.

FIG. 26 is a perspective view illustrating a structure example of a display device.

FIG. 27A is a cross-sectional view illustrating a structure example of a display device. FIG. 27B and FIG. 27C are cross-sectional views illustrating structure examples of transistors.

FIG. 28 is a cross-sectional view illustrating a structure example of a display device.

FIG. 29 is a cross-sectional view illustrating a structure example of a display device.

FIG. 30 is a cross-sectional view illustrating a structure example of a display device.

FIG. 31A to FIG. 31F are cross-sectional views illustrating structure examples of a light-emitting element.

FIG. 32A to FIG. 32C are cross-sectional views illustrating structure examples of a light-emitting element.

### MODE FOR CARRYING OUT THE INVENTION

Embodiments are described below with reference to the drawings. However, the embodiments can be implemented with various modes, and it will be readily appreciated by those skilled in the art that modes and details can be changed in various ways without departing from the spirit and scope of the present invention. Therefore, the present invention should not be construed as being limited to the description of embodiments below.

Note that in structures of the invention described below, the same portions or portions having similar functions are denoted by the same reference numerals in different drawings, and the description thereof is not repeated. Furthermore, the same hatch pattern is used for the portions having similar functions, and the portions are not especially denoted by reference numerals in some cases.

The position, size, range, and the like of each component illustrated in drawings do not represent the actual position, size, range, and the like in some cases for easy understanding. Therefore, the disclosed invention is not necessarily limited to the position, size, range, and the like disclosed in drawings.

Note that the term “film” and the term “layer” can be interchanged with each other depending on the case or circumstances. For example, the term “conductive layer” can be changed into the term “conductive film” in some cases. For another example, the term “insulating film” can be changed into the term “insulating layer” in some cases.

In this specification and the like, terms for describing positioning, such as “over,” “under,” “above,” and “below,” are sometimes used for convenience to describe the positional relation between components with reference to drawings. The positional relation between components is changed as appropriate in accordance with a direction in which each component is described. Thus, the positional relation is not limited to the terms described in this specification and the like, and can be described with another term as appropriate depending on the situation. For example, the expression “an insulating layer positioned over a conductive layer” can be replaced with the expression “an insulating layer positioned under a conductive layer” when the direction of a drawing illustrating these components is rotated by 180°.

Furthermore, unless otherwise specified, an off-state current in this specification and the like refers to a drain current of a transistor in an off state (also referred to as a non-conduction state or a cutoff state). Unless otherwise specified, an off state refers to, in an n-channel transistor, a state where a voltage V_{gs} between its gate and source is lower than a threshold voltage Vₜₕ (in a p-channel transistor, higher than Vₜₕ).

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is used in an active layer of a transistor, the metal oxide is referred to as an oxide semiconductor in some cases. That is, in this specification and the like, an “OS transistor” can also be referred to as a transistor including an oxide or an oxide semiconductor.

### Embodiment 1

In this embodiment, an electronic device, a display device, and the like of one embodiment of the present invention will be described. For example, one embodiment of the present invention can be suitably used for a wearable electronic device for VR or AR applications, specifically, an HMD.

The electronic device of one embodiment of the present invention includes a first display device and a second display device. The first display device and the second display device each include a pixel portion, and pixels are arranged in a matrix in the pixel portion. The pixels each include a light-emitting element (also referred to as a light-emitting device) that emits visible light, and when the light-emitting element emits light with a luminance corresponding to image data, an image can be displayed on the pixel portion.

In this specification and the like, visible light refers to light having a wavelength greater than or equal to 380 nm and less than 780 nm. In addition, infrared light refers to light having a wavelength greater than or equal to 780 nm. Furthermore, near-infrared light refers to light having a wavelength greater than or equal to 780 nm and less than or equal to 2500 nm. The expression “the light-emitting element emits visible light, infrared light, and near-infrared light” means that the peak wavelengths of light emitted from the light-emitting element are in the ranges of visible light, infrared light, and near-infrared light, respectively.

In this specification and the like, the light-emitting element includes an EL layer between a pair of electrodes. The EL layer includes at least a light-emitting layer. Here, examples of a layer included in the EL layer (also referred to as a functional layer) include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer).

The first display device displays a first image seen in the center and the vicinity of the center of a visual field of a user of the electronic device and the second display device displays a second image around the first image, for example. Here, humans minutely determine images in the centers and the vicinities of the centers of their visual fields and roughly determine images on the outer side. For example, humans minutely determine images in their central visual fields and effective visual fields and roughly determine images in their peripheral visual fields. Thus, even when the resolution of the second image is made lower than the resolution of the first image, the user of the electronic device hardly feels a decrease in image quality, e.g., the user hardly feels graininess. Meanwhile, when the resolution of the second image is lowered, the capacity of image data can be reduced, for example; thus, the driving speed of the second display device can be low while the frame frequency is ensured. Accordingly, the electronic device of one embodiment of the present invention can reduce the power consumption without making the user feel a decrease in image quality as compared with the case where the resolution of the whole image displayed on the electronic device is made uniform.

Here, in the case where the first display device displays the first image seen in the center and the vicinity of the center of the visual field of the user of the electronic device, for example, the second display device does not need to display an image at a position overlapping with the first image. That is, for example, it is not necessary to display an image in the center and the vicinity of the center of a pixel portion included in the second display device. Thus, light-emitting elements that emit visible light are not necessarily provided in pixels provided in the center and the vicinity of the center of the pixel portion included in the second display device.

Therefore, in the electronic device of one embodiment of the present invention, light-receiving elements (also referred to as light-receiving devices or optical sensors) are provided in the pixels provided in the center and the vicinity of the center of the pixel portion included in the second display device. This enables detection of a pupil of the user of the electronic device, for example; thus, the electronic device can perform gaze tracking. For example, the electronic device can detect user's blinks and thus can detect a user's health condition such as a fatigue level. Accordingly, the electronic device of one embodiment of the present invention can be a multifunctional electronic device.

In the electronic device of one embodiment of the present invention, an optical sensor is provided in the pixel portion. In this case, the electronic device can be smaller than in the case where the optical sensor is provided outside the pixel portion. Accordingly, the electronic device of one embodiment of the present invention can be a multifunctional and small electronic device.

### <Structure Example of Electronic Device>

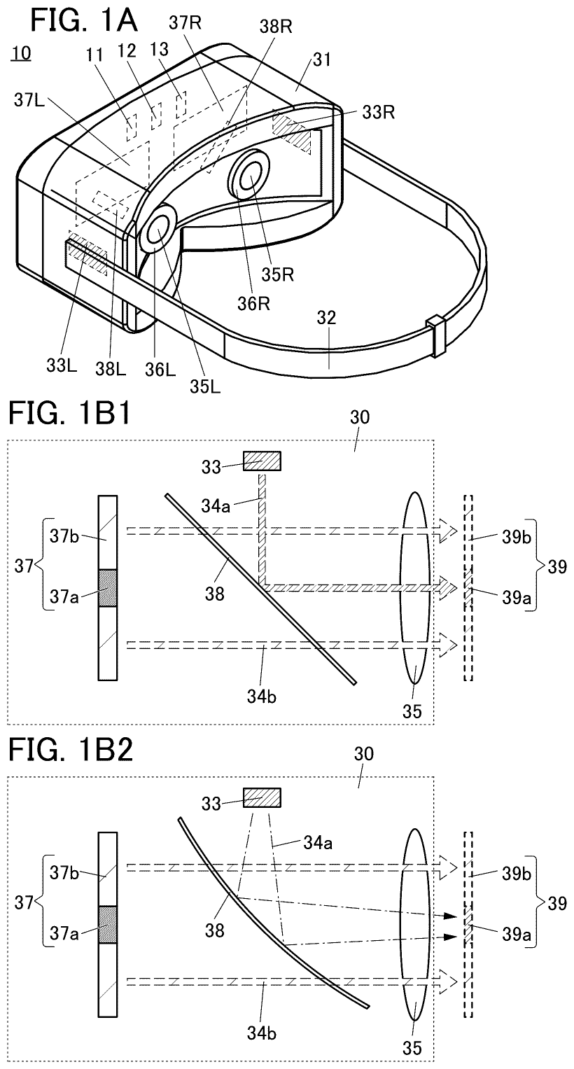

FIG. 1A is an external view illustrating a structure example of an electronic device 10 that is an electronic device of one embodiment of the present invention. The electronic device 10 can be an HMD. Alternatively, the electronic device 10 can be called a goggles-type electronic device. Alternatively, the electronic device 10 is called a glasses-type electronic device in some cases.

The electronic device 10 includes a housing 31, a pair of pixel portions 33 (a pixel portion 33L and a pixel portion 33R), a fixing member 32, a pair of lenses 35 (a lens 35L and a lens 35R), a pair of frames 36 (a frame 36L and a frame 36R), a pair of pixel portions 37 (a pixel portion 37L and a pixel portion 37R), and a pair of half mirrors 38 (a half mirror 38L and a half mirror 38R). The electronic device 10 can include a communication circuit 11, a detection circuit 12, and a control circuit 13.

FIG. 1B1 is a schematic view illustrating a structure example of an optical system 30 included in the electronic device 10. The optical system 30 includes the pixel portion 33, the pixel portion 37, the half mirror 38, and the lens 35. The lens 35 and the pixel portion 37 are provided to face each other with the half mirror 38 therebetween. The lens 35 is provided to include a region overlapping with the pixel portion 37. Here, the electronic device 10 can include the optical system 30 including the pixel portion 33L, the pixel portion 37L, the half mirror 38L, and the lens 35L and the optical system 30 including the pixel portion 33R, the pixel portion 37R, the half mirror 38R, and the lens 35R. That is, the electronic device 10 can have a structure including the two optical systems 30.

The pixel portion 33 can display an image by emitting light 34a. The pixel portion 37 can display an image by emitting light 34b. The light 34a reflected by the half mirror 38 is projected to a projected surface 39a through the lens 35. The light 34b transmitted through the half mirror 38 is projected to a projected surface 39b through the lens 35. In the above manner, images displayed on the pixel portion 33 and the pixel portion 37 can be projected to the projected surface 39 (the projected surface 39a and the projected surface 39b).

Thus, it can be said that the half mirror 38 has a function of combining, on the projected surface 39, an image displayed on the pixel portion 33 and an image displayed on the pixel portion 37. Accordingly, it can be said that the half mirror 38 has a function of an optical combiner. Note that the optical system 30 may be provided with a member functioning as an optical combiner other than the half mirror 38. For example, a reflective polarizing plate may be provided instead of the half mirror 38.

In this specification and the like, an optical combiner refers to a member that combines images displayed on two or more pixel portions to make the images seen as one image.

The projected surface 39 can be an eye of a user of the electronic device 10. Note that when a reflective polarizing plate is provided instead of the half mirror 38, the reflectance of the light 34a by the optical combiner and the transmittance of the light 34b by the optical combiner can be increased in some cases.

The projected surface 39a to which the light 34a emitted from the pixel portion 33 is projected is provided in the center and the vicinity of the center of the projected surface 39. The projected surface 39b to which the light 34b emitted from the pixel portion 37 is projected is provided around the projected surface 39a. That is, an image projected to the center and the vicinity of the center of the projected surface 39 can be displayed on the pixel portion 33, and an image projected to the other portion of the projected surface 39 can be displayed on the pixel portion 37.

For example, in the case where the projected surface 39 is the eye of the user of the electronic device 10, the projected surface 39a can be the center and the vicinity of the center of the eye and the projected surface 39b can be a peripheral region. Thus, the user of the electronic device 10 can see an image displayed on the pixel portion 33 in the center and the vicinity of the center of the visual field and can see an image displayed on the pixel portion 37 in the peripheral visual field.

In the case where an image displayed on the pixel portion 33 is projected to the center and the vicinity of the center of the projected surface 39, when the pixel portion 37 displays an image in the center and the vicinity of the center, i.e., emits light, the light is mixed with the light 34a. Thus, the image displayed on the pixel portion 33 and the image displayed on the pixel portion 37 overlap with each other in the center and the vicinity of the center of the projected surface 39, leading to a decrease in image quality of an image seen by the user of the electronic device 10 in some cases, for example. Therefore, it is preferable that an image not be displayed in the center and the vicinity of the center of the pixel portion 37. In the following description, a region of the pixel portion 37 where an image is not displayed is referred to as a region 37a, and a region of the pixel portion 37 where an image is displayed is referred to as a region 37b.

In this specification and the like, the pixel portion 33 and the region 37b can also be referred to as a display portion.

Note that invisible light, e.g., infrared light, can be emitted from the region 37a. In this case, light emitted from the region 37a and transmitted through the half mirror 38 can be projected to the projected surface 39a.

The lens 35 has a function of refracting light entering the lens 35. Thus, images displayed on the pixel portion 33 and the pixel portion 37 can be enlarged and seen by the user of the electronic device 10, for example. Note that the refraction of the light 34a and the light 34b at the lens 35 is not illustrated in FIG. 1B1.

FIG. 1B2 illustrates a modification example of the optical system 30 illustrated in FIG. 1B1, in which the half mirror 38 has a curved surface shape. In FIG. 1B2, the light 34a emitted from the pixel portion 33 is indicated by dashed-dotted lines.

When the half mirror 38 has a curved surface shape, the half mirror 38 can have a function of a lens. Thus, an image displayed on the pixel portion 33 can be enlarged or downsized and seen by the user of the electronic device 10.

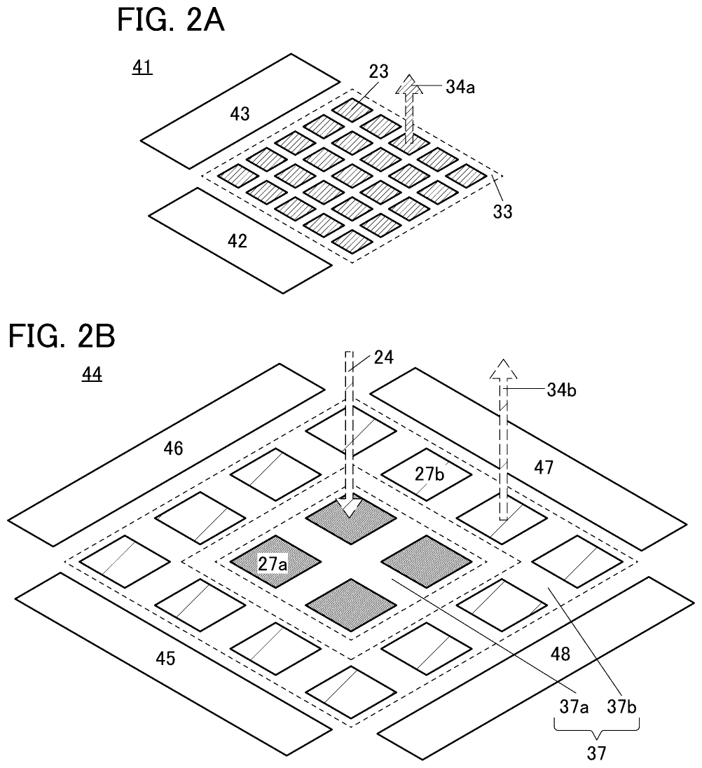

FIG. 2A is a block diagram illustrating a structure example of a display device 41 including the pixel portion 33. As illustrated in FIG. 2A, a plurality of pixels 23 are arranged, e.g., arranged in a matrix, in the pixel portion 33. The display device 41 includes a gate driver circuit 42 and a source driver circuit 43. Although not illustrated in FIG. 2A, the gate driver circuit 42 and the source driver circuit 43 are electrically connected to the pixels 23.

The pixel 23 includes a light-emitting element that emits visible light, and when light emitted from the light-emitting element is emitted from the pixel 23 as the light 34a, an image can be displayed on the pixel portion 33. As the light-emitting element, an OLED (Organic Light Emitting Diode) or a QLED (Quantum-dot Light Emitting Diode) is preferably used, for example. Examples of a light-emitting substance contained in the light-emitting element include a substance that emits fluorescent light (a fluorescent material), a substance that emits phosphorescent light (a phosphorescent material), a substance that exhibits thermally activated delayed fluorescence (a thermally activated delayed fluorescence (TADF) material), and an inorganic compound (e.g., a quantum dot material). An LED such as a micro-LED (Light Emitting Diode) can be used as the light-emitting element.

In the display device 41, the source driver circuit 43 can write image data to the pixel 23 selected by the gate driver circuit 42. When the image data is written to the pixel 23, the pixel 23 emits the light 34a with a luminance corresponding to the image data, so that an image can be displayed on the pixel portion 33.

FIG. 2B is a block diagram illustrating a structure example of a display device 44 including the pixel portion 37. As described above, the pixel portion 37 includes the region 37a where an image is not displayed and the region 37b where an image is displayed. The region 37a can be a region in the center and the vicinity of the center of the pixel portion 37, and the region 37b can be a region around the region 37a. That is, the region 37b is provided to surround the region 37a. Note that the center of the pixel portion 37 may be positioned not in the region 37a but in the region 37b.

In the electronic device of one embodiment of the present invention, a plurality of pixels 27a are arranged, e.g., arranged in a matrix, in the region 37a. In addition, a plurality of pixels 27b are arranged in the region 37b. The display device 44 includes a gate driver circuit 45, a source driver circuit 46, a row driver circuit 47, and a column driver circuit 48. Although not illustrated in FIG. 2B, for example, the gate driver circuit 45 and the source driver circuit 46 are electrically connected to the pixels 27b, and the row driver circuit 47 and the column driver circuit 48 are electrically connected to the pixels 27a.

The pixel 27a includes a light-receiving element and can detect light 24 entering the pixel 27a. The light-receiving element can be a photodiode (PD), for example. The light-receiving element includes an active layer functioning as a photoelectric conversion layer. For the active layer, an organic material can be used. Alternatively, for the active layer, an inorganic material such as silicon may be used.

Like the pixel 23, the pixel 27b includes a light-emitting element that emits visible light, and when light emitted from the light-emitting element is emitted from the pixel 27b as the light 34b, an image can be displayed on the region 37b.

Providing the light-receiving element in the pixel 27a enables the display device 44 to obtain imaging data including the eye of the user of the electronic device 10, for example. When the light-receiving element included in the pixel 27a detects the light 24, which is light reflected by the eye of the user of the electronic device 10, the display device 44 can obtain the imaging data including the eye of the user of the electronic device 10, for example. In this case, the light 24 can be light that enters and is reflected by the eye of the user of the electronic device 10 in the light 34b emitted from the pixel 27b, for example.

The electronic device 10 can detect a pupil of the user, for example, on the basis of the imaging data. Accordingly, the electronic device 10 can perform gaze tracking. Here, the gaze of the user of the electronic device 10 can be tracked by a pupil center corneal reflection method, a bright/dark pupil effect method, or the like. The electronic device 10 can detect user's blinks and detect a change over time in the user's blinks, for example. Thus, the electronic device 10 can detect a user's health condition such as a fatigue level. Note that the electronic device 10 may detect the user's health condition such as a fatigue level by detecting the pupil. For example, the health condition, such as a fatigue level, of the user of the electronic device 10 may be detected on the basis of the size of the pupil.

An image displayed on the pixel portion 33 and an image displayed on the region 37b can be made different on the basis of the imaging data. For example, an object such as a cursor displayed on the pixel portion 33 or the region 37b can be moved on the basis of the gaze tracking result. The luminance of the image displayed on the pixel portion 33 and the luminance of the image displayed on the region 37b can be made different on the basis of the fatigue level of the user of the electronic device 10, for example. In the case where it is determined that the user of the electronic device 10 feels fatigue, the luminance of the image displayed on the pixel portion 33 and the luminance of the image displayed on the region 37b can be lowered, for example.

Accordingly, when the light-receiving element is provided in the pixel 27a, the electronic device 10 can be a multifunctional electronic device. Since the light-receiving element is provided in the pixel portion 37, the electronic device 10 can be smaller than in the case where the light-receiving element is provided outside the pixel portion 33 and the pixel portion 37.

Here, as illustrated in FIG. 2A and FIG. 2B, the pixel density of the pixel portion 33 is preferably higher than the pixel density of the pixel portion 37. For example, the area occupied by one pixel 23 provided in the pixel portion 33 is preferably smaller than the area occupied by one pixel 27a or one pixel 27b provided in the pixel portion 37. The distance between adjacent pixels 23 is preferably less than each of the distance between adjacent pixels 27a, the distance between adjacent pixels 27b, and the distance between the pixel 27a and the pixel 27b adjacent to each other. As described above, the pixel portion 33 can display an image seen in the center and the vicinity of the center of the visual field of the user of the electronic device 10, and the region 37b in the pixel portion 37 can display an image seen in the peripheral visual field. Here, humans minutely determine images in the centers and the vicinities of the centers of their visual fields and roughly determine images on the outer side. For example, humans minutely determine images in their central visual fields and effective visual fields and roughly determine images in their peripheral visual fields. Thus, even when the pixel density of the pixel portion 37 is lower than the pixel density of the pixel portion 33 and the resolution of an image displayed on the region 37b is lower than the resolution of an image displayed on the pixel portion 33, the user of the electronic device 10 hardly feels a decrease in image quality, e.g., the user hardly feels graininess. Meanwhile, when the pixel density of the pixel portion 37 is lowered, the capacity of image data can be reduced, for example; thus, the driving speed of the display device 44 can be low while the frame frequency is ensured. Accordingly, the electronic device 10 can reduce the power consumption without making the user feel a decrease in image quality as compared with the case where the pixel density of the whole pixel portion is made uniform.

In the display device 44, the source driver circuit 46 can write image data to the pixel 27b selected by the gate driver circuit 45. When the image data is written to the pixel 27b, the pixel 27b emits the light 34b with a luminance corresponding to the image data, so that an image can be displayed on the pixel portion 37. In the display device 44, the imaging data retained in the pixel 27a selected by the row driver circuit 47 can be read by the column driver circuit 48.

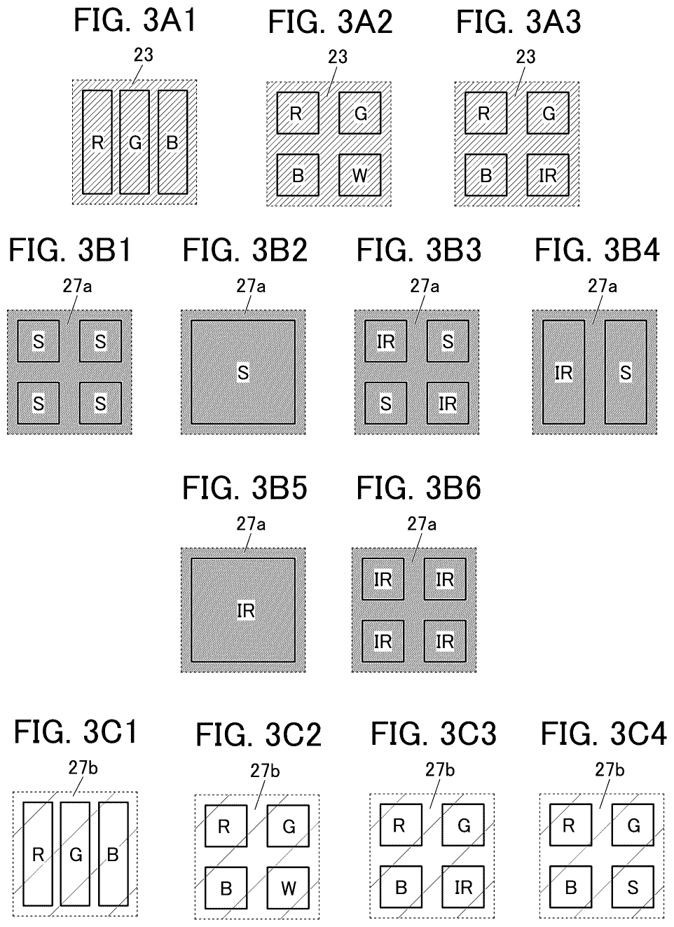

FIG. 3A1 to FIG. 3A3 are plan views illustrating structure examples of the pixel 23. FIG. 3A1 illustrates an example in which the pixel 23 includes a subpixel R that emits red light, a subpixel G that emits green light, and a subpixel B that emits blue light. The pixel 23 may include a subpixel that emits light of yellow, cyan, magenta, or the like. For example, the pixel 23 may include a subpixel that emits yellow light, a subpixel that emits cyan light, and a subpixel that emits magenta light.

Here, red light can be, for example, light with a peak wavelength greater than or equal to 630 nm and less than or equal to 780 nm. The green light can be, for example, light with a peak wavelength greater than or equal to 500 nm and less than 570 nm. Furthermore, blue light can be, for example, light with a peak wavelength greater than or equal to 450 nm and less than 480 nm.

FIG. 3A2 illustrates an example in which the pixel 23 includes a subpixel W that emits white light in addition to the subpixel R, the subpixel G, and the subpixel B. FIG. 3A3 illustrates an example in which the pixel 23 includes a subpixel IR that emits infrared light, specifically, near-infrared light in addition to the subpixel R, the subpixel G, and the subpixel B.

FIG. 3B1 to FIG. 3B6 are schematic views illustrating structure examples of the pixel 27a. FIG. 3B1 illustrates an example in which the pixel 27a includes four subpixels S each provided with a light-receiving element. FIG. 3B2 illustrates an example in which the pixel 27a includes one subpixel S.

As the number of subpixels S provided in one pixel 27a increases, the display device 44 can perform image capturing with higher definition. Meanwhile, when the number of subpixels S provided in one pixel 27a is small, the driving speed of the row driver circuit 47 and the column driver circuit 48 can be low, for example, while the amount of light to which the light-receiving element is exposed and the frame frequency are ensured. Thus, the power consumption of the electronic device 10 can be reduced.

FIG. 3B3 illustrates an example in which the pixel 27a includes two subpixels IR and two subpixels S. FIG. 3B4 illustrates an example in which the pixel 27a includes one subpixel IR and one subpixel S. FIG. 3B5 illustrates an example in which the pixel 27a includes one subpixel IR. FIG. 3B6 illustrates an example in which the pixel 27a includes four subpixels IR.

FIG. 3C1 to FIG. 3C4 are schematic views illustrating structure examples of the pixel 27b. The structures illustrated in FIG. 3C1, FIG. 3C2, and FIG. 3C3 are similar to the structures illustrated in FIG. 3A1, FIG. 3A2, and FIG. 3A3, respectively. FIG. 3C4 illustrates an example in which the pixel 27b includes the subpixel S in addition to the subpixel R, the subpixel G, and the subpixel B. Note that like the pixel 23, the pixel 27b may include a subpixel that emits light of yellow, cyan, or magenta.

In the case where the pixel 23, the pixel 27a, or the pixel 27b includes the subpixel IR, the subpixel S is provided with a light-receiving element having sensitivity to infrared light. Accordingly, the electronic device 10 can perform image capturing with infrared light and can detect infrared light emitted from the subpixel IR and reflected by the eye of the user of the electronic device 10, for example.

Here, the infrared light reflectance in the pupil included in the eye is lower than the infrared light reflectance in an iris around the pupil. The difference between the infrared light reflectance in the iris and the infrared light reflectance in the pupil is larger than the difference between the visible light reflectance in the iris and the visible light reflectance in the pupil. Accordingly, when the subpixel IR that emits infrared light is provided in the pixel 23, the pixel 27a, or the pixel 27b, the electronic device 10 can clearly distinguish the pupil from the iris, for example; thus, the pupil can be detected with high accuracy. Therefore, the electronic device 10 can perform gaze tracking with high accuracy, for example. Note that a light source that emits infrared light may be provided outside the pixel portion 33 and the pixel portion 37. That is, a light source that emits infrared light may be externally provided. In this case, the electronic device 10 can perform image capturing with infrared light even when the subpixels IR are not provided in the pixel 23, the pixel 27a, and the pixel 27b.

In the case where the pixel 27a includes the subpixel IR, the pixel 27a can be electrically connected to the gate driver circuit 45 and the source driver circuit 46 illustrated in FIG. 2B. In the case where the pixel 27b includes the subpixel S, the pixel 27b can be electrically connected to the row driver circuit 47 and the column driver circuit 48 illustrated in FIG. 2B.

In the case where the subpixel S is not provided in the pixel 27a as illustrated in FIG. 3B5 and FIG. 3B6, the pixel 27b is provided with the subpixel S as illustrated in FIG. 3C4, whereby the display device 44 can perform gaze tracking, detection of the user's health condition such as a fatigue level, or the like. When the subpixel S is not provided in the pixel 27a, the area occupied by the subpixel IR can be increased. As a result, the reliability of the light-emitting element provided in the subpixel IR can be improved. Note that in the case where the subpixel IR is provided in the pixel 27a, a structure may be employed in which the subpixel S is provided in neither the pixel 27a nor the pixel 27b. That is, for example, the pixel 27a may have the structure illustrated in FIG. 3B5 or FIG. 3B6 and the pixel 27b may have any of the structures illustrated in FIG. 3C1, FIG. 3C2, and FIG. 3C3. Even in this case, when an optical sensor is provided outside the pixel portion 33 and the pixel portion 37, i.e., an optical sensor is externally provided, the electronic device 10 can perform gaze tracking, detection of the user's health condition such as a fatigue level, or the like.

Although FIG. 3A1, FIG. 3B4, and FIG. 3C1 illustrate examples where the subpixels are arranged in a stripe pattern, the arrangement method of the subpixels is not limited thereto. Although FIG. 3A2, FIG. 3A3, FIG. 3B1, FIG. 3B3, FIG. 3B6, FIG. 3C2, FIG. 3C3, and FIG. 3C4 illustrate examples where the subpixels are arranged in a matrix, the arrangement method of the subpixels is not limited thereto.

The structures of all the pixels 23 provided in the pixel portion 33 are not necessarily the same. For example, the pixel portion 33 may be provided with the pixel 23 having the structure illustrated in FIG. 3A2 and the pixel 23 having the structure illustrated in FIG. 3A3. Similarly, the structures of all the pixels 27a provided in the region 37a are not necessarily the same. For example, the region 37a may be provided with the pixel 27a having the structure illustrated in FIG. 3B1 and the pixel 27a having the structure illustrated in FIG. 3B3. Alternatively, the region 37a may be provided with the pixel 27a having the structure illustrated in FIG. 3B3 and the pixel 27a having the structure illustrated in FIG. 3B6. Furthermore, the structures of all the pixels 27b provided in the region 37b are not necessarily the same. For example, the region 37b may be provided with the pixel 27b having the structure illustrated in FIG. 3C2 and the pixel 27b having the structure illustrated in FIG. 3C3.

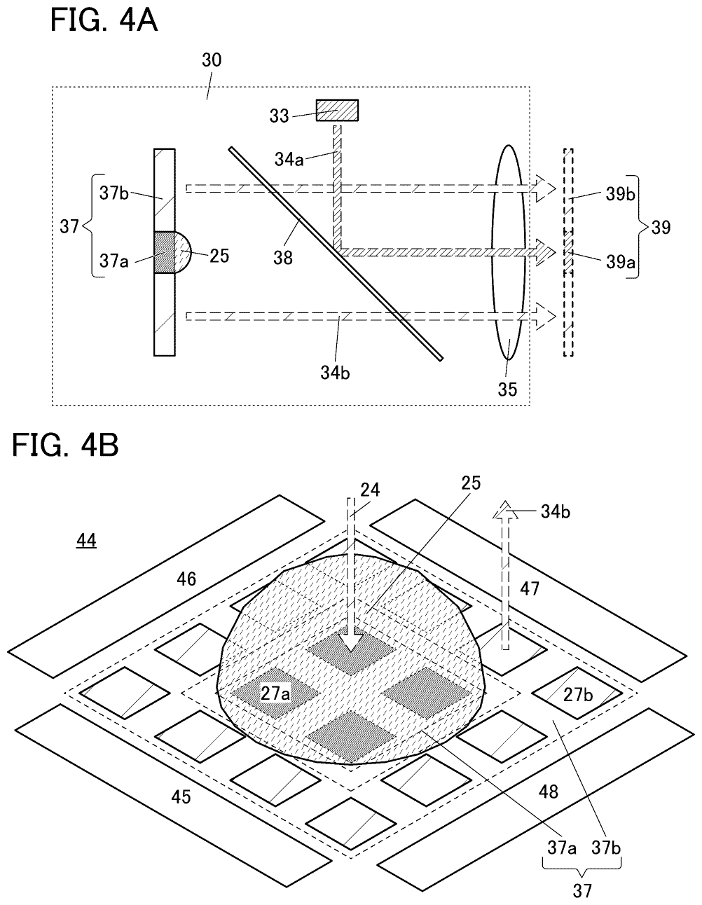

FIG. 4A is a modification example of the optical system 30 illustrated in FIG. 1B1 and differs from FIG. 1B1 in that a lens 25 is provided between the region 37a and the half mirror 38. The lens 25 includes a region overlapping with the region 37a. The region 37b includes a region not overlapping with the lens 25. Note that the lens 35 is provided at a position facing the pixel portion 37 with the half mirror 38 therebetween so as to include regions overlapping with the region 37a and the region 37b.

FIG. 4B is a block diagram illustrating a structure example of the display device 44, in which the lens 25 is added to the structure illustrated in FIG. 2B. As illustrated in FIG. 4B, the lens 25 is provided to overlap with the pixel 27a and not to overlap with the pixel 27b.

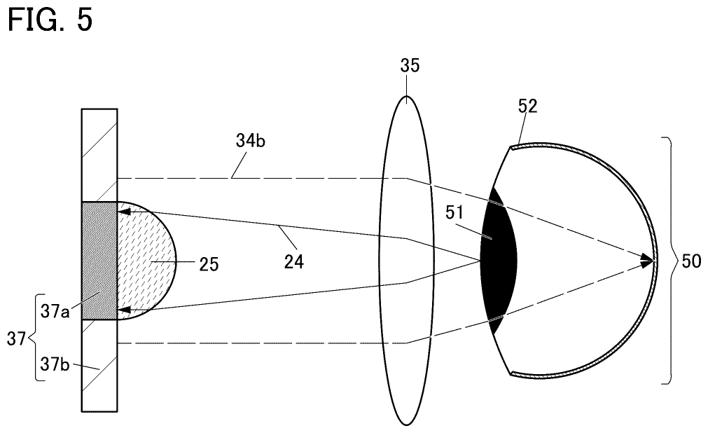

FIG. 5 is a schematic view illustrating the effect of the lens 25 and illustrates the pixel portion 37 and the lens 35 in addition to the lens 25. In the case illustrated in FIG. 5, a light-receiving element is provided in the region 37a, and a light-emitting element that emits the light 34b that is visible light is provided in the region 37b. In addition, an eye 50 is illustrated as an example of the projected surface 39. The eye 50 includes a pupil 51 and a retina 52.

As illustrated in FIG. 5, in the case where the lens 25 overlaps with the region 37a and does not overlap with the region 37b, the light 34b emitted from the region 37b is refracted at the lens 35 and enters the retina 52 without passing through the lens 25. Here, when the focus of the lens 35 is positioned on the retina 52 or in the vicinity thereof, an image represented as the light 34b can be formed on the retina 52.

In the case where the lens 25 is provided, the focus of the optical system including the lens 25 and the lens 35 can be positioned on the surface of the eye 50 or in the vicinity thereof. That is, the focal length of the optical system including the lens 25 and the lens 35 can be less than the focal length of the lens 35. Thus, the pupil 51 positioned closer to the surface of the eye 50 than the retina 52 is can be detected using the light-receiving element provided in the region 37a with high accuracy. Therefore, the electronic device 10 can perform gaze tracking with high accuracy, for example. Note that in FIG. 5, the lens 35 has an elliptical shape, and the light 34b emitted from the region 37b and the light 24 reflected by the eye 50 are refracted at the major axis of the lens 35; however, the light 34b and the light 24 are actually refracted at the surface of the lens 35, a cornea and a crystalline lens (not illustrated) included in the eye 50, and the like.

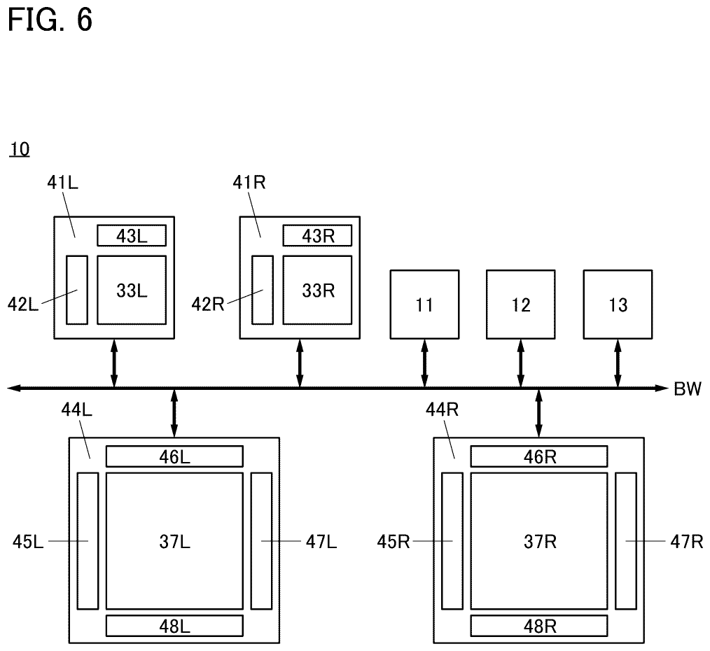

FIG. 6 is a block diagram illustrating a structure example of the electronic device 10. The display device 41, the display device 44, the communication circuit 11, the detection circuit 12, and the control circuit 13 included in the electronic device 10 transmit and receive various kinds of data, signals, and the like to and from each other through a bus wiring BW. Here, the display device 41 including the pixel portion 33L is a display device 41L, and the display device 41 including the pixel portion 33R is a display device 41R. The gate driver circuit 42 and the source driver circuit 43 included in the display device 41L are respectively a gate driver circuit 42L and a source driver circuit 43L, and the gate driver circuit 42 and the source driver circuit 43 included in the display device 41R are respectively a gate driver circuit 42R and a source driver circuit 43R. The display device 44 including the pixel portion 37L is a display device 44L, and the display device 44 including the pixel portion 37R is a display device 44R. Furthermore, the gate driver circuit 45, the source driver circuit 46, the row driver circuit 47, and the column driver circuit 48 included in the display device 44L are respectively a gate driver circuit 45L, a source driver circuit 46L, a row driver circuit 47L, and a column driver circuit 48L, and the gate driver circuit 45, the source driver circuit 46, the row driver circuit 47, and the column driver circuit 48 included in the display device 44R are respectively a gate driver circuit 45R, a source driver circuit 46R, a row driver circuit 47R, and a column driver circuit 48R.

The communication circuit 11 has a function of communicating with an external device by wire or wirelessly. The communication circuit 11 has a function of receiving image data from an external device, for example. The communication circuit 11 may have a function of transmitting data generated by the electronic device 10 to an external device.

The communication circuit 11 is provided with a high frequency circuit (RF circuit), for example, to transmit and receive an RF signal. The high frequency circuit is a circuit for performing mutual conversion between an electromagnetic signal and an electrical signal in a frequency band that is set by national laws to perform wireless communication with another communication apparatus using the electromagnetic signal. In the case of performing wireless communication, it is possible to use, as a communication protocol or a communication technology, a communication standard such as LTE (Long Term Evolution), GSM (Global System for Mobile Communication: registered trademark), EDGE (Enhanced Data Rates for GSM Evolution), CDMA 2000 (Code Division Multiple Access 2000), or WCDMA (Wideband Code Division Multiple Access: registered trademark), or a communication standard developed by IEEE such as Wi-Fi (registered trademark), Bluetooth (registered trademark), or ZigBee (registered trademark). The third-generation mobile communication system (3G), the fourth-generation mobile communication system (4G), or the fifth-generation mobile communication system (5G) defined by the International Telecommunication Union (ITU) or the like can be used.

The communication circuit 11 may include an external port such as a LAN (Local Area Network) connection terminal, a digital broadcast-receiving terminal, or an AC adaptor connection terminal.

The detection circuit 12 has a function of performing detection on the basis of the imaging data obtained by the display device 44, for example. Specifically, the detection circuit 12 has a function of performing detection on the basis of the imaging data that is read by the column driver circuit 48 included in the display device 44. The detection circuit 12 has a function of detecting the pupil from the imaging data, for example. The detection circuit has a function of detecting degree of eye opening from the imaging data, for example.

The control circuit 13 has a function of generating data representing the luminance of light emitted from the light-emitting element provided in the pixel portion 33 (first luminance data) and data representing the luminance of light emitted from the light-emitting element provided in the pixel portion 37 (second luminance data) on the basis of the image data received by the communication circuit 11, for example. In the case where the image data includes address information of a pixel and information on the luminance of each pixel, for example, the control circuit 13 can select whether the information on the luminance of each pixel is included in the first luminance data or the second luminance data on the basis of the address information. Note that the luminance data may be referred to as the image data.

Here, the control circuit 13 can have a function of performing downconversion for reducing the definition of the image data. The control circuit 13 may have a function of performing upconversion for increasing the definition of the image data. For example, the control circuit 13 can perform downconversion on the second luminance data. The control circuit 13 may perform upconversion on the first luminance data.

The control circuit 13 has a function of supplying the first luminance data to the display device 41, specifically, the source driver circuit 43 included in the display device 41, and supplying the second luminance data to the display device 44, specifically, the source driver circuit 46 included in the display device 44. Here, in the case where a light-emitting element that emits infrared light is provided in the pixel portion 33 or the pixel portion 37, the control circuit 13 may generate data representing the luminance of light emitted from the light-emitting element regardless of the image data received by the communication circuit 11, for example. For example, all the light-emitting elements that emit infrared light may have the same luminance.

In this specification and the like, in the case where a light-emitting element is provided in the region 37a of the pixel portion 37, both data representing the luminance of light emitted from the light-emitting element provided in the region 37a and data representing the luminance of light emitted from the light-emitting element provided in the region 37b can be referred to as “second luminance data”. Alternatively, the data representing the luminance of light emitted from the light-emitting element provided in the region 37a can be referred to as “second luminance data”, and the data representing the luminance of light emitted from the light-emitting element provided in the region 37b can be referred to as “third luminance data”. In this case, the control circuit 13 can generate the first luminance data and the third luminance data on the basis of the image data received by the communication circuit 11 and can generate the second luminance data regardless of the image data received by the communication circuit 11, for example. The control circuit 13 can supply the first luminance data to the source driver circuit 43 and supply the second luminance data and the third luminance data to the source driver circuit 46.

The control circuit 13 has a function of generating at least one piece of the luminance data on the basis of a detection result of the detection circuit 12 in addition to the image data received by the communication circuit 11, for example. In the case where the control circuit 13 has a function of generating the first luminance data and the second luminance data, the control circuit 13 can generate at least one of the first luminance data and the second luminance data on the basis of the detection result of the detection circuit 12 in addition to the image data received by the communication circuit 11, for example.

For example, in the case where the first luminance data represents an image displayed on the pixel portion 33 and the second luminance data represents an image displayed on the region 37b, the control circuit 13 can generate the first luminance data and the second luminance data so as to move an object such as a cursor displayed on the pixel portion 33 or the region 37b on the basis of the gaze tracking result. The control circuit 13 can generate the first luminance data and the second luminance data such that the luminance of the image displayed on the pixel portion 33 and the luminance of the image displayed on the region 37b are made different on the basis of the fatigue level of the user of the electronic device 10, for example. In the case where it is determined that the user of the electronic device 10 feels fatigue, the first luminance data and the second luminance data can be generated such that the luminance of the image displayed on the pixel portion 33 and the luminance of the image displayed on the region 37b are lowered, for example.

A microprocessor such as a DSP (Digital Signal Processor) or a GPU (Graphics Processing Unit) as well as a central processing unit (CPU) can be used alone or in combination as the control circuit 13. A structure may be employed in which such a microprocessor is obtained with a PLD (Programmable Logic Device) such as an FPGA (Field Programmable Gate Array) or an FPAA (Field Programmable Analog Array).

The control circuit 13 interprets and executes instructions from various programs with a processor to process various kinds of data and control programs. The programs that might be executed by the processor may be stored in a memory region included in the processor or a memory circuit which is additionally provided. As the memory circuit, a memory device using a nonvolatile memory element, such as a flash memory, an MRAM (Magnetoresistive Random Access Memory), a PRAM (Phase change RAM), an ReRAM (Resistive RAM), or an FeRAM (Ferroelectric RAM); a memory device using a volatile memory element, such as a DRAM (Dynamic RAM) and an SRAM (Static RAM); or the like may be used, for example.

### <Structure Example of Pixel Portion>

Structure examples of the display device included in the electronic device of one embodiment of the present invention are described. Specifically, structure examples of a light-emitting element and a light-receiving element provided in a pixel included in a pixel portion of the display device are described.

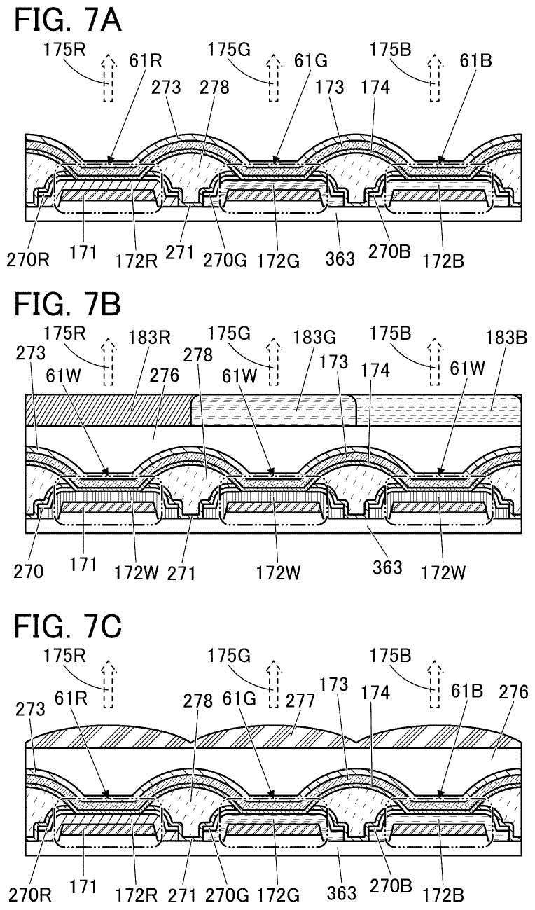

FIG. 7A is a cross-sectional view illustrating structure examples of a light-emitting element 61R, a light-emitting element 61G, and a light-emitting element 61B. The light-emitting element 61R can emit light 175R with intensity in a red wavelength range, the light-emitting element 61G can emit light 175G with intensity in a green wavelength range, and the light-emitting element 61B can emit light 175B with intensity in a blue wavelength range. Thus, the light-emitting element 61R, the light-emitting element 61G, and the light-emitting element 61B can be respectively provided in the subpixel R, the subpixel G, and the subpixel B illustrated in FIG. 3A1 to FIG. 3A3 and FIG. 3C1 to FIG. 3C4.

The light-emitting element 61R, the light-emitting element 61G, and the light-emitting element 61B are provided over an insulating layer 363. A plurality of transistors can be provided over a substrate and the insulating layer 363 can be provided to cover these transistors, for example.

The light-emitting element 61R includes a conductive layer 171 over the insulating layer 363, an EL layer 172R over the conductive layer 171, and a conductive layer 173 over the EL layer 172R. The light-emitting element 61G includes the conductive layer 171 over the insulating layer 363, an EL layer 172G over the conductive layer 171, and the conductive layer 173 over the EL layer 172G. The light-emitting element 61B includes the conductive layer 171 over the insulating layer 363, an EL layer 172B over the conductive layer 171, and the conductive layer 173 over the EL layer 172B.

In this specification and the like, a structure in which at least light-emitting layers are separately formed for light-emitting elements with different emission wavelengths is referred to as a SBS (side-by-side) structure in some cases. For example, the light-emitting element 61R, the light-emitting element 61G, and the light-emitting element 61B illustrated in FIG. 7A have an SBS structure. The SBS structure can optimize materials and structures of light-emitting elements and thus can increase the freedom of choices of the materials and the structures, so that the luminance and the reliability can be easily improved.

The conductive layer 171 functioning as a pixel electrode is divided for the light-emitting elements. The conductive layer 173 functioning as a common electrode is provided as a continuous layer shared by the light-emitting element 61R, the light-emitting element 61G, and the light-emitting element 61B. End portions of the EL layer 172R, the EL layer 172G, and the EL layer 172B can be positioned outward from end portions of the conductive layers 171, and the EL layer 172R, the EL layer 172G, and the EL layer 172B can cover the end portions of the conductive layers 171.

In this manner, the EL layer 172R, the EL layer 172G, and the EL layer 172B are preferably provided so as not to be in contact with each other. This can suitably prevent unintentional light emission (also referred to as crosstalk) from being caused by current flowing through two adjacent EL layers. As a result, the contrast can be increased to achieve a display device with high display quality.

For the insulating layer 363, one or both of an inorganic insulating film and an organic insulating film can be used. An inorganic insulating film is preferably used as the insulating layer 363, for example. As the inorganic insulating film, for example, an oxide insulating film and a nitride insulating film such as a silicon oxide film, a silicon oxynitride film, a silicon nitride oxide film, a silicon nitride film, an aluminum oxide film, an aluminum oxynitride film, or a hafnium oxide film can be given.

Note that in this specification, a nitride oxide refers to a compound that contains more nitrogen than oxygen. An oxynitride refers to a compound that contains more oxygen than nitrogen. The content of each element can be measured by Rutherford backscattering spectrometry (RBS), for example.

The EL layer 172R contains at least a light-emitting organic compound that emits light with intensity in a red wavelength range. The EL layer 172G contains at least a light-emitting organic compound that emits light with intensity in a green wavelength range. The EL layer 172B contains at least a light-emitting organic compound that emits light with intensity in a blue wavelength range.

The EL layer 172R, the EL layer 172G, and the EL layer 172B may each include one or more of an electron-injection layer, an electron-transport layer, a hole-injection layer, and a hole-transport layer in addition to the layer containing a light-emitting organic compound (the light-emitting layer). Embodiment 4 can be referred to for the details of the structures and materials of the light-emitting elements included in the electronic device of one embodiment of the present invention.

A conductive film having a visible-light-transmitting property is used for one of the conductive layer 171 and the conductive layer 173, and a conductive film having a visible-light-reflecting property is used for the other. The use of the light-transmitting conductive layer 171 and the reflective conductive layer 173 offers a bottom-emission display device, whereas the use of the reflective conductive layer 171 and the light-transmitting conductive layer 173 offers a top-emission display device. Note that when both the conductive layer 171 and the conductive layer 173 have a light-transmitting property, a dual-emission display device can be obtained. For example, in the case of a top-emission display device, the light 175R, the light 175G, and the light 175B are emitted to the conductive layer 173 side as illustrated in FIG. 7A.

Between the light-emitting elements 61 (the light-emitting element 61R, the light-emitting element 61G, and the light-emitting element 61B), a protective layer 271 is provided to cover the end portion of the EL layer 172R, the end portion of the EL layer 172G, and the end portion of the EL layer 172B. The protective layer 271 has a barrier property against water, for example. Accordingly, providing the protective layer 271 can inhibit entry of impurities (typically, water or the like) into the EL layer 172R, the EL layer 172G, and the EL layer 172B through their end portions. In addition, leakage current between adjacent light-emitting elements 61 is reduced, so that color saturation and contrast ratio are improved and power consumption is reduced.

The protective layer 271 can have, for example, a single-layer structure or a stacked-layer structure at least including an inorganic insulating film. As the inorganic insulating film, for example, an oxide film or a nitride film such as a silicon oxide film, a silicon oxynitride film, a silicon nitride oxide film, a silicon nitride film, an aluminum oxide film, an aluminum oxynitride film, or a hafnium oxide film can be given. Alternatively, a semiconductor material such as indium gallium oxide or indium gallium zinc oxide (IGZO) may be used for the protective layer 271. Note that the protective layer 271 can be formed by an atomic layer deposition (ALD) method, a chemical vapor deposition (CVD) method, or a sputtering method, for example. Although the protective layer 271 includes an inorganic insulating film in this example, one embodiment of the present invention is not limited thereto. For example, the protective layer 271 may have a stacked-layer structure of an inorganic insulating film and an organic insulating film.

In the case where an indium gallium zinc oxide is used for the protective layer 271, the indium gallium zinc oxide can be processed by a wet etching method or a dry etching method. For example, in the case where IGZO is used as the protective layer 271, a chemical solution of oxalic acid, phosphoric acid, a mixed chemical solution (e.g., a mixed chemical solution of phosphoric acid, acetic acid, nitric acid, and water, which is also referred to as a mixed acid aluminum etchant), or the like can be used. Note that the volume ratio of phosphoric acid, acetic acid, nitric acid, and water in the mixed acid aluminum etchant can be 53.3:6.7:3.3:36.7 or in the vicinity thereof.

The light-emitting element 61R, the light-emitting element 61G, and the light-emitting element 61B each include a region where the EL layer 172 (the EL layer 172R, the EL layer 172G, or the EL layer 172B) and the protective layer 271 overlap with each other with a sacrificial layer 270 (a sacrificial layer 270R, a sacrificial layer 270G, or a sacrificial layer 270B) therebetween. The sacrificial layer 270 is formed because of a fabrication process of the display device described later. Note that the sacrificial layer 270 is not provided in some cases.

Note that in this specification and the like, a sacrificial layer may be referred to as a mask layer. In addition, a sacrificial film may be referred to as a mask film.

In a region between adjacent light-emitting elements 61, an insulating layer 278 is provided over the protective layer 271. FIG. 7A illustrates an example in which the insulating layer 278 has a convex top surface. Note that although FIG. 7A illustrates a plurality of cross sections of the protective layers 271 and the insulating layers 278, for example, the protective layer 271 and the insulating layer 278 are each one continuous layer when the display surface is seen from above. In other words, the display device can have a structure such that one protective layer 271 and one insulating layer 278 are provided, for example. Note that the display device may include a plurality of protective layers 271 that are separated from each other and a plurality of insulating layers 278 that are separated from each other.

The insulating layer 278 having a convex shape is provided in the region between adjacent light-emitting elements 61, whereby a step due to the EL layer 172 can be filled in the region. This can improve the coverage with the conductive layer 173. Thus, a connection defect due to disconnection of the conductive layer 173 and an increase in electric resistance due to local thinning of the conductive layer 173 can be inhibited. When the top surface of the insulating layer 278 is flat, disconnection and local thinning of the conductive layer 173 can be inhibited more suitably. Furthermore, even in the case where the insulating layer 278 has a concave shape, disconnection and local thinning of the conductive layer 173 can be inhibited.

In this specification and the like, disconnection refers to a phenomenon in which a layer, a film, an electrode, or the like is split because of the shape of the formation surface (e.g., a level difference).

Examples of the insulating layer 278 include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. Alternatively, a photoresist may be used as the insulating layer 278. The photoresist used as the insulating layer 278 may be a positive photoresist or a negative photoresist.

A common layer 174 can be provided between the conductive layer 173 and each of the EL layer 172R, the EL layer 172G, the EL layer 172B, and the insulating layer 278. The common layer 174 can include a region in contact with the EL layer 172R, a region in contact with the EL layer 172G, and a region in contact with the EL layer 172B. The common layer 174 is provided as a continuous layer shared by the light-emitting element 61R, the light-emitting element 61G, and the light-emitting element 61B.

In the case where the common layer 174 is provided in the display device, the conductive layer 173 functioning as the common electrode can be formed successively without a process such as etching between formations of the common layer 174 and the conductive layer 173. For example, after the common layer 174 is formed in a vacuum, the conductive layer 173 can be formed in a vacuum without exposing the substrate to the air. In other words, the common layer 174 and the conductive layer 173 can be successively formed in a vacuum. Accordingly, the lower surface of the conductive layer 173 can be a clean surface, as compared with the case where the common layer 174 is not provided in the display device.

As the common layer 174, one or more of a hole-injection layer, a hole-transport layer, a hole-blocking layer, an electron-blocking layer, an electron-transport layer, and an electron-injection layer can be used. For example, the common layer 174 may be a carrier-injection layer. The common layer 174 can also be regarded as part of the EL layer 172. Note that the common layer 174 is not necessarily provided, in which case the fabrication process of the display device can be simplified. In the case where the common layer 174 is provided, a layer having the same function as the common layer 174 among the layers included in the EL layer 172 is not necessarily provided. For example, in the case where the common layer 174 includes an electron-injection layer, the EL layer 172 can have a structure not including an electron-injection layer. For another example, in the case where the common layer 174 includes a hole-injection layer, the EL layer 172 can have a structure not including a hole-injection layer.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be distinguished from each other in some cases by the cross-sectional shape, the characteristics, or the like. Furthermore, one layer may have two or three functions of the carrier-injection layer, the carrier-transport layer, and the carrier-blocking layer in some cases.

A protective layer 273 is provided over the conductive layer 173 so as to cover the light-emitting element 61R, the light-emitting element 61G, and the light-emitting element 61B. The protective layer 273 has a function of preventing diffusion of impurities such as water into the light-emitting elements from above. For the protective layer 273, a material similar to the material that can be used for the protective layer 271 can be used. The protective layer 273 can be formed by an ALD method, a CVD method, or a sputtering method, for example.

Furthermore, the color purity of emitted light can be further increased when the light-emitting element 61 has a microcavity structure. In order that the light-emitting element 61 has a microcavity structure, a product (optical path length) of a distance d between the conductive layer 171 and the conductive layer 173 and a refractive index n of the EL layer 172 is set to m times half of a wavelength λ (m is an integer of 1 or more). The distance d can be obtained by Formula 1.

$$d = m \times λ / ( 2 \times n ) . \qquad Formula 1$$

According to Formula 1, in the light-emitting element 61 having the microcavity structure, the distance d is determined in accordance with the wavelength (emission color) of emitted light. The distance d corresponds to the thickness of the EL layer 172. Thus, the EL layer 172G is provided to have a larger thickness than the EL layer 172B, and the EL layer 172R is provided to have a larger thickness than the EL layer 172G in some cases.

To be exact, the distance d is a distance from a reflection region in the conductive layer 171 functioning as a reflective electrode to a reflection region in the conductive layer 173 functioning as an electrode having properties of transmitting and reflecting emitted light (a transflective electrode). For example, in the case where the conductive layer 171 is a stack of silver and ITO (Indium Tin Oxide) that is a transparent conductive film and the ITO is positioned on the EL layer 172 side, the distance d suitable for the emission color can be set by adjusting the thickness of the ITO. That is, even when the EL layer 172R, the EL layer 172G, and the EL layer 172B have the same thickness, the distance d suitable for the emission color can be obtained by adjusting the thickness of the ITO.

However, it is sometimes difficult to determine the exact position of the reflection region in each of the conductive layer 171 and the conductive layer 173. In this case, it is assumed that the effect of the microcavity structure can be obtained sufficiently with a certain position in the conductive layer 171 and the conductive layer 173 being supposed as the reflection region.

In order to increase the light extraction efficiency in the microcavity structure, the optical path length from the conductive layer 171 functioning as a reflective electrode to the light-emitting layer is preferably set to an odd multiple of λ/4. In order to achieve this optical path length, the thicknesses of the layers included in the light-emitting element 61 are preferably adjusted as appropriate.

In the case where light is emitted from the conductive layer 173 side, the reflectance of the conductive layer 173 is preferably higher than the transmittance thereof. The transmittance of the conductive layer 173 is preferably higher than or equal to 2% and lower than or equal to 50%, further preferably higher than or equal to 2% and lower than or equal to 30%, still further preferably higher than or equal to 2% and lower than or equal to 10%. When the transmittance of the conductive layer 173 is set low (the reflectance is set high), the effect of the microcavity structure can be enhanced.

FIG. 7B illustrates a modification example of the structure illustrated in FIG. 7A. FIG. 7B illustrates an example in which light-emitting elements 61W that emit white light are provided over the insulating layer 363 instead of the light-emitting element 61R, the light-emitting element 61G, and the light-emitting element 61B. The light-emitting elements 61W each include, for example, an EL layer 172W that emits white light as the EL layer 172. The EL layer 172W can have, for example, a structure in which two or more light-emitting layers that are selected so as to emit light of complementary colors are stacked. It is also possible to use a stacked EL layer in which a charge-generation layer is provided between light-emitting layers as the EL layer 172W.

Here, the EL layer 172W is divided for the light-emitting elements 61W. This can prevent unintentional light emission from being caused by current flowing through the EL layers 172W of the two adjacent light-emitting elements 61W. Particularly when the EL layer 172W has a structure in which a charge-generation layer is provided between two light-emitting layers, the influence of crosstalk becomes larger as the resolution increases, i.e., as the distance between adjacent pixels decreases, leading to lower contrast. Thus, the above structure can achieve a display device having both high resolution and high contrast. Note that the EL layer 172W may be a continuous layer instead of being divided for the light-emitting elements 61W.

In the illustrated example, an insulating layer 276 is provided over the protective layer 273, and a coloring layer 183R, a coloring layer 183G, and a coloring layer 183B are provided over the insulating layer 276. Specifically, the coloring layer 183R that transmits red light is provided at a position overlapping with the light-emitting element 61W on the left, the coloring layer 183G that transmits green light is provided at a position overlapping with the light-emitting element 61W in the middle, and the coloring layer 183B that transmits blue light is provided at a position overlapping with the light-emitting element 61W on the right. Providing the coloring layer 183R, the coloring layer 183G, and the coloring layer 183B enables the display device to display a color image even when all the light-emitting elements provided in the display device are light-emitting elements that emit white light, for example. Note that in the case of a bottom-emission display device, the coloring layer 183R, the coloring layer 183G, and the coloring layer 183B are provided between the conductive layer 171 and the insulating layer 363.

Adjacent coloring layers 183 (the coloring layer 183R, the coloring layer 183G, and the coloring layer 183B) have overlapping regions. For example, in the cross section illustrated in FIG. 7B, one end portion of the coloring layer 183G overlaps with the coloring layer 183R, and the other end portion of the coloring layer 183G overlaps with the coloring layer 183B. This can inhibit light emitted from the light-emitting element 61W provided at a position overlapping with the coloring layer 183G from entering the coloring layer 183R or the coloring layer 183B and being emitted from the coloring layer 183R or the coloring layer 183B, for example. Thus, the display device can have high display quality.

The insulating layer 276 functions as a planarization layer. For the insulating layer 276, an organic material can be used, for example. For the insulating layer 276, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of these resins, or the like can be used, for example.

When the insulating layer 276 is provided over the protective layer 273, the coloring layer 183 can be provided on a flat surface. This makes it easy to form the coloring layer 183.

Like the light-emitting element 61R, the light-emitting element 61G, and the light-emitting element 61B, the light-emitting element 61W can have a microcavity structure. Thus, for example, the light-emitting element 61W overlapping with the coloring layer 183R can emit red-enhanced light, the light-emitting element 61W overlapping with the coloring layer 183G can emit green-enhanced light, and the light-emitting element 61W overlapping with the coloring layer 183B can emit blue-enhanced light. Therefore, when the light-emitting element 61W has a microcavity structure, the color purity of the light 175R, the light 175G, and the light 175B can be increased.

FIG. 7C illustrates a modification example of the structure illustrated in FIG. 7A, in which the insulating layer 276 is provided over the protective layer 273 and a microlens array 277 is provided over the insulating layer 276.

The microlens array 277 can condense light emitted from the light-emitting element 61R, the light-emitting element 61G, and the light-emitting element 61B in some cases. Condensing light emitted from the light-emitting element 61R, the light-emitting element 61G, and the light-emitting element 61B is suitable because a user can see bright images particularly when the user sees the display surface from the front of the display device.

Note that the microlens array 277 may be provided in the structure illustrated in FIG. 7B. For example, an insulating layer having a function of a planarization layer can be provided over the coloring layer 183R, the coloring layer 183G, and the coloring layer 183B, and the microlens array 277 can be provided over the insulating layer. The coloring layer 183R, the coloring layer 183G, and the coloring layer 183B may be provided in the structure illustrated in FIG. 7C. For example, an insulating layer having a function of a planarization layer may be provided over the microlens array 277, and the coloring layer 183R, the coloring layer 183G, and the coloring layer 183B may be provided over the insulating layer.

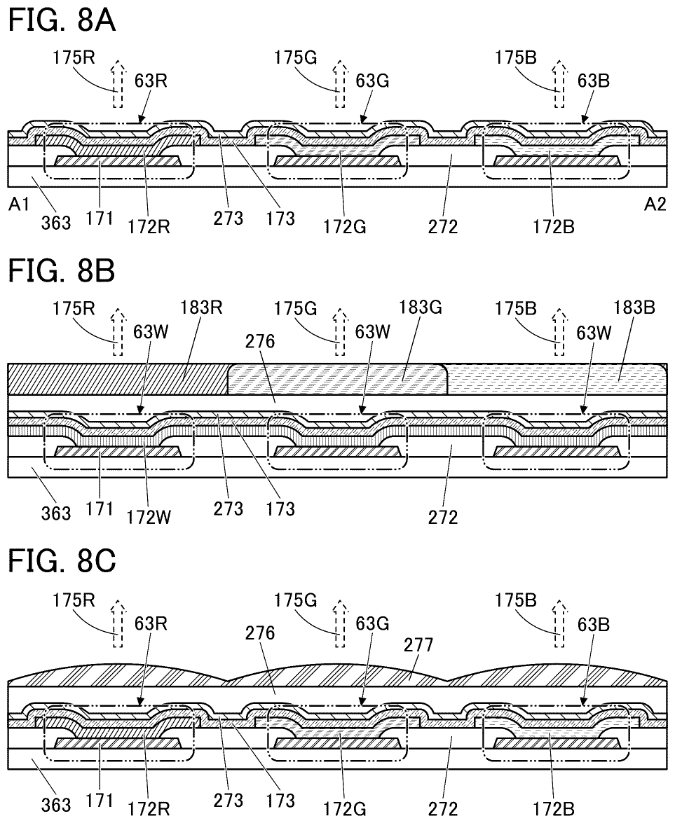

FIG. 8A illustrates a modification example of the structure illustrated in FIG. 7A, in which a light-emitting element 63R, a light-emitting element 63G, and a light-emitting element 63B are provided over the insulating layer 363 instead of the light-emitting element 61R, the light-emitting element 61G, and the light-emitting element 61B.

The light-emitting element 63R includes the conductive layer 171 over the insulating layer 363, the EL layer 172R over the conductive layer 171, and the conductive layer 173 over the EL layer 172R. The light-emitting element 63G includes the conductive layer 171 over the insulating layer 363, the EL layer 172G over the conductive layer 171, and the conductive layer 173 over the EL layer 172G. The light-emitting element 63B includes the conductive layer 171 over the insulating layer 363, the EL layer 172B over the conductive layer 171, and the conductive layer 173 over the EL layer 172B.

FIG. 8A illustrates an example in which an insulating layer 272 is provided to cover the end portions of the conductive layer 171 functioning as a pixel electrode. Providing the insulating layer 272 can prevent an unintentional electric short-circuit between the conductive layers 171 included in adjacent light-emitting elements 63 (the light-emitting element 63R, the light-emitting element 63G, and the light-emitting element 63B) and unintended light emission. Thus, a highly reliable display device can be provided.

In the light-emitting element 63R, the light-emitting element 63G, and the light-emitting element 63B, the EL layer 172R, the EL layer 172G, and the EL layer 172B each include a region in contact with the top surface of the conductive layer 171 and a region in contact with the surface of the insulating layer 272. The end portions of the EL layer 172R, the EL layer 172G, and the EL layer 172B are positioned over the insulating layer 272.

An end portion of the insulating layer 272 is preferably tapered. In the structure illustrated in FIG. 8A, the protective layer 271, the sacrificial layer 270, the insulating layer 278, and the common layer 174 are not provided. Furthermore, a color purity of the emission color can be increased when the light-emitting element 63 has a microcavity structure like the light-emitting element 61.

Note that in this specification and the like, a tapered shape refers to such a shape that at least part of a side surface of a component is inclined with respect to a substrate surface or a formation surface. For example, the tapered shape preferably includes a region where the angle formed by the inclined side surface and the substrate surface or the formation surface (such an angle is also referred to as a taper angle) is less than 90°. Note that the side surface, the substrate surface, and the formation surface of the component are not necessarily completely flat, and may have a substantially planar shape with a small curvature or a substantially planar shape with slight unevenness.

An organic material or an inorganic material can be used for the insulating layer 272, for example. Examples of an organic material that can be used for the insulating layer 272 include an acrylic resin, an epoxy resin, a polyimide resin, a polyamide resin, a polyimide-amide resin, a polysiloxane resin, a benzocyclobutene-based resin, and a phenol resin. Examples of an inorganic material that can be used for the insulating layer 272 include silicon oxide, aluminum oxide, gallium oxide, germanium oxide, yttrium oxide, zirconium oxide, lanthanum oxide, neodymium oxide, hafnium oxide, tantalum oxide, silicon nitride, aluminum nitride, silicon oxynitride, aluminum oxynitride, silicon nitride oxide, and aluminum nitride oxide.

FIG. 8B illustrates a modification example of the structure illustrated in FIG. 8A, in which light-emitting elements 63W that emit white light are provided over the insulating layer 363 instead of the light-emitting element 63R, the light-emitting element 63G, and the light-emitting element 63B. The light-emitting elements 63W each include the EL layer 172W as the EL layer 172. Note that when the light-emitting elements 63W each have a microcavity structure like the light-emitting element 61W, the color purity of the light 175R, the light 175G, and the light 175B can be increased.

FIG. 8B illustrates an example in which the insulating layer 276 is provided over the protective layer 273, and the coloring layer 183R, the coloring layer 183G, and the coloring layer 183B are provided over the insulating layer 276.

FIG. 8B illustrates an example in which the EL layer 172W is a continuous layer without being divided for the light-emitting elements 63W. When the EL layer 172W is a continuous layer, the fabrication process of the display device can be simplified. Note that the EL layer 172W may be divided for the light-emitting elements 63W.

FIG. 8C illustrates a modification example of the structure illustrated in FIG. 8A, in which the insulating layer 276 is provided over the protective layer 273 and the microlens array 277 is provided over the insulating layer 276.

The display device having any of the structures illustrated in FIG. 7A, FIG. 7B, and FIG. 7C can have high resolution without a reduction in contrast compared with the display device having any of the structures illustrated in FIG. 8A, FIG. 8B, and FIG. 8C. For example, the distance between the adjacent light-emitting elements 61 can be made small. Specifically, the distance between the light-emitting elements 61 can be less than or equal to 1 μm, preferably less than or equal to 500 nm, further preferably less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, in two adjacent EL layers 172, a region where the distance between the end portion of one of the EL layers 172 and the end portion of the other of the EL layers 172 is less than or equal to 1 μm, preferably less than or equal to 0.5 μm (500 nm), further preferably less than or equal to 100 nm is provided.

Meanwhile, the display device having any of the structures illustrated in FIG. 8A, FIG. 8B, and FIG. 8C can be fabricated by a simple method compared with the display device having any of the structures illustrated in FIG. 7A, FIG. 7B, and FIG. 7C. Accordingly, the display device having any of the structures illustrated in FIG. 8A, FIG. 8B, and FIG. 8C can be fabricated at low cost.

As described above, the resolution of the display device 41 including the pixel portion 33 is higher than the resolution of the display device 44 including the pixel portion 37. Thus, the structures illustrated in FIG. 7A, FIG. 7B, and FIG. 7C can be suitably employed for the display device 41. Specifically, the light-emitting element 61 can be suitably used as the light-emitting element included in the pixel 23 provided in the pixel portion 33. Meanwhile, as described above, the display device having any of the structures illustrated in FIG. 8A, FIG. 8B, and FIG. 8C can be fabricated at low cost. Thus, when the display device having any of the structures illustrated in FIG. 8A, FIG. 8B, and FIG. 8C are preferably used as the display device 44, in which case the electronic device 10 can be an inexpensive electronic device. Specifically, the light-emitting element 63 can be suitably used as the light-emitting element included in the pixel 27b provided in the region 37b of the pixel portion 37. Note that any of the structures illustrated in FIG. 7A, FIG. 7B, and FIG. 7C may be employed for the display device 44. Furthermore, any of the structures illustrated in FIG. 8A, FIG. 8B, and FIG. 8C may be employed for the display device 41.

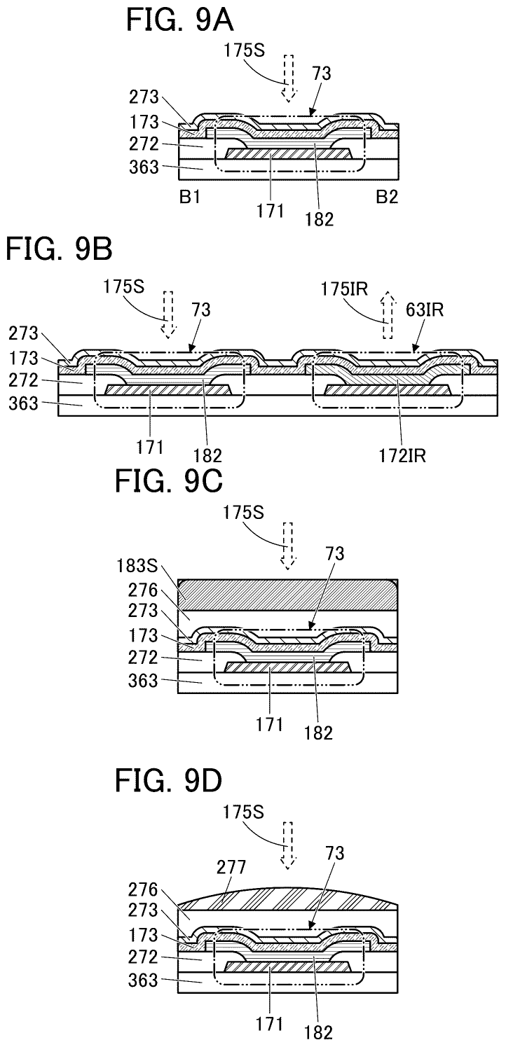

FIG. 9A is a cross-sectional view illustrating a structure example of a light-receiving element 73. The light-receiving element 73 can be provided in the subpixel S illustrated in FIG. 3B1 to FIG. 3B4 and FIG. 3C4, for example.

The light-receiving element 73 can be obtained by replacing the EL layer 172 of the light-emitting element 63 with a PD layer 182. The PD layer 182 includes at least an active layer functioning as a photoelectric conversion layer. The active layer has a function of changing a resistance value depending on the wavelength and intensity of incident light. For the PD layer 182, an organic compound can be used as in the EL layer 172. Note that an inorganic material such as silicon may be used for the PD layer 182. The PD layer 182 may include an electron-transport layer and a hole-transport layer in addition to the active layer.

In this specification and the like, in a subpixel provided with the light-emitting element, the area of the EL layer in a plan view is the area occupied by the subpixel. In a subpixel provided with the light-receiving element, the area of the PD layer in a plan view is the area occupied by the subpixel. The total area occupied by the subpixels forming a pixel is the area occupied by the pixel.

The light-receiving element 73 has a function of detecting light 175S entering from the outside of the display device through the protective layer 273 and the conductive layer 173. For example, the light 175S detected by the light-receiving element 73 can be visible light, specifically red light, green light, or blue light. For example, the light 175S detected by the light-receiving element 73 can be infrared light, specifically near-infrared light.

Note that the insulating layer 272 is not necessarily provided between the conductive layer 171 and the PD layer 182. In this case, the EL layer 172 of the light-emitting element 61 is replaced with the PD layer 182, whereby the light-receiving element 73 can be obtained.

FIG. 9B is a cross-sectional view illustrating a structure example of a light-emitting element 63IR in addition to the light-receiving element 73. The light-emitting element 63IR includes an EL layer 172IR. The EL layer 172IR can emit light 175IR with intensity in an infrared wavelength range, specifically a near-infrared wavelength range, for example. Thus, the light-emitting element 63IR can be provided in the subpixel IR illustrated in FIG. 3B3 to FIG. 3B6 and FIG. 3C3, for example.

Like the light-emitting element 61 illustrated in FIG. 7A to FIG. 7C, the light-emitting element 63IR may have a structure in which the insulating layer 272 is not provided between the conductive layer 171 and the EL layer 172IR. The light-emitting element 63IR having such a structure can be suitably provided in the subpixel IR illustrated in FIG. 3A3, for example. Note that the light-emitting element 63IR illustrated in FIG. 9B may be provided in the subpixel IR illustrated in FIG. 3A3. The light-emitting element 63IR having a structure in which the insulating layer 272 is not provided between the conductive layer 171 and the EL layer 172IR may be provided in the subpixel IR illustrated in FIG. 3B3 to FIG. 3B6 and FIG. 3C3.

The light-receiving element 73 illustrated in FIG. 9B has a function of detecting infrared light, specifically near-infrared light, as the light 175S, for example. Thus, the display device having the structure illustrated in FIG. 9B can perform gaze tracking of the user of the electronic device 10 or detection of the user's health condition such as a fatigue level with the use of infrared light, for example.

FIG. 9C illustrates a modification example of the structure illustrated in FIG. 9A, in which the insulating layer 276 is provided over the protective layer 273 and a coloring layer 183S is provided over the insulating layer 276. When the coloring layer 183S is provided to include a region overlapping with the light-receiving element 73, light with a wavelength that becomes noise when entering the PD layer 182 can be removed from the light 175S. Thus, the S/N ratio of imaging data obtained by the light-receiving element 73 can be increased, and for example, the accuracy of gaze tracking of the user or the accuracy of detection of the user's health condition by the electronic device 10 can be increased.

FIG. 9D illustrates a modification example of the structure illustrated in FIG. 9A, in which the insulating layer 276 is provided over the protective layer 273 and the microlens array 277 is provided over the insulating layer 276. When the microlens array 277 is provided to include a region overlapping with the light-receiving element 73, the light 175S can be condensed and enter the PD layer 182. Accordingly, the detection sensitivity of the light-receiving element 73 can be increased, so that the accuracy of gaze tracking of the user or the accuracy of detection of the user's health condition by the electronic device 10 can be increased, for example.

Note that the microlens array 277 may be provided in the structure illustrated in FIG. 9C. For example, an insulating layer having a function of an adhesive layer can be provided over the coloring layer 183S, and the microlens array 277 can be provided over the insulating layer. The coloring layer 183S may be provided in the structure illustrated in FIG. 9D. For example, an insulating layer having a function of a planarization layer may be provided over the microlens array 277, and the coloring layer 183S may be provided over the insulating layer.

Next, materials that can be used for the light-receiving element included in the electronic device of one embodiment of the present invention will be described.

Either a low molecular compound or a high molecular compound can be used for the light-receiving element, and an inorganic compound may be contained. Each of the layers included in the light-receiving element can be formed by an evaporation method (including a vacuum evaporation method), a transfer method, a printing method, an inkjet method, a coating method, or the like.

The active layer included in the light-receiving element includes a semiconductor. Examples of the semiconductor include an inorganic semiconductor such as silicon and an organic semiconductor including an organic compound. This embodiment describes an example in which an organic semiconductor is used as the semiconductor included in the active layer. The use of an organic semiconductor is preferable because the light-emitting layer and the active layer can be formed by the same method (e.g., a vacuum evaporation method) and thus the same manufacturing apparatus can be used.

Examples of an n-type semiconductor material contained in the active layer are electron-accepting organic semiconductor materials such as fullerene (e.g., C₆₀ fullerene and C₇₀ fullerene) and a fullerene derivative. Examples of the fullerene derivative include [6,6]-phenyl-C₇₁-butyric acid methyl ester (abbreviation: PC71BM), [6,6]-phenyl-C6₁-butyric acid methyl ester (abbreviation: PC61BM), and 1′,1″,4′,4″-tetrahydro-di[1,4]methanonaphthaleno[1,2:2′, 3′, 56,60:2″, 3″ ][5,6]fullerene-C₆₀ (abbreviation: ICBA).

Other examples of an n-type semiconductor material include perylenetetracarboxylic acid derivatives such as N,N-dimethyl-3,4,9,10-perylenetetracarboxylic diimide (abbreviation: Me-PTCDI) and 2,2′-(5,5′-(thieno[3,2-b]thiophene-2,5-diyl)bis(thiophene-5,2-diyl))bis(methan-1-yl-1-ylidene)dimalononitrile (abbreviation: FT2TDMN).

Other examples of an n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of a p-type semiconductor material contained in the active layer include electron-donating organic semiconductor materials such as copper(II) phthalocyanine (abbreviation: CuPc), tetraphenyldibenzoperiflanthene (abbreviation: DBP), zinc phthalocyanine (abbreviation: ZnPc), tin (II) phthalocyanine (abbreviation: SnPc), quinacridone, and rubrene.

Other examples of a p-type semiconductor material include a carbazole derivative, a thiophene derivative, a furan derivative, and a compound having an aromatic amine skeleton. Other examples of a p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a rubrene derivative, a tetracene derivative, a polyphenylene vinylene derivative, a polyparaphenylene derivative, a polyfluorene derivative, a polyvinylcarbazole derivative, and a polythiophene derivative.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of similar kinds, which have molecular orbital energy levels close to each other, can increase the carrier-transport property.

For the active layer, a high molecular compound such as poly[[4,8-bis[5-(2-ethylhexyl)-2-thienyl]benzo[1,2-b:4,5-b′]dithiophene-2,6-diyl]-2,5-thiophenediyl[5,7-bis(2-ethylhexyl)-4,8-dioxo-4H,8H-benzo[1,2-c:4,5-c′]dithiophene-1,3-diyl]] polymer (abbreviation: PBDB-T) or a PBDB-T derivative, which functions as a donor, can be used. For example, a method in which an acceptor material is dispersed to PBDB-T or a PBDB-T derivative can be used.

For example, the active layer is preferably formed by co-evaporation of an n-type semiconductor and a p-type semiconductor. Alternatively, the active layer may be formed by stacking an n-type semiconductor and a p-type semiconductor.

In addition, three or more kinds of materials may be mixed for the active layer. For example, a third material may be mixed with an n-type semiconductor material and a p-type semiconductor material in order to extend the wavelength range. The third material may be a low molecular compound or a high molecular compound.

In addition to the active layer, the light-receiving element may further include a layer containing any of a substance having a high hole-transport property, a substance having a high electron-transport property, a substance having a bipolar property (a substance having a high electron-transport property and a high hole-transport property), and the like. Without limitation to the above, the light-receiving element may further include a layer containing any of a substance having a high hole-injection property, a hole-blocking material, a material having a high electron-injection property, an electron-blocking material, and the like. Layers other than the active layer included in the light-receiving element can be formed using a material that can be used for the light-emitting element, for example.

As the hole-transport material or the electron-blocking material, a high molecular compound such as poly(3,4-ethylenedioxythiophene)/poly(styrenesulfonic acid) (PEDOT/PSS), or an inorganic compound such as molybdenum oxide or copper iodide (CuI) can be used, for example. As the electron-transport material or the hole-blocking material, an inorganic compound such as zinc oxide (ZnO), or an organic compound such as polyethylenimine ethoxylate (PEIE) can be used. The light-receiving element may include a mixed film of PEIE and ZnO, for example.

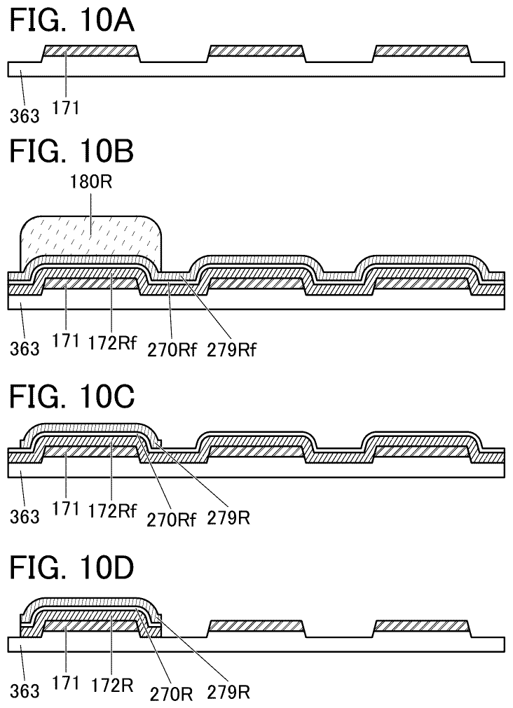

An example of a method for fabricating the display device having the structure illustrated in FIG. 7A will be described below with reference to FIG. 10A to FIG. 12C.

First, a plurality of transistors are formed over a substrate, and the insulating layer 363 is formed to cover these transistors. Next, as illustrated in FIG. 10A, the conductive layer 171 is formed over the insulating layer 363. For example, a film to be the conductive layer 171 is formed by a sputtering method or a vacuum evaporation method, and the film is processed by a photolithography and an etching method, for example, whereby the conductive layer 171 can be formed. Note that when the film to be the conductive layer 171 is processed by an etching method, for example, a depressed portion is sometimes formed in the insulating layer 363. Specifically, a depressed portion is sometimes formed in the insulating layer 363 in a region not overlapping with the conductive layer 171.

Next, as illustrated in FIG. 10B, an EL film 172Rf to be the EL layer 172R later is formed over the conductive layer 171 and the insulating layer 363. The EL film 172Rf can be formed by an evaporation method, specifically a vacuum evaporation method, for example. The EL film 172Rf may be formed by a transfer method, a printing method, an inkjet method, a coating method, or the like.

Next, as illustrated in FIG. 10B, a sacrificial film 270Rf to be the sacrificial layer 270R later and a sacrificial film 279Rf to be a sacrificial layer 279R later are sequentially formed over the EL film 172Rf.

Although an example is described below where the sacrificial film is formed to have a two-layer structure of the sacrificial film 270Rf and the sacrificial film 279Rf, the sacrificial film may have a single-layer structure or a stacked-layer structure of three or more layers.

Providing the sacrificial film over the EL film 172Rf can reduce damage to the EL film 172Rf in the fabrication process of the display device, resulting in improved reliability of the light-emitting element.

As the sacrificial film 270Rf, a film that is highly resistant to the processing conditions for the EL film 172Rf, specifically, a film having high etching selectivity with the EL film 172Rf is used. For the sacrificial film 279Rf, a film having high etching selectivity with the sacrificial film 270Rf is used.

The sacrificial film 270Rf and the sacrificial film 279Rf are formed at a temperature lower than the upper temperature limit of the EL film 172Rf. The typical substrate temperatures in formation of the sacrificial film 270Rf and the sacrificial film 279Rf are each lower than or equal to 200° C., preferably lower than or equal to 150° C., further preferably lower than or equal to 120° C., still further preferably lower than or equal to 100° C., and yet still further preferably lower than or equal to 80° C.

As the sacrificial film 270Rf and the sacrificial film 279Rf, it is preferable to use a film that can be removed by a wet etching method. Using a wet etching method can reduce damage to the EL film 172Rf in processing the sacrificial film 270Rf and the sacrificial film 279Rf, as compared with the case of using a dry etching method.

The sacrificial film 270Rf and the sacrificial film 279Rf can be formed by a sputtering method, an ALD method (a thermal ALD method, a PEALD method, or the like), a CVD method, or a vacuum evaporation method, for example.

Note that the sacrificial film 270Rf, which is formed over and in contact with the EL film 172Rf, is preferably formed by a formation method that causes less damage to the EL film 172Rf than a formation method for the sacrificial film 279Rf. For example, the sacrificial film 270Rf is preferably formed by an ALD method or a vacuum evaporation method rather than a sputtering method.

As the sacrificial film 270Rf and the sacrificial film 279Rf, it is possible to use one or more of a metal film, an alloy film, a metal oxide film, a semiconductor film, an organic insulating film, and an inorganic insulating film, for example.

For each of the sacrificial film 270Rf and the sacrificial film 279Rf, it is possible to use a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials, for example. It is particularly preferable to use a low-melting-point material such as aluminum or silver. A metal material capable of blocking ultraviolet rays is preferably used for one or both of the sacrificial film 270Rf and the sacrificial film 279Rf, in which case the EL film 172Rf can be inhibited from being irradiated with ultraviolet rays and deteriorating.

For the sacrificial film 270Rf and the sacrificial film 279Rf, a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon can be used.

Note that an element M (M is one or more kinds selected from aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used instead of gallium described above. Specifically, M is preferably one or more kinds selected from gallium, aluminum, and yttrium.

As the sacrificial film, a film containing a material having a light-blocking property with respect to light, particularly ultraviolet rays, can be used. For example, a film having a property of reflecting ultraviolet rays or a film absorbing ultraviolet rays can be used. Although a variety of materials such as a metal, an insulator, a semiconductor, and a metalloid that have a property of blocking ultraviolet rays can be used as the material having a light-blocking property, the sacrificial film is preferably a film capable of being processed by etching and is particularly preferably a film having good processability because part or the whole of the sacrificial film is removed in a later step.

The use of a film containing a material having a light-blocking property with respect to ultraviolet rays for the sacrificial film can inhibit the EL layer from being irradiated with ultraviolet rays in a light exposure step, for example. The EL layer is inhibited from being damaged by ultraviolet rays, so that the reliability of the light-emitting element can be improved.

Note that the film containing a material having a light-blocking property with respect to ultraviolet rays can have the same effect even when used as a material of a protective film 271f that is described later.

For the sacrificial film, a material with a high affinity for a semiconductor fabrication process can be used. As a material with a high affinity for a semiconductor fabrication process, a semiconductor material such as silicon or germanium can be used. Alternatively, an oxide or a nitride of the semiconductor material can be used. Alternatively, a non-metallic material such as carbon or a compound thereof can be used. A metal such as titanium, tantalum, tungsten, chromium, or aluminum or an alloy containing at least one of these metals can be used. Alternatively, an oxide containing the above-described metal, such as titanium oxide or chromium oxide, or a nitride such as titanium nitride, chromium nitride, or tantalum nitride can be used.

As the sacrificial film 270Rf and the sacrificial film 279Rf, a variety of inorganic insulating films that can be used as the protective layer 273 can be used. In particular, an oxide insulating film is preferable because its adhesion to the EL film 172Rf is higher than that of a nitride insulating film. For example, an inorganic insulating material such as aluminum oxide, hafnium oxide, or silicon oxide can be used for the sacrificial film 270Rf and the sacrificial film 279Rf. As the sacrificial film 270Rf and the sacrificial film 279Rf, an aluminum oxide film can be formed by an ALD method, for example. The use of an ALD method is preferable because damage to a base (in particular, the EL layer) can be reduced.

For example, an inorganic insulating film (e.g., an aluminum oxide film) formed by an ALD method can be used as the sacrificial film 270Rf, and an inorganic film (e.g., an In—Ga—Zn oxide film, an aluminum film, or a tungsten film) formed by a sputtering method can be used as the sacrificial film 279Rf.

Note that the same inorganic insulating film can be used for both the sacrificial film 270Rf and the protective layer 271 that is to be formed later. For example, an aluminum oxide film formed by an ALD method can be used for both the sacrificial film 270Rf and the protective layer 271. Here, for the sacrificial film 270Rf and the protective layer 271, the same film-formation condition may be used or different film-formation conditions may be used. For example, when the sacrificial film 270Rf is formed under conditions similar to those of the protective layer 271, the sacrificial film 270Rf can be an insulating layer having a high barrier property against at least one of water and oxygen. Meanwhile, the sacrificial film 270Rf is a layer most or all of which is to be removed in a later step, and thus is preferably easy to process. Therefore, the sacrificial film 270Rf is preferably formed with a substrate temperature lower than the substrate temperature at the time of formation of the protective layer 271.

One or both of the sacrificial film 270Rf and the sacrificial film 279Rf may be formed using an organic material. For example, as the organic material, a material that can be dissolved in a solvent chemically stable with respect to at least the uppermost film of the EL film 172Rf may be used. Specifically, a material that is dissolved in water or alcohol can be suitably used. In forming a film of such a material, it is preferable to apply the material dissolved in a solvent such as water or alcohol by a wet film formation method and then perform heat treatment for evaporating the solvent. At this time, the heat treatment is preferably performed in a reduced-pressure atmosphere, in which case the solvent can be removed at a low temperature in a short time and thermal damage to the EL film 172Rf can be reduced accordingly.

For each of the sacrificial film 270Rf and the sacrificial film 279Rf, an organic resin such as polyvinyl alcohol (PVA), polyvinyl butyral, polyvinylpyrrolidone, polyethylene glycol, polyglycerin, pullulan, water-soluble cellulose, an alcohol-soluble polyamide resin, or a fluororesin such as perfluoropolymer may be used.

For example, an organic film (e.g., a PVA film) formed by an evaporation method or the above wet film formation method can be used as the sacrificial film 270Rf, and an inorganic film (e.g., a silicon nitride film) formed by a sputtering method can be used as the sacrificial film 279Rf.

Note that in the display device of one embodiment of the present invention, part of the sacrificial film remains as the sacrificial layer in some cases.

Subsequently, a resist mask 180R is formed over the sacrificial film 279Rf as illustrated in FIG. 10B. The resist mask 180R can be formed by application of a photosensitive material (photoresist), light exposure, and development. Either a positive resist material or a negative resist material may be used to form the resist mask 180R.

Next, as illustrated in FIG. 10B and FIG. 10C, part of the sacrificial film 279Rf is removed using the resist mask 180R, so that the sacrificial layer 279R is formed. Then, the resist mask 180R is removed.

Next, as illustrated in FIG. 10C and FIG. 10D, part of the sacrificial film 270Rf is removed using the sacrificial layer 279R as a mask (also referred to as a hard mask), so that the sacrificial layer 270R is formed.

The sacrificial film 270Rf and the sacrificial film 279Rf can be processed by a wet etching method or a dry etching method.

Using a wet etching method can reduce damage to the EL film 172Rf in processing the sacrificial film 270Rf and the sacrificial film 279Rf, as compared with the case of using a dry etching method. In the case of using a wet etching method, it is preferable to use a developer, a tetramethylammonium hydroxide (TMAH) aqueous solution, dilute hydrofluoric acid, oxalic acid, phosphoric acid, acetic acid, nitric acid, or a mixed solution containing two or more of these acids, for example. In the case of using a wet etching method, a mixed acid chemical solution containing water, phosphoric acid, diluted hydrofluoric acid, and nitric acid may be used. A chemical solution used for the wet etching treatment may be alkaline or acid. Meanwhile, a dry etching method enables more anisotropic etching than a wet etching method; thus, the use of a dry etching method achieves microfabrication compared with the use of a wet etching method.

Since the EL film 172Rf is not exposed in processing the sacrificial film 279Rf, the range of choices of the processing method is wider than that for processing the sacrificial film 270Rf. Specifically, even in the case where a gas containing oxygen is used as the etching gas in the processing of the sacrificial film 279Rf, deterioration of the EL film 172Rf can be inhibited.

The resist mask 180R can be removed by ashing using oxygen plasma, for example. Alternatively, an oxygen gas and CF₄, C₄F₈, SF₆, CHF₃, Cl₂, H₂O, BCl₃, or a Group 18 element may be used. He can be used as the Group 18 element, for example. Alternatively, the resist mask 180R may be removed by wet etching. At this time, the sacrificial film 279Rf is positioned on the outermost surface and the EL film 172Rf is not exposed; thus, the EL film 172Rf can be inhibited from being damaged in the step of removing the resist mask 180R. In addition, the range of choices of the method for removing the resist mask 180R can be widened.

Next, as illustrated in FIG. 10C and FIG. 10D, the EL film 172Rf is processed to form the EL layer 172R. For example, part of the EL film 172Rf is removed by etching using the sacrificial layer 279R and the sacrificial layer 270R as masks, so that the EL layer 172R is formed. Although not illustrated in FIG. 10D, a depressed portion is sometimes formed in a region of the insulating layer 363 that does not overlap with the EL layer 172R by etching treatment for the EL film 172Rf.

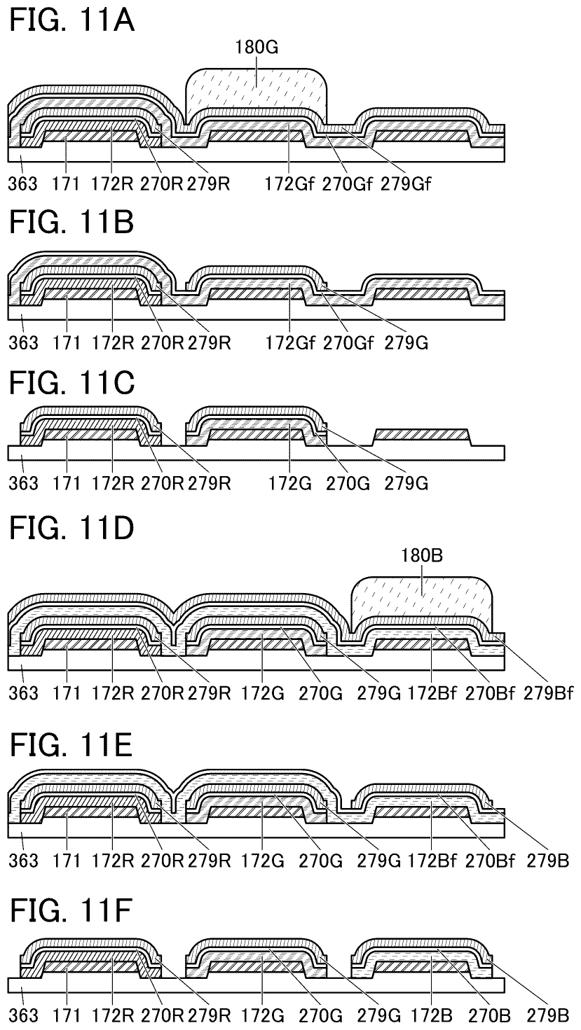

Next, as illustrated in FIG. 11A, an EL film 172Gf to be the EL layer 172G later is formed over the conductive layer 171, the sacrificial layer 279R, and the insulating layer 363. The EL film 172Gf can be formed by a method similar to a method that can be employed to form the EL film 172Rf.

Next, as illustrated in FIG. 11A, a sacrificial film 270Gf to be the sacrificial layer 270G later and a sacrificial film 279Gf to be a sacrificial layer 279G later are sequentially formed over the EL film 172Gf. Next, a resist mask 180G is formed. The materials and the formation methods of the sacrificial film 270Gf and the sacrificial film 279Gf are similar to conditions applicable to the sacrificial film 270Rf and the sacrificial film 279Rf. The materials and the formation method of the resist mask 180G are similar to conditions applicable to the resist mask 180R.

Subsequently, as illustrated in FIG. 11A and FIG. 11B, part of the sacrificial film 279Gf is removed using the resist mask 180G, so that the sacrificial layer 279G is formed. Then, the resist mask 180G is removed. For the formation of the sacrificial layer 279G and the removal of the resist mask 180G, methods similar to methods that can be employed for the formation of the sacrificial layer 279R and the removal of the resist mask 180R can be used, respectively.

Next, as illustrated in FIG. 11B and FIG. 11C, part of the sacrificial film 270Gf is removed using the sacrificial layer 279G as a mask, so that the sacrificial layer 270G is formed. Next, the EL film 172Gf is processed to form the EL layer 172G. For example, part of the EL film 172Gf is removed by etching using the sacrificial layer 279G and the sacrificial layer 270G as masks, so that the EL layer 172G is formed. For the formation of the sacrificial layer 270G and the formation of the EL layer 172G, methods similar to methods that can be employed for the formation of the sacrificial layer 270R and the formation of the EL layer 172R can be used, respectively.

Next, as illustrated in FIG. 11D, an EL film 172Bf to be the EL layer 172B later is formed over the conductive layer 171, the sacrificial layer 279R, the sacrificial layer 279G, and the insulating layer 363. The EL film 172Bf can be formed by a method similar to a method that can be employed to form the EL film 172Rf.

Next, as illustrated in FIG. 11D, a sacrificial film 270Bf to be the sacrificial layer 270B later and a sacrificial film 279Bf to be a sacrificial layer 279B later are sequentially formed over the EL film 172Bf. Next, a resist mask 180B is formed. The materials and the formation methods of the sacrificial film 270Bf and the sacrificial film 279Bf are similar to conditions applicable to the sacrificial film 270Rf and the sacrificial film 279Rf. The materials and the formation method of the resist mask 180B are similar to conditions applicable to the resist mask 180R.

Next, as illustrated in FIG. 11D and FIG. 11E, part of the sacrificial film 279Bf is removed using the resist mask 180B, so that the sacrificial layer 279B is formed. Then, the resist mask 180B is removed. For the formation of the sacrificial layer 279B and the removal of the resist mask 180B, methods similar to methods that can be employed for the formation of the sacrificial layer 279R and the removal of the resist mask 180R can be used, respectively.

Next, as illustrated in FIG. 11E and FIG. 11F, part of the sacrificial film 270Bf is removed using the sacrificial layer 279B as a mask, so that the sacrificial layer 270B is formed. Next, the EL film 172Bf is processed to form the EL layer 172B. For example, part of the EL film 172Bf is removed by etching using the sacrificial layer 279B and the sacrificial layer 270B as masks, so that the EL layer 172B is formed. For the formation of the sacrificial layer 270B and the formation of the EL layer 172B, methods similar to methods that can be employed for the formation of the sacrificial layer 270R and the formation of the EL layer 172R can be used, respectively.

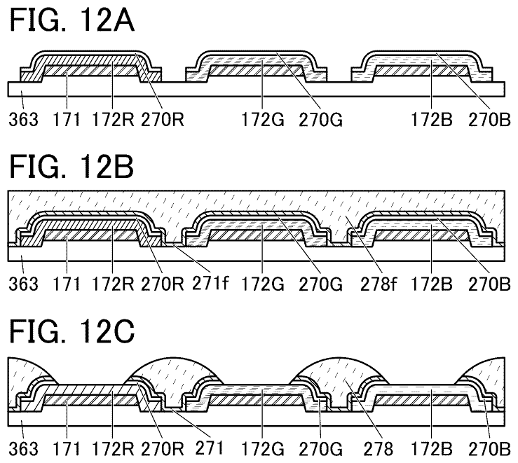

Next, as illustrated in FIG. 11F and FIG. 12A, the sacrificial layer 279R, the sacrificial layer 279G, and the sacrificial layer 279B are preferably removed. Depending on the later steps, the sacrificial layer 270R, the sacrificial layer 270G, the sacrificial layer 270B, the sacrificial layer 279R, the sacrificial layer 279G, and the sacrificial layer 279B remain in the display device in some cases. The sacrificial layer 279R, the sacrificial layer 279G, and the sacrificial layer 279B are removed at this stage, the sacrificial layer 279R, the sacrificial layer 279G, and the sacrificial layer 279B can be prevented from remaining in the display device. For example, in the case where conductive materials are used for the sacrificial layer 279R, the sacrificial layer 279G, and the sacrificial layer 279B, removing the sacrificial layer 279R, the sacrificial layer 279G, and the sacrificial layer 279B in advance can inhibit generation of leakage current, formation of capacity, and the like due to the remaining sacrificial layer 279R, sacrificial layer 279G, and sacrificial layer 279B.

Although the case where the sacrificial layer 279R, the sacrificial layer 279G, and the sacrificial layer 279B are removed is exemplified in this embodiment, the sacrificial layer 279R, the sacrificial layer 279G, and the sacrificial layer 279B are not necessarily removed.

The step of removing the sacrificial layers can be performed by a method similar to that for the step of processing the sacrificial layers. In particular, using a wet etching method can reduce damage to the EL layer 172R, the EL layer 172G, and the EL layer 172B in removing the sacrificial layers, as compared with the case of using a dry etching method.

The sacrificial layers may be removed by being dissolved in a solvent such as water or alcohol. Examples of alcohol include ethyl alcohol, methyl alcohol, isopropyl alcohol (IPA), and glycerin.

Next, as illustrated in FIG. 12B, the protective film 271f to be the protective layer 271 later is formed to cover the EL layer 172R, the EL layer 172G, the EL layer 172B, the sacrificial layer 270R, the sacrificial layer 270G, and the sacrificial layer 270B. The protective film 271f can be formed by an ALD method, a sputtering method, a CVD method, or a PECVD method, for example, and is preferably formed by an ALD method that can reduce deposition damage to the EL layer 172 and can achieve good coverage.

Then, as illustrated in FIG. 12B, an insulating film 278f to be the insulating layer 278 later is formed over the protective film 271f. For example, the insulating film 278f is preferably formed by spin coating using a photosensitive material.

Next, as illustrated in FIG. 12B and FIG. 12C, the insulating film 278f is processed to form the insulating layer 278 between the EL layers 172. Specifically, the insulating layer 278 is formed so that it overlaps with parts of the top surfaces of two EL layers 172 and includes a region positioned between the side surfaces of the two EL layers 172, for example.

In the case where a photosensitive material such as a photoresist is used for the insulating film 278f, the insulating layer 278 can be formed by light exposure and development on the insulating film 278f. In the case where a positive photosensitive material is used for the insulating film 278f, a region where the insulating layer 278 is not formed is irradiated with ultraviolet rays or visible rays in the light exposure step. In the case where a negative photosensitive material is used for the insulating film 278f, a region where the insulating layer 278 is formed is irradiated with ultraviolet rays or visible rays in the light exposure step.

Note that after the formation of the insulating layer 278, a residue (what is called a scum) in the development may be removed. For example, the residue can be removed by ashing using oxygen plasma. Etching may be performed so that the surface level of the insulating layer 278 is adjusted. The insulating layer 278 may be processed by ashing using oxygen plasma, for example.

Next, as illustrated in FIG. 12B and FIG. 12C, part of the protective film 271f is removed using the insulating layer 278 as a mask, so that the protective layer 271 is formed. Furthermore, the sacrificial layer 270R, the sacrificial layer 270G, and the sacrificial layer 270B are partly removed to form openings in the sacrificial layer 270R, the sacrificial layer 270G, and the sacrificial layer 270B. Accordingly, the top surfaces of the EL layer 172R, the EL layer 172G, and the EL layer 172B are exposed. Note that as illustrated in FIG. 12C, the sacrificial layer 270R, the sacrificial layer 270G, and the sacrificial layer 270B remain in regions overlapping with the insulating layer 278 or the protective layer 271 in some cases.

Next, the common layer 174 is formed over the EL layer 172R, the EL layer 172G, the EL layer 172B, and the insulating layer 278. The common layer 174 can be formed by an evaporation method (including a vacuum evaporation method), a transfer method, a printing method, an inkjet method, a coating method, or the like.

Next, the conductive layer 173 is formed over the common layer 174. The conductive layer 173 can be formed by a sputtering method, a vacuum evaporation method, or the like. Alternatively, the conductive layer 173 may be formed by stacking a film formed by a vacuum evaporation method and a film formed by a sputtering method.

Here, the conductive layer 173 can be formed successively without a process such as etching between formations of the common layer 174 and the conductive layer 173. For example, the common layer 174 and the conductive layer 173 can be successively formed in a vacuum. Accordingly, the lower surface of the conductive layer 173 can be a clean surface, as compared with the case where the common layer 174 is not provided in the display device.

Next, the protective layer 273 is formed over the conductive layer 173. The protective layer 273 can be formed by a vacuum evaporation method, a sputtering method, a CVD method, an ALD method, or the like. Through the above process, the display device having the structure illustrated in FIG. 7A can be fabricated.

In the above method for fabricating the display device, the EL layer 172R, the EL layer 172G, and the EL layer 172B are formed by forming an EL film over the entire surface and then processing the EL film by a photolithography method and an etching method, for example, and a fine metal mask is not used. Here, when the EL layer is formed using a fine metal mask, a deviation from the designed shape and position of an island-shaped light-emitting layer is caused due to various influences such as a low accuracy of the metal mask, positional deviation between the metal mask and a substrate, a warp of the metal mask, and vapor-scattering-induced expansion of the outline of a formed film; consequently, increasing the resolution and aperture ratio of a display device is difficult. Accordingly, a display device in which an EL layer is formed without using a fine metal mask can have higher resolution than a display device in which an EL layer is formed using a fine metal mask. The display device can have a high aperture ratio.

In this specification and the like, a device fabricated using a metal mask or an FMM (fine metal mask, high-resolution metal mask) is sometimes referred to as a device having an MM (metal mask) structure. In this specification and the like, a device fabricated without using a metal mask or an FMM is sometimes referred to as a device having an MML (metal maskless) structure.

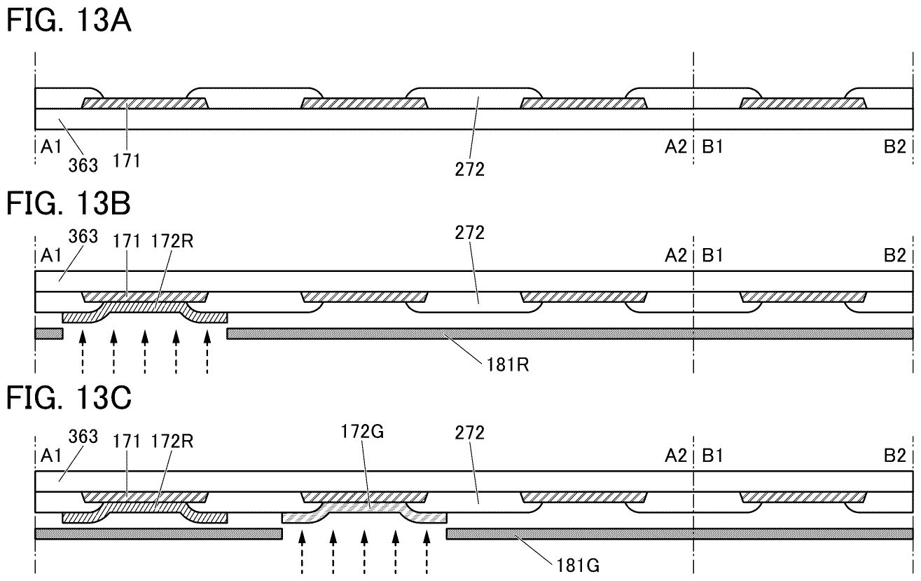

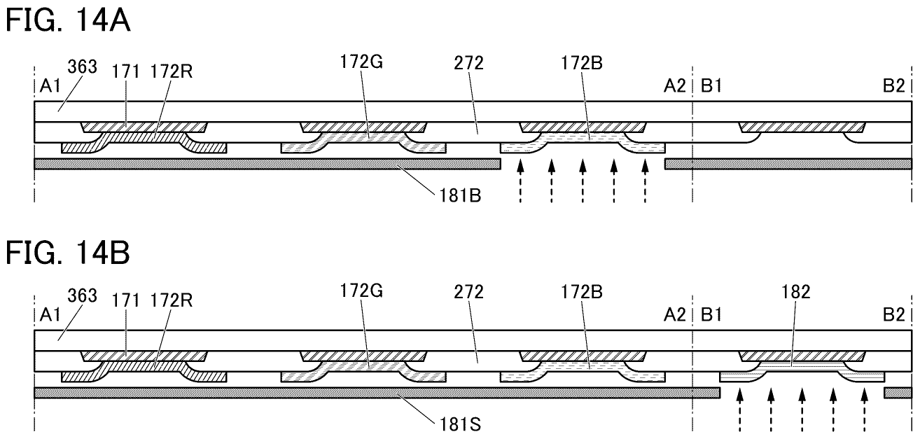

Next, an example of a method for fabricating the display device having the structures illustrated in FIG. 8A and FIG. 9A will be described below with reference to FIG. 13A to FIG. 14B. FIG. 13A to FIG. 14B illustrate a method for fabricating the structure of the cross-section illustrated in FIG. 8A along A1-A2 and the structure of the cross-section illustrated in FIG. 9A along B1-B2.

First, as illustrated in FIG. 13A, the conductive layer 171 is formed by a method similar to the method described with reference to FIG. 10A. Next, the insulating layer 272 is formed to cover the end portion of the conductive layer 171. For example, a film to be the insulating layer 272 is formed and then processed, whereby the insulating layer 272 can be formed. The film to be the insulating layer 272 can be formed by a spin coating method, a spray coating method, a screen printing method, a CVD method, a sputtering method, or a vacuum evaporation method, for example. The film to be the insulating layer 272 can be processed by a photolithography method and an etching method, for example.

Next, as illustrated in FIG. 13B, the EL layer 172R is formed using an FMM 181R. For example, the EL layer 172R is formed by a vacuum evaporation method or a sputtering method using the FMM 181R. Note that the EL layer 172R may be formed by an inkjet method. FIG. 13B illustrates a state where film formation is performed under a condition that the substrate is inverted so that a film formation surface faces downward, i.e., film formation is performed with a face-down system.

Next, as illustrated in FIG. 13C, the EL layer 172G is formed using an FMM 181G. The EL layer 172G can be formed by a method similar to that for the EL layer 172R. Similarly, as illustrated in FIG. 14A, the EL layer 172B is formed using an FMM 181B.

Next, as illustrated in FIG. 14B, the PD layer 182 is formed using an FMM 181S. For example, the PD layer 182 can be formed by a vacuum evaporation method or a sputtering method using the FMM 181S. Note that the PD layer 182 may be formed by an inkjet method.

Here, the EL layer 172R, the EL layer 172G, the EL layer 172B, and the PD layer 182 are formed after the insulating layer 272 is formed, whereby the FMM 181 (the FMM 181R, the FMM 181G, the FMM 181B, or the FMM 181S) can be prevented from being in contact with the conductive layer 171 and the FMM 181 can be brought close to the conductive layer 171. Thus, the EL layer 172 and the PD layer 182 can be inhibited from extending across an opening of the FMM 181. Thus, the adjacent EL layer 172 and PD layer 182 can be prevented from being in contact with each other. Accordingly, the reliability of the display device can be increased as compared with the case where the EL layer 172 and the PD layer 182 are formed using the FMM 181 without forming the insulating layer 272.

In the case where the EL layer 172R, the EL layer 172G, and the EL layer 172B are formed using the FMM 181, formation of a sacrificial layer, processing of the EL film by a photolithography method and an etching method, and the like are not necessary. Thus, in the case where the EL layer 172R, the EL layer 172G, and the EL layer 172B are formed using the FMM 181, the display device can be fabricated by a simple method as compared with the case where the EL layer 172R, the EL layer 172G, and the EL layer 172B are formed without the FMM 181. Thus, a display device can be fabricated at a low cost.

Next, the conductive layer 173 is formed over the EL layer 172R, the EL layer 172G, the EL layer 172B, the PD layer 182, and the insulating layer 272. As described above, the conductive layer 173 can be formed by a sputtering method, a vacuum evaporation method, or the like. Alternatively, the conductive layer 173 may be formed by stacking a film formed by an evaporation method and a film formed by a sputtering method.

Next, the protective layer 273 is formed over the conductive layer 173. As described above, the protective layer 273 can be formed by a vacuum evaporation method, a sputtering method, a CVD method, an ALD method, or the like. Through the above steps, the display device illustrated in FIG. 8A and FIG. 9A can be fabricated.

Note that the EL layer 172R, the EL layer 172G, the EL layer 172B, and the PD layer 182 included in the display device provided with the insulating layer 272 may be formed without using the FMM 181. For example, as illustrated in FIG. 10B to FIG. 11F, the EL layer 172R, the EL layer 172G, and the EL layer 172B may be formed in the following manner: an EL film is formed over the entire surface and then the EL film is processed by a photolithography method and an etching method, for example. Similarly, the PD layer 182 may be formed in the following manner: a PD film to be the PD layer 182 later is formed over the entire surface and then the PD film is processed by a photolithography method and an etching method, for example. In the case where the EL layer 172R, the EL layer 172G, the EL layer 172B, and the PD layer 182 are formed without using the FMM 181, the protective layer 271, the insulating layer 278, and the common layer 174 may be formed. Furthermore, in the case where the continuous EL layer 172W as illustrated in FIG. 8B is formed as the EL layer 172, the EL layer 172W can be formed without using the FMM 181; thus, the fabrication process of the display device can be simplified as compared with the case where the EL layer 172W is formed separately for each light-emitting element 63W using the FMM 181.

At least part of the structure examples, the drawings corresponding thereto, and the like described in this embodiment can be combined with the other structure examples, the other drawings, and the like as appropriate.

### Embodiment 2

In this embodiment, pixel layouts of a display device included in the electronic device of one embodiment of the present invention will be described.

There is no particular limitation on the arrangement of subpixels forming a pixel of the display device, and any of a variety of methods can be employed. Examples of the arrangement of subpixels include stripe arrangement, S-stripe arrangement, matrix arrangement, delta arrangement, Bayer arrangement, and pentile arrangement.

The top surface shape of the subpixel illustrated in a diagram in this embodiment corresponds to the top surface shape of a light-emitting region.

Examples of the top surface shape of the subpixel include polygons such as a triangle, a tetragon (including a rectangle and a square), and a pentagon; polygons with rounded corners; an ellipse; and a circle.

The range of the circuit layout for forming the subpixels is not limited to the range of the subpixels illustrated in a diagram and may be placed outside the range of the subpixels.

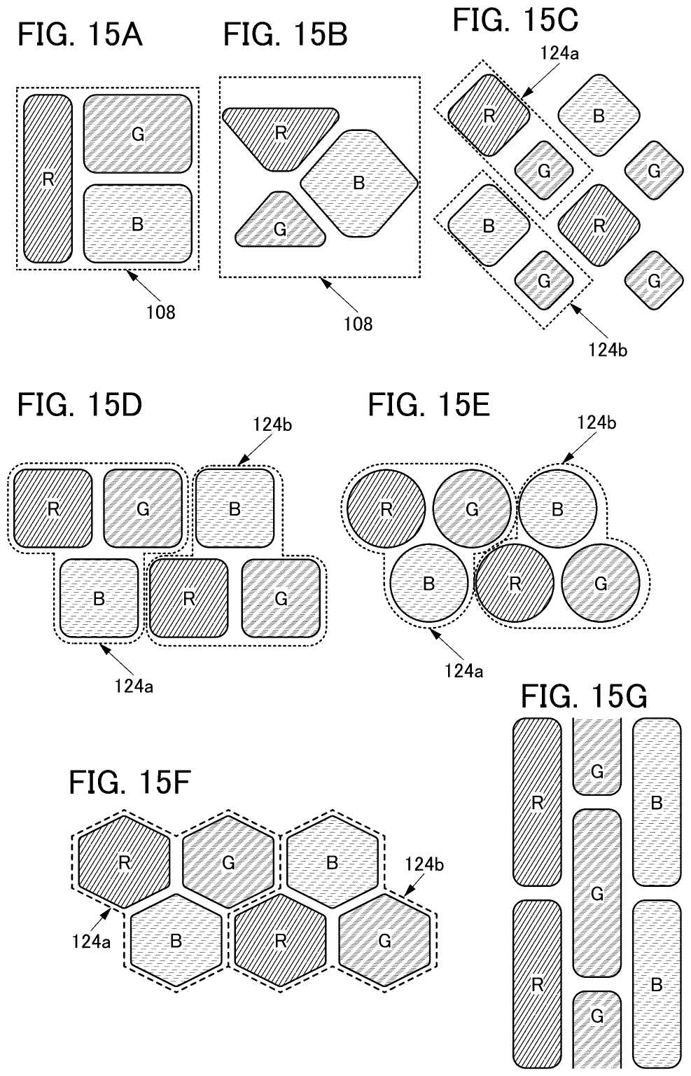

A pixel 108 illustrated in FIG. 15A employs S-stripe arrangement. The pixel 108 illustrated in FIG. 15A is composed of three subpixels: the subpixel R, the subpixel G, and the subpixel B.

The pixel 108 illustrated in FIG. 15B includes the subpixel R whose top surface shape is a rough trapezoid with rounded corners, the subpixel G whose top surface shape is a rough triangle with rounded corners, and the subpixel B whose top surface shape is a rough tetragon or rough hexagon with rounded corners. In addition, the subpixel R has a larger light-emitting area than the subpixel G. In this manner, the shapes and sizes of the subpixels can be determined independently. For example, the size of a subpixel including a light-emitting element with higher reliability can be smaller.

A pixel 124a and a pixel 124b illustrated in FIG. 15C employ PenTile arrangement. FIG. 15C illustrates an example where the pixels 124a each including the subpixel R and the subpixel G and the pixels 124b each including the subpixel G and the subpixel B are alternately arranged.

The pixels 124a and the pixels 124b illustrated in FIG. 15D to FIG. 15F employ delta arrangement. The pixel 124a includes two subpixels (the subpixel R and the subpixel G) in the upper row (first row) and one subpixel (the subpixel B) in the lower row (second row). The pixel 124b includes one subpixel (the subpixel B) in the upper row (first row) and two subpixels (the subpixel R and the subpixel G) in the lower row (second row).

FIG. 15D illustrates an example where a top surface shape of each subpixel is a rough tetragon with rounded corners, FIG. 15E illustrates an example where a top surface shape of each subpixel is a circle, and FIG. 15F illustrates an example where a top surface shape of each subpixel is a rough hexagon with rounded corners.

In FIG. 15F, the subpixels are placed inside the respective hexagonal regions that are arranged densely. Focusing on one of the subpixels, the subpixel is placed so as to be surrounded by six subpixels. The subpixels are arranged such that subpixels emitting light of the same color are not adjacent to each other. For example, focusing on the subpixel R, the subpixel R is surrounded by three subpixels G and three subpixels B that are alternately arranged.

FIG. 15G illustrates an example where subpixels of different colors are arranged in a zigzag manner. Specifically, the positions of the top sides of two subpixels arranged in the column direction (e.g., the subpixel R and the subpixel G or the subpixel G and the subpixel B) are not aligned in the top view.

For example, in each pixel illustrated in FIG. 15A to FIG. 15G, it is preferable that the subpixel R be a subpixel that emits red light, the subpixel G be a subpixel that emits green light, and the subpixel B be a subpixel that emits blue light. Note that the structure of the subpixels is not limited to this, and the colors and arrangement order of the subpixels can be determined as appropriate. For example, the subpixel G may be the subpixel that emits red light and the subpixel R may be the subpixel that emits green light.

In a photolithography method, as a pattern to be processed becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a subpixel may have a polygonal shape with rounded corners, an elliptical shape, a circular shape, or the like.

Furthermore, in the method for manufacturing the display apparatus of one embodiment of the present invention, the EL layer is processed into an island shape with the use of a resist mask. A resist film formed over the EL layer needs to be cured at a temperature lower than the upper temperature limit of the EL layer. Therefore, the resist film is insufficiently cured in some cases depending on the upper temperature limit of the material of the EL layer and the curing temperature of the resist material. An insufficiently cured resist film may have a shape different from a desired shape by processing. As a result, the top surface of the EL layer may have a polygonal shape with rounded corners, an elliptical shape, a circular shape, or the like. For example, when a resist mask with a square top surface is intended to be formed, a resist mask with a circular top surface may be formed, and the top surface of the EL layer may be circular.

To obtain a desired top surface shape of the EL layer, a technique of correcting a mask pattern in advance so that a transferred pattern agrees with a design pattern (an OPC (Optical Proximity Correction) technique) may be used. Specifically, with the OPC technique, a pattern for correction is added to a corner portion of a figure on a mask pattern, for example.

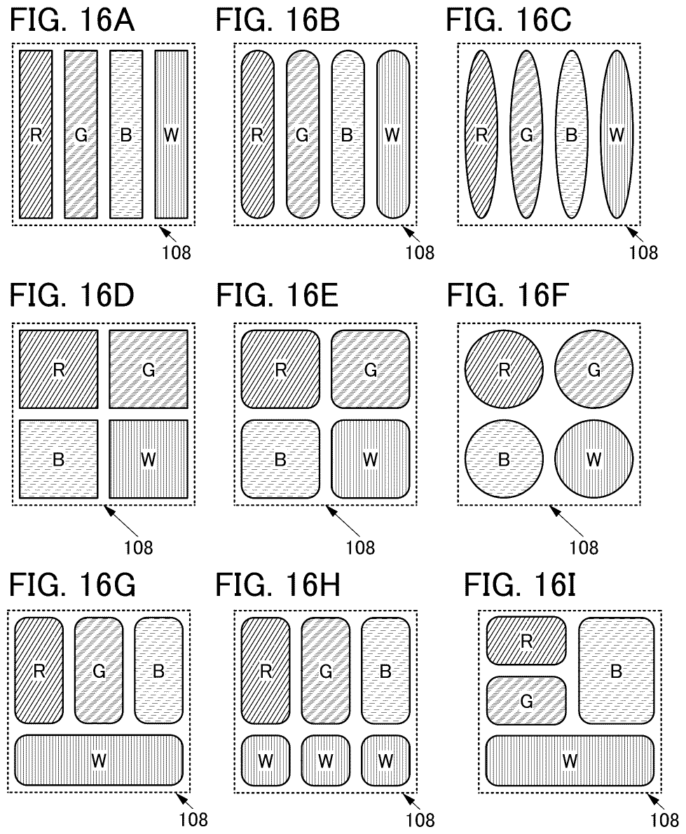

As illustrated in FIG. 16A to FIG. 16I, the pixel can include four types of subpixels.

The pixels 108 illustrated in FIG. 16A to FIG. 16C employ stripe arrangement.

FIG. 16A illustrates an example where each subpixel has a rectangular top surface shape, FIG. 16B illustrates an example where each subpixel has a top surface shape formed by combining two half circles and a rectangle, and FIG. 16C illustrates an example where each subpixel has an elliptical top surface shape.

The pixels 108 illustrated in FIG. 16D to FIG. 16F employ matrix arrangement.

FIG. 16D illustrates an example where each subpixel has a square top surface shape, FIG. 16E illustrates an example where each subpixel has a rough square top surface shape with rounded corners, and FIG. 16F illustrates an example where each subpixel has a circular top surface shape.

FIG. 16G and FIG. 16H each illustrate an example in which one pixel 108 is composed of two rows and three columns.

The pixel 108 illustrated in FIG. 16G includes three subpixels (the subpixel R, the subpixel G, and the subpixel B) in the upper row (first row) and one subpixel (the subpixel W) in the lower row (second row). In other words, the pixel 108 includes the subpixel R in the left column (first column), the subpixel G in the center column (second column), the subpixel B in the right column (third column), and the subpixel W across these three columns.

The pixel 108 illustrated in FIG. 16H includes three subpixels (the subpixel R, the subpixel G, and the subpixel B) in the upper row (first row) and three subpixels W in the lower row (second row). In other words, the pixel 108 includes the subpixel R and the subpixel W in the left column (first column), the subpixel G and the subpixel W in the middle column (second column), and the subpixel B and the subpixel W in the right column (third column). Matching the positions of the subpixels in the upper row and the lower row as illustrated in FIG. 16H enables dust that would be produced in the manufacturing process, for example, to be removed efficiently. Thus, a display device with high display quality can be provided.

In the pixel 108 illustrated in FIG. 16G and FIG. 16H, stripe arrangement is employed as the layout of the subpixel R, the subpixel G, and the subpixel B, whereby the display quality can be improved.

FIG. 16I illustrates an example in which one pixel 108 is composed of three rows and two columns.

The pixel 108 illustrated in FIG. 16I includes the subpixel R in the upper row (first row), the subpixel G in the center row (second row), the subpixel B across the first and second rows, and one subpixel (the subpixel W) in the lower row (third row). In other words, the pixel 108 includes the subpixel R and the subpixel G in the left column (first column), the subpixel B in the right column (second column), and the subpixel W across these two columns.

In the pixel 108 illustrated in FIG. 16I, so-called S stripe arrangement is employed as the layout of the subpixel R, the subpixel G, and the subpixel B, whereby the display quality can be improved.

The pixel 108 illustrated in FIG. 16A to FIG. 16I consists of four subpixels: the subpixel R, the subpixel G, the subpixel B, and the subpixel W. For example, the subpixel R can be a subpixel that emits red light, the subpixel G can be a subpixel that emits green light, the subpixel B can be a subpixel that emits blue light, and the subpixel W can be a subpixel that emits white light. Note that at least one of the subpixel R, the subpixel G, the subpixel B, and the subpixel W may be a subpixel that emits cyan light, a subpixel that emits magenta light, a subpixel that emits yellow light, or a subpixel that emits near-infrared light.

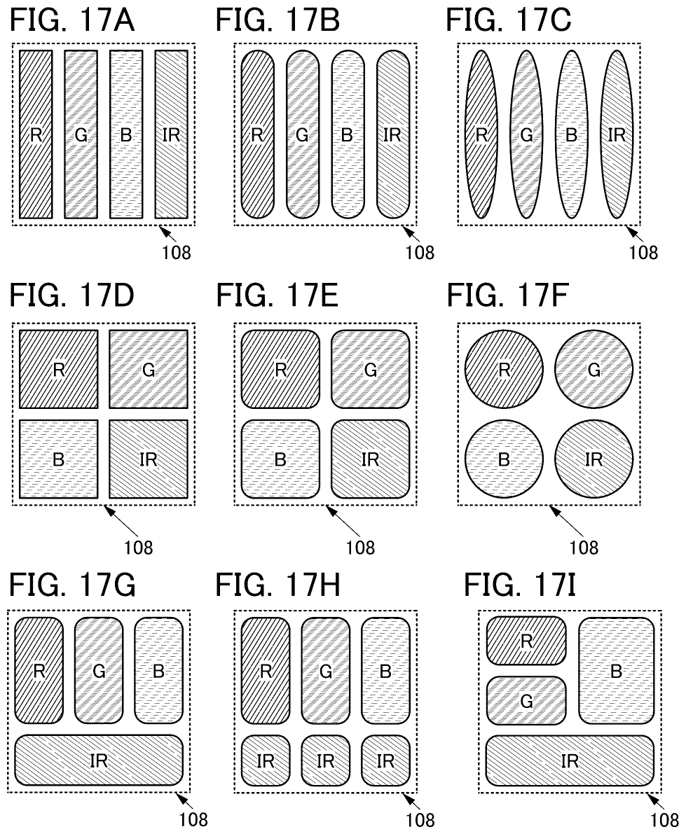

FIG. 17A to FIG. 171 illustrate examples in which the subpixel W included in the pixel 108 illustrated in FIG. 16A to FIG. 16I is replaced with the subpixel IR. The pixels illustrated in FIG. 15A to FIG. 15G, FIG. 16A to FIG. 16I, and FIG. 17A to FIG. 171 can be used as the pixel 23 included in the display device 41 and the pixel 27b included in the display device 44 described in Embodiment 1, for example.

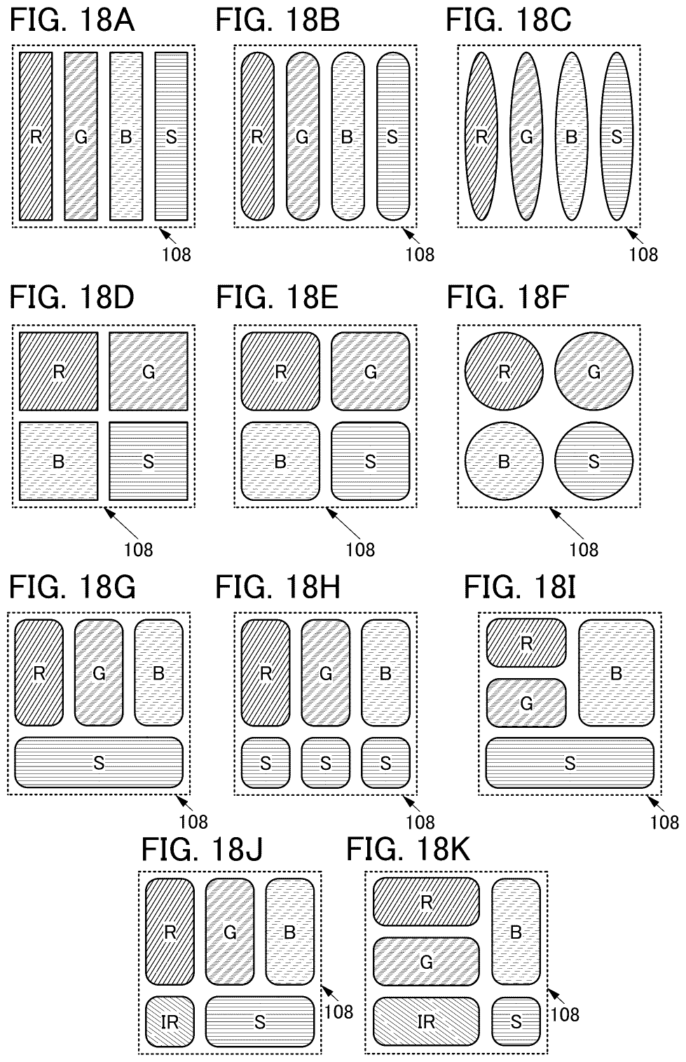

FIG. 18A to FIG. 181 are examples in which the subpixel W included in the pixel 108 illustrated in FIG. 16A to FIG. 16I is replaced with the subpixel S.

FIG. 18J and FIG. 18K illustrate examples in which the pixel 108 includes five types of subpixels, specifically the subpixel R, the subpixel G, the subpixel B, the subpixel IR, and the subpixel S.

FIG. 18J illustrates an example where one pixel 108 is composed of two rows and three columns. The pixel 108 illustrated in FIG. 18J includes three subpixels (the subpixel R, the subpixel G, and the subpixel B) in the upper row (first row) and two subpixels (the subpixel IR and the subpixel S) in the lower row (second row). In other words, the pixel 108 includes the subpixel R and the subpixel IR in the left column (first column), the subpixel G in the center column (second column), the subpixel B in the right column (third column), and the subpixel S across the second and third columns.

FIG. 18K illustrates an example where one pixel 108 is composed of three rows and two columns. The pixel 108 illustrated in FIG. 18K includes the subpixel R in the upper row (first row), the subpixel G in the center row (second row), the subpixel B across the first and second rows, and two subpixels (the subpixel IR and the subpixel S) in the lower row (third row). In other words, the pixel 108 includes the subpixel R, the subpixel G, and the subpixel IR in the left column (first column), and the subpixel B and the subpixel S in the right column (second column).

Note that the subpixel IR and the subpixel S may be interchanged with each other in the pixel 108 each illustrated in FIG. 18J and FIG. 18K. Alternatively, two subpixels IR or two subpixels S may be provided. That is, the subpixel S may be replaced with the subpixel IR. Alternatively, the subpixel IR may be replaced with the subpixel S.

The pixels illustrated in FIG. 18A to FIG. 18K can each be used as the pixel 27b included in the display device 44 described in Embodiment 1, for example.

As described above, the pixel composed of the subpixels each including the light-emitting element can employ any of a variety of layouts in the display device of one embodiment of the present invention.

At least part of the structure examples, the drawings corresponding thereto, and the like described in this embodiment can be combined with the other structure examples, the other drawings, and the like as appropriate.

### Embodiment 3

In this embodiment, a display device of one embodiment of the present invention will be described.

### [Display Module]

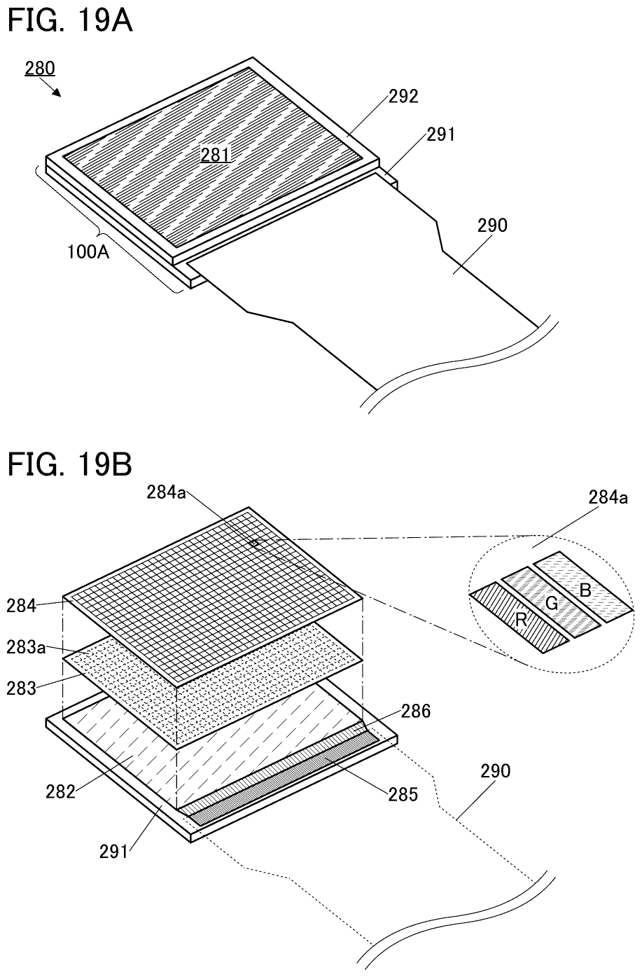

FIG. 19A illustrates a perspective view of a display module 280. The display module 280 includes a display device 100A and an FPC 290. Note that the display device included in the display module 280 is not limited to the display device 100A and may be any of a display device 100B to a display device 100G described later.

The display module 280 includes a substrate 291 and a substrate 292. The display module 280 includes a pixel portion 281. The pixel portion 281 is a region of the display module 280 where an image is displayed, and is a region where light emitted from pixels provided in a pixel portion 284 described later can be seen.

FIG. 19B illustrates a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. A terminal portion 285 to be connected to the FPC 290 is provided in a region that is over the substrate 291 and does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side of FIG. 19B. The pixel 284a can employ any of the structures described in the above embodiments. FIG. 19B illustrates an example where the pixel 284a has a structure similar to that of the pixel 23 illustrated in FIG. 3A1.

The pixel circuit portion 283 includes a plurality of pixel circuits 283a arranged periodically.

The pixel circuit 283a has a function of controlling the driving of the light-emitting element included in the pixel 284a. For example, the pixel circuit 283a can include at least one selection transistor, one current control transistor (driving transistor), and a capacitor for one light-emitting element. In this case, a gate signal is input to a gate of the selection transistor, and a data signal (also referred to as a video signal or an image signal) is input to a source or a drain of the selection transistor. Thus, an active-matrix display device is achieved.

The circuit portion 282 includes a circuit for driving the pixel circuits 283a in the pixel circuit portion 283. For example, one or both of a gate line driver circuit and a data line driver circuit are preferably included. In addition, at least one of an arithmetic circuit, a memory circuit, a power supply circuit, and the like may be included.

The FPC 290 functions as a wiring for supplying a data signal, a power supply potential, or the like to the circuit portion 282 from the outside. An IC may be mounted over the FPC 290.

The display module 280 can have a structure in which one or both of the pixel circuit portion 283 and the circuit portion 282 are stacked below the pixel portion 284; thus, the aperture ratio (the effective display area ratio) of the pixel portion 281 can be significantly high. For example, the aperture ratio of the pixel portion 281 can be greater than or equal to 40% and less than 100%, preferably greater than or equal to 50% and less than or equal to 95%, further preferably greater than or equal to 60% and less than or equal to 95%. Furthermore, the pixels 284a can be arranged extremely densely and thus the pixel portion 281 can have greatly high resolution. For example, the pixels 284a are preferably arranged in the pixel portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

### [Display Device 100A]

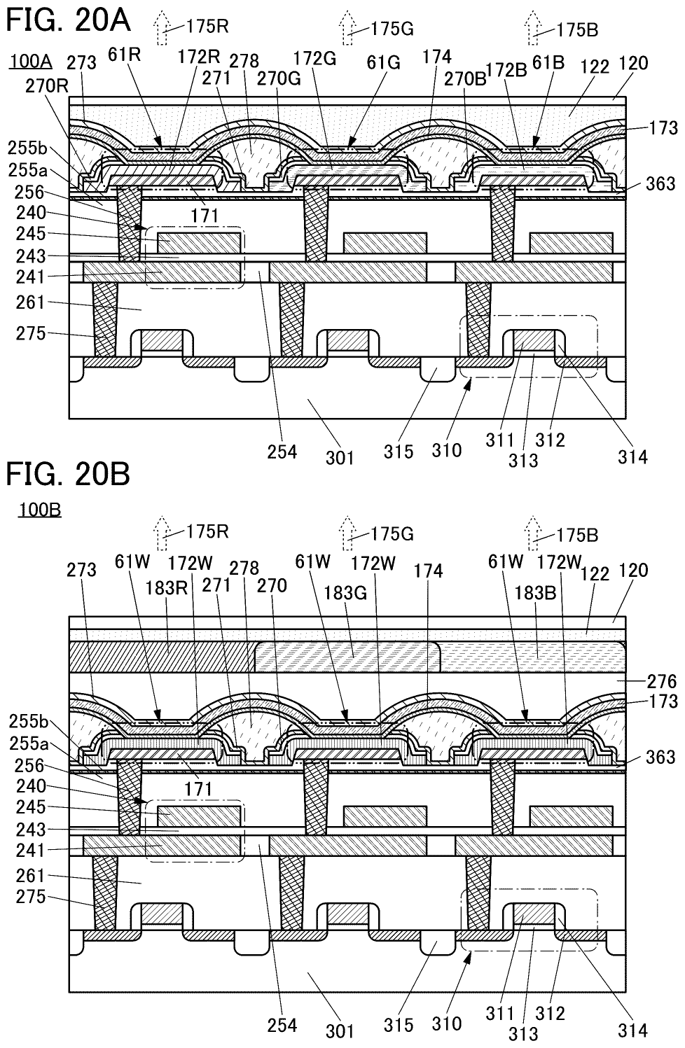

The display device 100A illustrated in FIG. 20A includes a substrate 301, the light-emitting element 61R, the light-emitting element 61G, the light-emitting element 61B, a capacitor 240, and a transistor 310.

The substrate 301 corresponds to the substrate 291 in FIG. 19A and FIG. 19B. The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, a pair of low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The pair of low-resistance regions 312 are regions where the substrate 301 is doped with an impurity, and function as a source and a drain. The insulating layers 314 are provided to cover the side surface of the conductive layer 311.

An element isolation layer 315 is provided between two adjacent transistors 310 so as to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned between these conductive layers. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 275 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255a is provided to cover the capacitor 240, an insulating layer 255b is provided over the insulating layer 255a, and the insulating layer 363 is provided over the insulating layer 255b. The light-emitting element 61R, the light-emitting element 61G, and the light-emitting element 61B are provided over the insulating layer 363. FIG. 20A illustrates an example where the light-emitting element 61R, the light-emitting element 61G, and the light-emitting element 61B have the stacked-layer structure illustrated in FIG. 7A. The light-emitting element 61R emits the light 175R, the light-emitting element 61G emits the light 175G, and the light-emitting element 61B emits the light 175B. Note that the display device 100A may include, for example, the light-emitting element 63R, the light-emitting element 63G, and the light-emitting element 63B illustrated in FIG. 8A instead of the light-emitting element 61R, the light-emitting element 61G, and the light-emitting element 61B. The same applies to display devices described later.

An insulator is provided in a region between adjacent light-emitting elements 61. For example, in FIG. 20A, the protective layer 271 and the insulating layer 278 over the protective layer 271 are provided in the region.

The EL layer 172R is provided to cover the top surface and the side surface of the conductive layer 171 included in the light-emitting element 61R. The EL layer 172G is provided to cover the top surface and the side surface of the conductive layer 171 included in the light-emitting element 61G. The EL layer 172B is provided to cover the top surface and the side surface of the conductive layer 171 included in the light-emitting element 61B. The sacrificial layer 270R is positioned over the EL layer 172R, the sacrificial layer 270G is positioned over the EL layer 172G, and the sacrificial layer 270B is positioned over the EL layer 172B.

The conductive layer 171 is electrically connected to one of the source and the drain of the transistor 310 through a plug 256 embedded in the insulating layer 243, the insulating layer 255a, the insulating layer 255b, and the insulating layer 363, the conductive layer 241 embedded in the insulating layer 254, and the plug 275 embedded in the insulating layer 261. The level of the upper surface of the insulating layer 363 is equal to or substantially equal to the level of the upper surface of the plug 256. A variety of conductive materials can be used for the plugs.

The protective layer 273 is provided over the light-emitting element 61R, the light-emitting element 61G, and the light-emitting element 61B. A substrate 120 is attached onto the protective layer 273 with a resin layer 122. The substrate 120 corresponds to the substrate 292 in FIG. 19A.

A light-blocking layer may be provided on a surface of the substrate 120 on the resin layer 122 side. A variety of optical members can be provided on the outer surface of the substrate 120. Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer surface of the substrate 120. For example, a glass layer or a silica layer (SiOₓ layer) is preferably provided as the surface protective layer to inhibit the surface contamination and generation of a scratch. The surface protective layer may be formed using DLC (diamond like carbon), aluminum oxide (AlOₓ), a polyester-based material, a polycarbonate-based material, or the like. For the surface protective layer, a material having a high transmittance with respect to visible light is preferably used. For the surface protective layer, a material with high hardness is preferably used.

For the substrate 120, glass, quartz, ceramic, sapphire, a resin, a metal, an alloy, a semiconductor, or the like can be used. For the substrate on the side from which light from the light-emitting element is extracted, a material that transmits the light is used. Furthermore, a polarizing plate may be used as the substrate 120.

The substrate 120 may be formed using a flexible material. This leads to higher flexibility of the display device. Examples of a flexible material include a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyether sulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used as the substrate 120.

In the case where a circularly polarizing plate overlaps with the display device, a highly optically isotropic substrate is preferably used as the substrate included in the display device. A highly optically isotropic substrate has a low birefringence. Note that it can be said that a highly optically isotropic substrate has a small amount of birefringence.

The absolute value of a retardation (phase difference) of a highly optically isotropic substrate is preferably less than or equal to 30 nm, further preferably less than or equal to 20 nm, still further preferably less than or equal to 10 nm.

Examples of the films having high optical isotropy include a triacetyl cellulose (TAC, also referred to as cellulose triacetate) film, a cycloolefin polymer (COP) film, a cycloolefin copolymer (COC) film, and an acrylic film.

When a film is used for the substrate and the film absorbs water, the shape of the display device might be changed, e.g., creases are generated. Thus, for the substrate, a film with a low water absorption rate is preferably used. For example, a film with a water absorption rate lower than or equal to 1% is preferably used, a film with a water absorption rate lower than or equal to 0.1% is further preferably used, and a film with a water absorption rate lower than or equal to 0.01% is still further preferably used.

As the resin layer 122, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. Alternatively, a two-liquid-mixture-type resin may be used. An adhesive sheet may be used, for example.

### [Display Device 100B]

The display device 100B illustrated in FIG. 20B includes the substrate 301, the light-emitting element 61W, the capacitor 240, and the transistor 310. FIG. 20B illustrates an example in which the light-emitting elements 61W each have the stacked-layer structure illustrated in FIG. 7B. The display device 100B includes the coloring layer 183R, the coloring layer 183G, and the coloring layer 183B, and each of the light-emitting elements 61W includes a region overlapping with one of the coloring layer 183R, the coloring layer 183G, and the coloring layer 183B. In the display device 100B, the light-emitting elements 61W can emit white light, for example. For example, the coloring layer 183R can transmit red light, the coloring layer 183G can transmit green light, and the coloring layer 183B can transmit blue light. In this manner, the display device 100B can emit the red light 175R, the green light 175G, and the blue light 175B, for example, to perform full color display.

### [Display Device 100C]

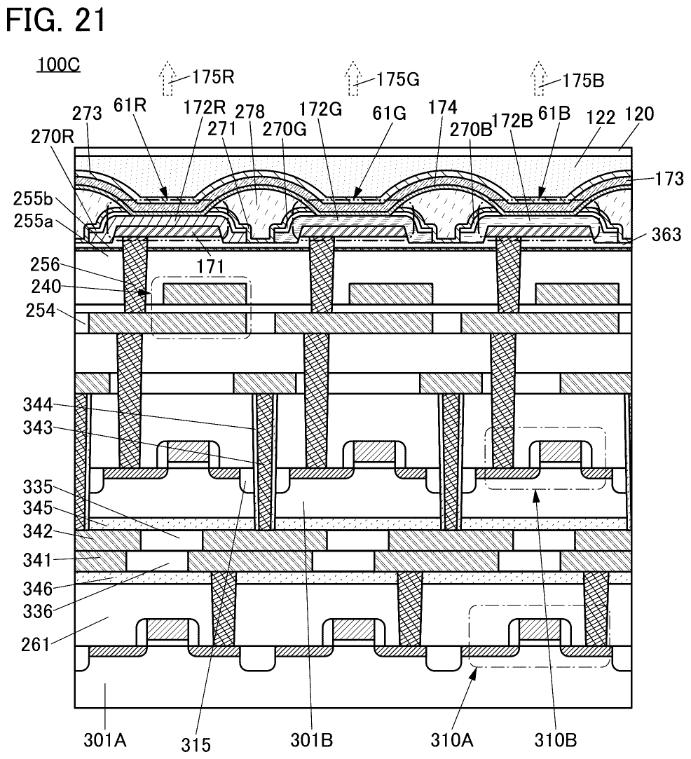

The display device 100C illustrated in FIG. 21 has a structure where a transistor 310A and a transistor 310B in each of which a channel is formed in a semiconductor substrate are stacked. Note that in the description of the display device below, portions similar to those of the above-described display device are not described in some cases.

In the display device 100C, a substrate 301B provided with the transistor 310B, the capacitor 240, and light-emitting elements 61 is bonded to a substrate 301A provided with the transistor 310A.

Here, an insulating layer 345 is preferably provided on the bottom surface of the substrate 301B. An insulating layer 346 is preferably provided over the insulating layer 261 provided over the substrate 301A. The insulating layer 345 and the insulating layer 346 are insulating layers functioning as protective layers and can inhibit diffusion of impurities into the substrate 301B and the substrate 301A. For the insulating layer 345 and the insulating layer 346, an inorganic insulating film that can be used for the protective layer 273 can be used.

The substrate 301B is provided with a plug 343 that penetrates the substrate 301B and the insulating layer 345. An insulating layer 344 is preferably provided to cover the side surface of the plug 343. The insulating layer 344 functions as a protective layer and can inhibit diffusion of impurities into the substrate 301B. For the insulating layer 344, an inorganic insulating film that can be used as the protective layer 273 can be used.

In addition, a conductive layer 342 is provided under the insulating layer 345 on the substrate 301B. The conductive layer 342 is preferably provided to be embedded in an insulating layer 335. The bottom surfaces of the conductive layer 342 and the insulating layer 335 are preferably planarized. Here, the conductive layer 342 is electrically connected to the plug 343.

On the other hand, a conductive layer 341 is provided over the insulating layer 346 over the substrate 301A. The conductive layer 341 is preferably provided to be embedded in the insulating layer 336. The top surfaces of the conductive layer 341 and the insulating layer 336 are preferably planarized.

The conductive layer 341 and the conductive layer 342 are bonded to each other, whereby the substrate 301A and the substrate 301B are electrically connected to each other. Here, improving the flatness of a plane formed by the conductive layer 342 and the insulating layer 335 and a plane formed by the conductive layer 341 and the insulating layer 336 allows the conductive layer 341 and the conductive layer 342 to be attached to each other favorably.

The conductive layer 341 and the conductive layer 342 are preferably formed using the same conductive material. For example, it is possible to use a metal film containing an element selected from Al, Cr, Cu, Ta, Ti, Mo, and W, or a metal nitride film containing any of the above elements as a component (e.g., a titanium nitride film, a molybdenum nitride film, or a tungsten nitride film). Copper is particularly preferably used for the conductive layer 341 and the conductive layer 342. In that case, it is possible to employ Cu-to-Cu (copper-to-copper) direct bonding (a technique for achieving electrical continuity by connecting Cu (copper) pads).

### [Display Device 100D]

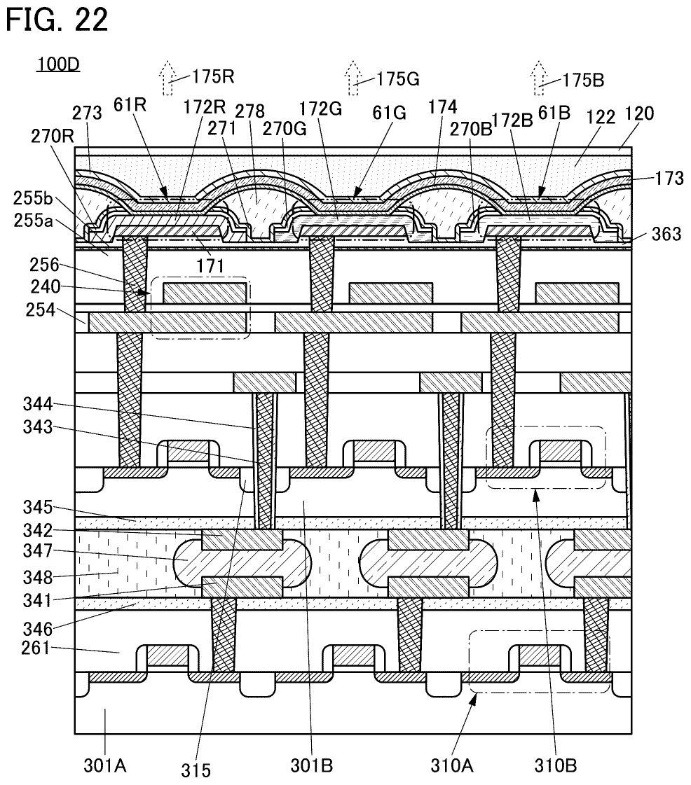

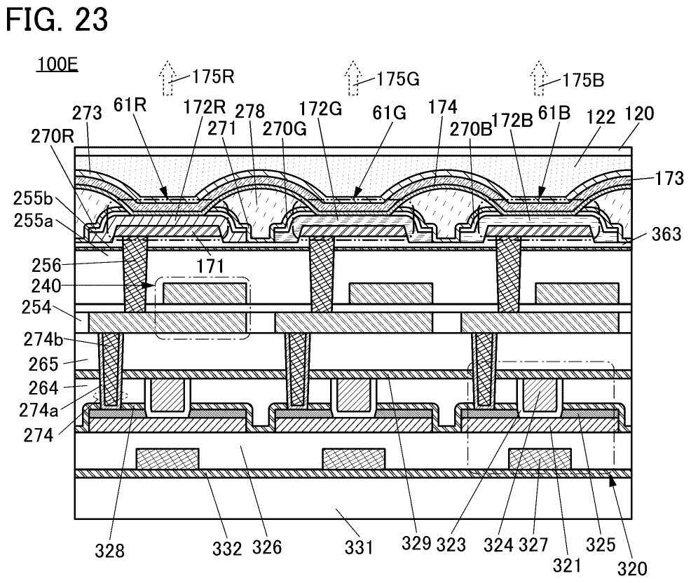

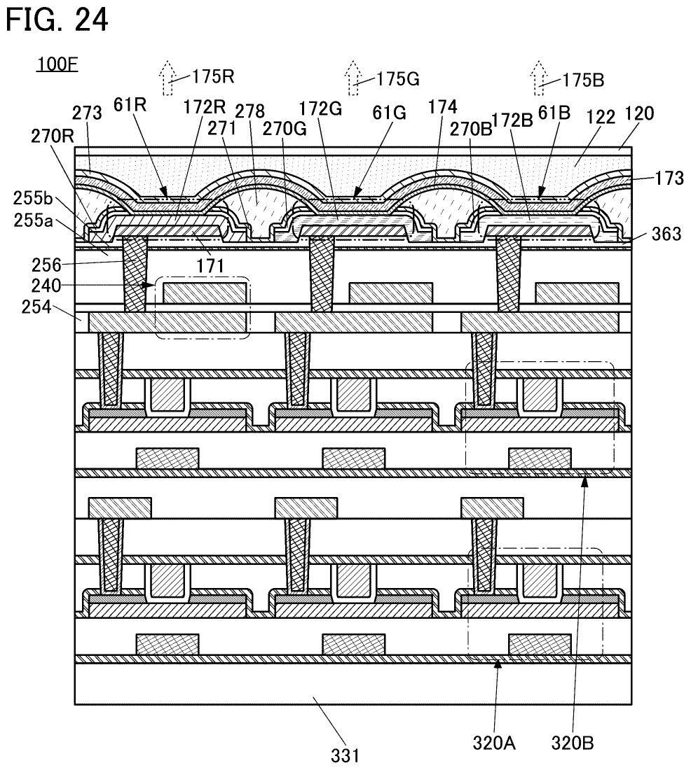

A display device 100D illustrated in FIG. 22 has a structure where the conductive layer 341 and the conductive layer 342 are bonded to each other through a bump 347.

As illustrated in FIG. 22, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. For another example, solder may be used for the bump 347. An adhesive layer 348 may be provided between the insulating layer 345 and the insulating layer 346. In the case where the bump 347 is provided, the insulating layer 335 and the insulating layer 336 may be omitted.

### [Display Device 100E]

A display device 100E illustrated in FIG. 23 differs from the display device 100A mainly in a structure of a transistor.

A transistor 320 is a transistor that contains a metal oxide (also referred to as an oxide semiconductor) in a semiconductor layer where a channel is formed (i.e., an OS transistor).

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIG. 19A and FIG. 19B. As the substrate 331, an insulating substrate or a semiconductor substrate can be used.

An insulating layer 332 is provided over the substrate 331. The insulating layer 332 functions as a barrier layer that prevents diffusion of impurities such as water and hydrogen from the substrate 331 into the transistor 320 and release of oxygen from the semiconductor layer 321 to the insulating layer 332 side. As the insulating layer 332, for example, a film in which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided so as to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least a region of the insulating layer 326 that is in contact with the semiconductor layer 321. The top surface of the insulating layer 326 is preferably planarized.

The semiconductor layer 321 is provided over the insulating layer 326. The semiconductor layer 321 preferably includes a metal oxide film having semiconductor characteristics. The pair of conductive layers 325 is provided over and in contact with the semiconductor layer 321 and functions as a source electrode and a drain electrode.

An insulating layer 328 is provided to cover the top and side surfaces of the pair of conductive layers 325, the side surface of the semiconductor layer 321, and the like, and an insulating layer 264 is provided over the insulating layer 328. The insulating layer 328 functions as a barrier layer that prevents diffusion of impurities such as water or hydrogen from the insulating layer 264 or the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layer 328 and the insulating layer 264. The insulating layer 323 that is in contact with the side surfaces of the insulating layer 264, the insulating layer 328, and the conductive layer 325 and the top surface of the semiconductor layer 321, and the conductive layer 324 over the insulating layer 323 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so that they are level or substantially level with each other, and an insulating layer 329 and an insulating layer 265 are provided to cover these layers.

The insulating layer 264 and the insulating layer 265 function as interlayer insulating layers. The insulating layer 329 functions as a barrier layer that prevents diffusion of impurities such as water and hydrogen from the insulating layer 265 and the like into the transistor 320. For the insulating layer 329, an insulating film similar to the insulating layer 328 and the insulating layer 332 can be used.

A plug 274 electrically connected to one of the pair of conductive layers 325 is provided so as to be embedded in the insulating layer 265, the insulating layer 329, the insulating layer 264, and the insulating layer 328. Here, the plug 274 preferably includes a conductive layer 274a covering the side surface of the opening formed in the insulating layer 265, the insulating layer 329, the insulating layer 264, and the insulating layer 328 and part of the top surface of the conductive layer 325, and a conductive layer 274b in contact with the top surface of the conductive layer 274a. For the conductive layer 274a, a conductive material that does not easily allow diffusion of hydrogen and oxygen is preferably used.

### [Display Device 100F]

A display device 100F illustrated in FIG. 24 has a structure where a transistor 320A and a transistor 320B each including an oxide semiconductor in a semiconductor where a channel is formed are stacked.

The description of the display device 100E can be referred to for the transistor 320A, the transistor 320B, and the components around them.

Although the structure in which two transistors including an oxide semiconductor are stacked is described, the present invention is not limited thereto. For example, three or more transistors may be stacked.

### [Display Device 100G]

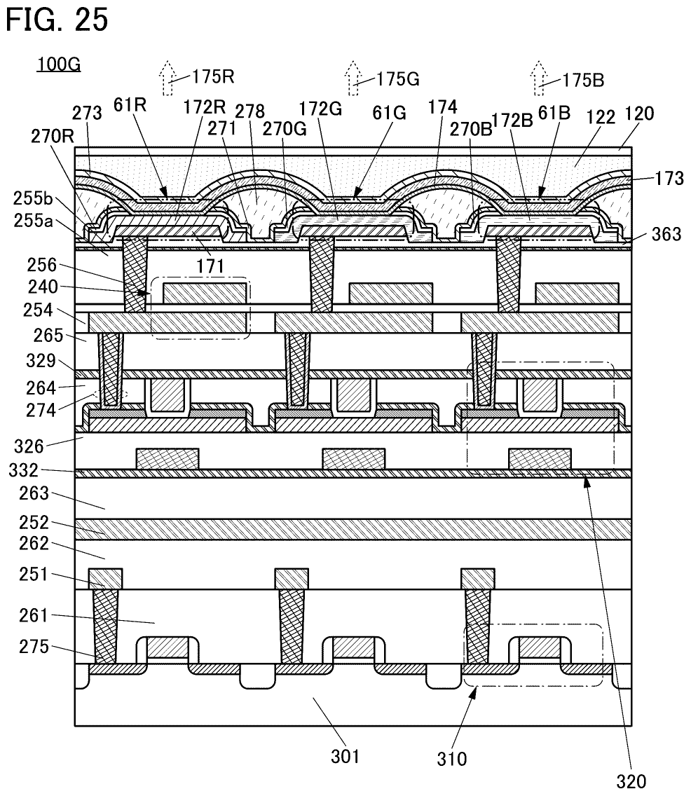

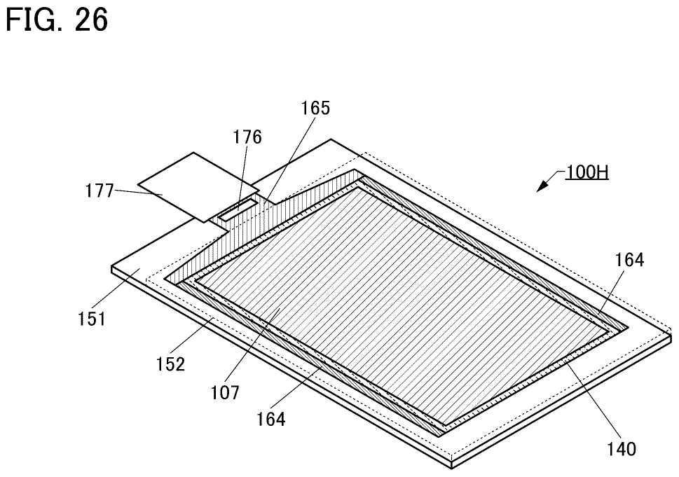

The display device 100G illustrated in FIG. 25 has a structure where the transistor 310 having a channel formed in the substrate 301 and the transistor 320 including a metal oxide in a semiconductor layer where a channel is formed are stacked.

An insulating layer 261 is provided so as to cover the transistor 310, and a conductive layer 251 is provided over the insulating layer 261. An insulating layer 262 is provided so as to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. An insulating layer 265 is provided so as to cover the transistor 320, and a capacitor 240 is provided over the insulating layer 265. The capacitor 240 and the transistor 320 are electrically connected to each other through the plug 274.

The transistor 320 can be used as a transistor included in the pixel circuit. The transistor 310 can be used as a transistor included in the pixel circuit. Alternatively, the transistor 310 can be used as a transistor included in a driver circuit (a gate line driver circuit, a data line driver circuit, or the like) for driving the pixel circuit. The transistor 310 and the transistor 320 can also be used as transistors included in a variety of circuits such as an arithmetic circuit and a memory circuit.

With such a structure, not only the pixel circuit but also the driver circuit, for example, can be formed directly under the light-emitting element; thus, the display device can be downsized as compared with the case where the driver circuit is provided around a display region.

### [Display Device 100H]

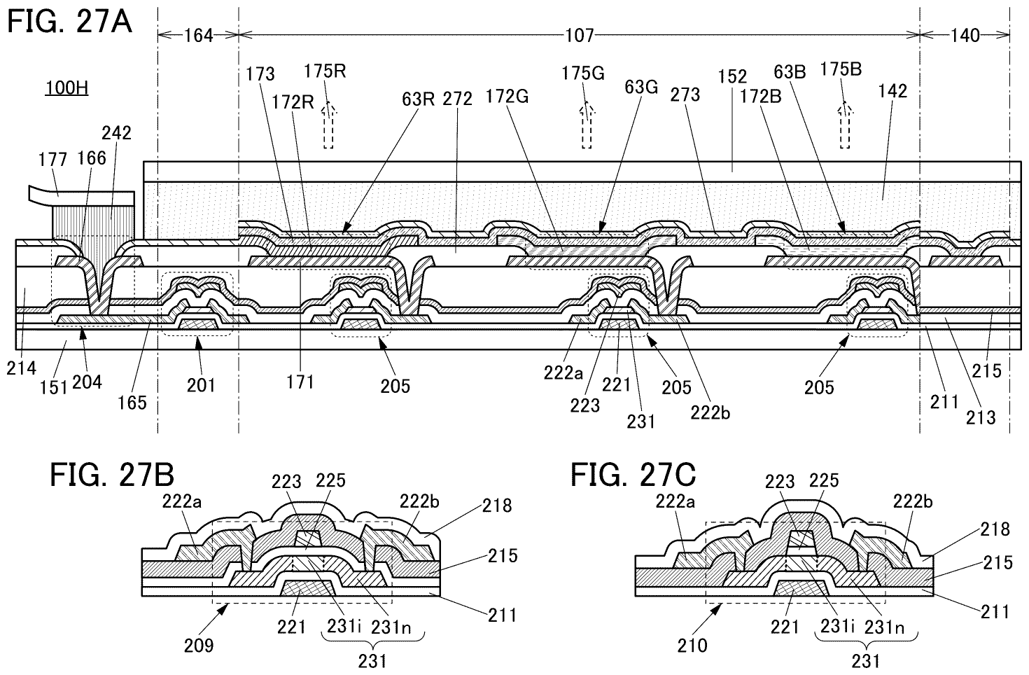

FIG. 26 is a perspective view of a display device 100H, and FIG. 27A is a cross-sectional view of the display device 100H.

The display device 100H has a structure in which a substrate 152 and a substrate 151 are bonded to each other. In FIG. 26, the substrate 152 is denoted by a dashed line.

The display device 100H includes a pixel portion 107, a connection portion 140, a circuit 164, a wiring 165, and the like. FIG. 26 illustrates an example where an IC 176 and an FPC 177 are mounted on the display device 100H. Thus, the structure illustrated in FIG. 26 can be regarded as a display module including the display device 100H, the IC (integrated circuit), and the FPC. Here, a display device in which a substrate is equipped with a connector such as an FPC or mounted with an IC is referred to as a display module.

The connection portion 140 is provided outside the pixel portion 107. The connection portion 140 can be provided along one or more sides of the pixel portion 107. The number of connection portions 140 can be one or more. FIG. 26 illustrates an example where the connection portion 140 is provided to surround the four sides of the pixel portion 107. A common electrode of a light-emitting element is electrically connected to a conductive layer in the connection portion 140, so that a potential can be supplied to the common electrode.

As the circuit 164, a gate line driver circuit can be used, for example.

A signal and power can be supplied to the pixel portion 107 and the circuit 164 through the wiring 165. The signal and power are input to the wiring 165 from the outside through the FPC 177 or from the IC 176.

FIG. 26 illustrates an example where the IC 176 is provided over the substrate 151 by a COG (Chip On Glass) method, a COF (Chip On Film) method, or the like. An IC including a gate line driver circuit, a data line driver circuit, or the like can be used as the IC 176, for example. Note that the display device 100H and the display module are not necessarily provided with an IC. The IC may be mounted on the FPC by a COF method, for example.

FIG. 27A illustrates an example of cross sections of part of a region including the FPC 177, part of the circuit 164, part of the pixel portion 107, part of the connection portion 140, and part of a region including an end portion of the display device 100H.

The display device 100H illustrated in FIG. 27A includes a transistor 201, a transistor 205, the light-emitting element 63R that emits the red light 175R, the light-emitting element 63G that emits the green light 175G, the light-emitting element 63B that emits the blue light 175B, and the like between the substrate 151 and the substrate 152. A variety of optical members can be provided on the outer surface of the substrate 152.

The light-emitting element 63R, the light-emitting element 63G, and the light-emitting element 63B each have the stacked-layer structure illustrated in FIG. 8A. For details of the light-emitting element 63, Embodiment 1 can be referred to.

Although not illustrated in FIG. 27A, the light-receiving element 73 illustrated in FIG. 9A, for example, may be included in the display device 100H. The display device 100H may include, for example, the light-emitting element 63IR emitting the light 175IR that can be infrared light, which is illustrated in FIG. 9B. Furthermore, the display device 100H may include, for example, the light-emitting element 61R, the light-emitting element 61G, and the light-emitting element 61B illustrated in FIG. 7A instead of the light-emitting element 63R, the light-emitting element 63G, and the light-emitting element 63B. The same applies to display devices described later.

The conductive layer 171 that has a function of a pixel electrode and is included in the light-emitting element 63 is electrically connected to the conductive layer 222b included in the transistor 205 through an opening provided in the insulating layer 214. The conductive layer 171 is provided along the opening in the insulating layer 214. Thus, a depressed portion is provided in the conductive layer 171.

The protective layer 273 is provided over the light-emitting element 63R, the light-emitting element 63G, and the light-emitting element 63B. The protective layer 273 and the substrate 152 are bonded to each other with an adhesive layer 142. A solid sealing structure, a hollow sealing structure, or the like can be employed to seal the light-emitting elements 63. In FIG. 27A, a solid sealing structure is employed in which a space between the substrate 152 and the substrate 151 is filled with the adhesive layer 142. Alternatively, a hollow sealing structure in which the space is filled with an inert gas (e.g., nitrogen or argon) may be employed. Here, the adhesive layer 142 may be provided not to overlap with the light-emitting elements. The space may be filled with a resin different from that of the frame-like adhesive layer 142.

FIG. 27A illustrates an example in which the connection portion 140 includes a conductive layer obtained by processing the same conductive film as the conductive film to be the conductive layer 171.

The display device 100H has a top-emission structure. Light emitted by the light-emitting element is emitted toward the substrate 152 side. For the substrate 152, a material having a high visible-light-transmitting property is preferably used. In contrast, there is no limitation on the light-transmitting property of a material used for the substrate 151. The conductive layer 171 having a function of a pixel electrode contains a material that reflects visible light, and the conductive layer 173 having a function of a common electrode contains a material that transmits visible light. Here, in the case where the display device 100H includes a light-emitting element that emits infrared light, a material having a high infrared-light-transmitting property is preferably used for the substrate 152. The conductive layer 171 preferably contains a material that reflects infrared light, and the conductive layer 173 preferably contains a material that transmits infrared light.

The transistor 201 and the transistor 205 are formed over the substrate 151. These transistors can be fabricated using the same material in the same process.

An insulating layer 211, an insulating layer 213, an insulating layer 215, and the insulating layer 214 are provided in this order over the substrate 151. Part of the insulating layer 211 functions as a first gate insulating layer of each transistor. Part of the insulating layer 213 functions as a second gate insulating layer of each transistor. The insulating layer 215 is provided to cover the transistors. The insulating layer 214 is provided to cover the transistors and has a function of a planarization layer. Note that there is no limitation on the number of gate insulating layers and the number of insulating layers covering the transistors, and each insulating layer may have either a single layer or two or more layers.

A material in which impurities such as water and hydrogen do not easily diffuse is preferably used for at least one of the insulating layers covering the transistors. This allows the insulating layer to function as a barrier layer. Such a structure can effectively inhibit diffusion of impurities into the transistors from the outside and increase the reliability of the display device.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

An organic insulating layer is suitable as the insulating layer 214 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. The insulating layer 214 may have a stacked-layer structure of an organic insulating layer and an inorganic insulating layer. The outermost layer of the insulating layer 214 preferably has a function of an etching protective layer. Thus, the formation of a depressed portion in the insulating layer 214 can be inhibited in processing a conductive film to be the conductive layer 171, for example. Note that a depressed portion may be provided in the insulating layer 214 in processing the conductive film to be the conductive layer 171, for example.

Each of the transistor 201 and the transistor 205 includes a conductive layer 221 functioning as a gate, the insulating layer 211 functioning as the first gate insulating layer, a conductive layer 222a and the conductive layer 222b functioning as a source and a drain, a semiconductor layer 231, the insulating layer 213 functioning as the second gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display device of this embodiment. For example, a planar transistor, a staggered transistor, an inverted staggered transistor, or the like can be used. A top-gate transistor structure or a bottom-gate transistor structure may be employed. Alternatively, gates may be provided above and below the semiconductor layer where a channel is formed.

The structure in which the semiconductor layer where a channel is formed is provided between two gates is used for the transistor 201 and the transistor 205. The two gates may be connected to each other and supplied with the same signal to drive the transistor. Alternatively, a potential for controlling the threshold voltage may be supplied to one of the two gates and a potential for driving may be supplied to the other to control the threshold voltage of the transistor.

There is no particular limitation on the crystallinity of a semiconductor material used for the transistors, and an amorphous semiconductor or a semiconductor having crystallinity (a microcrystalline semiconductor, a polycrystalline semiconductor, a single crystal semiconductor, or a semiconductor partly including crystal regions) may be used. A semiconductor having crystallinity is preferably used because deterioration of the transistor characteristics can be inhibited.

The semiconductor layer of the transistor preferably includes a metal oxide. That is, a transistor including a metal oxide in its channel formation region (an OS transistor) is preferably used for the display device of this embodiment.

Examples of the metal oxide that can be used for the semiconductor layer include indium oxide, gallium oxide, and zinc oxide. The metal oxide preferably contains two or three selected from indium, the element M, and zinc. The element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. In particular, the element M is preferably one or more kinds selected from aluminum, gallium, yttrium, and tin.

It is particularly preferable that an oxide containing indium (In), gallium (Ga), and zinc (Zn) (also referred to as IGZO) be used as the metal oxide used for the semiconductor layer. Alternatively, it is preferable to use an oxide containing indium, tin, and zinc (also referred to as ITZO (registered trademark)). Further alternatively, it is preferable to use an oxide containing indium, gallium, tin, and zinc. Alternatively, an oxide containing indium (In), aluminum (Al), and zinc (Zn) (also referred to as IAZO) is preferably used for the semiconductor layer. Alternatively, an oxide containing indium (In), aluminum (Al), gallium (Ga), and zinc (Zn) (also referred to as IAGZO) is preferably used for the semiconductor layer.

When the metal oxide used for the semiconductor layer is an In-M-Zn oxide, the atomic ratio of In is preferably greater than or equal to the atomic ratio of M in the In-M-Zn oxide. Examples of the atomic ratio of the metal elements in such an In-M-Zn oxide are the follows: In:M:Zn=1:1:1 or a composition in the neighborhood thereof; In:M:Zn=1:1:1.2 or a composition in the neighborhood thereof; In:M:Zn=1:3:2 or a composition in the neighborhood thereof; In:M:Zn=1:3:4 or a composition in the neighborhood thereof; In:M:Zn=2:1:3 or a composition in the neighborhood thereof; In:M:Zn=3:1:2 or a composition in the neighborhood thereof; In:M:Zn=4:2:3 or a composition in the neighborhood thereof; In:M:Zn=4:2:4.1 or a composition in the neighborhood thereof; In:M:Zn=5:1:3 or a composition in the neighborhood thereof; In:M:Zn=5:1:6 or a composition in the neighborhood thereof; In:M:Zn=5:1:7 or a composition in the neighborhood thereof; In:M:Zn=5:1:8 or a composition in the neighborhood thereof; In:M:Zn=6:1:6 or a composition in the neighborhood thereof, and In:M:Zn=5:2:5 or a composition in the neighborhood thereof. Note that a composition in the neighborhood includes the range of ±30% of an intended atomic ratio.

For example, when the atomic ratio is described as In:Ga:Zn=4:2:3 or a composition in the neighborhood thereof, the case is included where Ga is greater than or equal to 1 and less than or equal to 3 and Zn is greater than or equal to 2 and less than or equal to 4 with In being 4. When the atomic ratio is described as In:Ga:Zn=5:1:6 or a composition in the neighborhood thereof, the case is included where Ga is greater than 0.1 and less than or equal to 2 and Zn is greater than or equal to 5 and less than or equal to 7 with In being 5. When the atomic ratio is described as In:Ga:Zn=1:1:1 or a composition in the neighborhood thereof, the case is included where Ga is greater than 0.1 and less than or equal to 2 and Zn is greater than 0.1 and less than or equal to 2 with In being 1.

The semiconductor layer may include two or more metal oxide layers having different compositions. For example, a stacked-layer structure of a first metal oxide layer having In:M:Zn=1:3:4 [atomic ratio] or a composition in the neighborhood thereof and a second metal oxide layer having In:M:Zn=1:1:1 [atomic ratio] or a composition in the neighborhood thereof and being formed over the first metal oxide layer can be suitably employed. In particular, gallium or aluminum is preferably used as the element M.

Alternatively, a stacked-layer structure of one selected from indium oxide, indium gallium oxide, and IGZO and one selected from IAZO, IAGZO, and ITZO (registered trademark) may be employed, for example.

As the oxide semiconductor having crystallinity, a CAAC (c-axis aligned crystalline)-OS, an nc (nanocrystalline)-OS, and the like can be given.

Alternatively, a transistor containing silicon in its channel formation region (a Si transistor) may be used. As silicon, single crystal silicon, polycrystalline silicon, amorphous silicon, and the like can be given. In particular, a transistor containing low-temperature polysilicon (LTPS) in its semiconductor layer (hereinafter also referred to as an LTPS transistor) can be used. The LTPS transistor has high field-effect mobility and excellent frequency characteristics.

With the use of Si transistors such as LTPS transistors, a circuit required to be driven at a high frequency (e.g., a data driver circuit) can be formed on the same substrate as the pixel portion. Thus, external circuits mounted on the display device can be simplified, and parts costs and mounting costs can be reduced.

An OS transistor has much higher field-effect mobility than a transistor using amorphous silicon. In addition, an OS transistor has an extremely low leakage current between a source and a drain in an off state (hereinafter also referred to as off-state current), and charge accumulated in a capacitor that is connected in series to the transistor can be retained for a long period. Furthermore, power consumption of the display device can be reduced with use of an OS transistor.

To increase the emission luminance of the light-emitting element included in the pixel circuit, the amount of current fed through the light-emitting element needs to be increased. For this, it is necessary to increase the source-drain voltage of a driving transistor included in the pixel circuit. Since an OS transistor has a higher breakdown voltage between the source and the drain than a Si transistor, a high voltage can be applied between the source and the drain of the OS transistor. Accordingly, when an OS transistor is used as the driving transistor included in the pixel circuit, the amount of current flowing through the light-emitting element can be increased, so that the emission luminance of the light-emitting element can be increased.

When a transistor is driven in a saturation region, a change in source-drain current relative to a change in gate-source voltage can be smaller in an OS transistor than in a Si transistor. Accordingly, when an OS transistor is used as the driving transistor included in the pixel circuit, current flowing between the source and the drain can be minutely determined by controlling the gate-source voltage. Thus, the amount of current flowing through the light-emitting element can be controlled. Accordingly, the number of gray levels in the pixel circuit can be increased.

Regarding saturation characteristics of current flowing when a transistor is driven in a saturation region, even in the case where the source-drain voltage of an OS transistor increases gradually, more stable current (saturation current) can be fed through the OS transistor than through a Si transistor. Thus, by using an OS transistor as the driving transistor, a stable current can be fed through a light-emitting element even when the current-voltage characteristics of an organic EL element vary, for example. In other words, when the OS transistor is driven in the saturation region, the source-drain current hardly changes with an increase in the source-drain voltage. Hence, the luminance of the light-emitting element can be stable.

As described above, with use of an OS transistor as a driving transistor included in the pixel circuit, it is possible to achieve inhibition of black-level degradation, increase in emission luminance, increase in gray level, inhibition of variation in light-emitting elements, and the like.

The transistor included in the circuit 164 and the transistor included in the pixel portion 107 may have the same structure or different structures. A plurality of transistors included in the circuit 164 may have the same structure or two or more kinds of structures. Similarly, one structure or two or more types of structures may be employed for a plurality of transistors included in the pixel portion 107.

All transistors included in the pixel portion 107 may be OS transistors, or all transistors included in the pixel portion 107 may be Si transistors. Alternatively, some of the transistors included in the pixel portion 107 may be OS transistors and the others may be Si transistors.

For example, when both an LTPS transistor and an OS transistor are used in the pixel portion 107, the display device can have low power consumption and high driving capability. A structure in which an LTPS transistor and an OS transistor are used in combination is referred to as LTPO in some cases. For example, preferably, an OS transistor is used as a transistor functioning as a switch for controlling conduction and non-conduction between wirings and an LTPS transistor is used as a transistor for controlling current.

For example, one of the transistors included in the pixel portion 107 functions as a transistor for controlling current flowing through the light-emitting element and can be referred to as a driving transistor. One of a source and a drain of the driving transistor is electrically connected to the pixel electrode of the light-emitting element. An LTPS transistor is preferably used as the driving transistor. In that case, the amount of current flowing through the light-emitting element can be increased.

Another transistor included in the pixel portion 107 functions as a switch for controlling selection and non-selection of the pixel and can be referred to as a selection transistor. A gate of the selection transistor is electrically connected to a gate line, and one of a source and a drain thereof is electrically connected to a data line. An OS transistor is preferably used as the selection transistor. In that case, the gray level of the pixel can be maintained even with an extremely low frame frequency (e.g., lower than or equal to 1 fps); thus, power consumption can be reduced by stopping the driver in displaying a still image.

As described above, the display device of one embodiment of the present invention can have all of a high aperture ratio, high resolution, high display quality, and low power consumption.

Note that the display device of one embodiment of the present invention has a structure including the OS transistor and the light-emitting element having an MIL structure. With this structure, the leakage current that might flow through the transistor and the leakage current that might flow between adjacent light-emitting elements can be extremely low. With the structure, a viewer can notice any one or more of the image crispness, the image sharpness, a high chroma, and a high contrast ratio in an image displayed on the display device. When the leakage current that would flow through the transistor and the lateral leakage current between the light-emitting elements are extremely low, light leakage that might occur in black display (what is called black-level degradation) can be minimized, for example.

In particular, in the case where a light-emitting element having the MML structure employs the SBS structure, a layer provided between light-emitting elements is disconnected; accordingly, lateral leakage can be prevented or be made extremely low.

FIG. 27B and FIG. 27C illustrate other structure examples of transistors.

A transistor 209 and a transistor 210 each include the conductive layer 221 functioning as a gate, the insulating layer 211 functioning as the first gate insulating layer, the semiconductor layer 231 including a channel formation region 231i and a pair of low-resistance regions 231n, the conductive layer 222a electrically connected to one of the pair of low-resistance regions 231n, the conductive layer 222b electrically connected to the other of the pair of the low-resistance regions 231n, an insulating layer 225 functioning as the second gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned between at least the conductive layer 223 and the channel formation region 231i. Furthermore, an insulating layer 218 covering the transistor may be provided.

FIG. 27B illustrates an example of the transistor 209 in which the insulating layer 225 covers the top and side surfaces of the semiconductor layer 231. The conductive layer 222a and the conductive layer 222b are electrically connected to the low-resistance regions 231n through openings provided in the insulating layer 225 and the insulating layer 215. One of the conductive layer 222a and the conductive layer 222b functions as a source, and the other functions as a drain.

Meanwhile, in the transistor 210 illustrated in FIG. 27C, the insulating layer 225 overlaps with the channel formation region 231i of the semiconductor layer 231 and does not overlap with the low-resistance regions 231n. The structure illustrated in FIG. 27C can be formed by processing the insulating layer 225 using the conductive layer 223 as a mask, for example. In FIG. 27C, the insulating layer 215 is provided to cover the insulating layer 225 and the conductive layer 223, and the conductive layer 222a and the conductive layer 222b are electrically connected to the low-resistance regions 231n through the openings in the insulating layer 215.

The connection portion 204 is provided in the substrate 151 in a region that does not overlap with the substrate 152. In the connection portion 204, the wiring 165 is electrically connected to the FPC 177 through a conductive layer 166 and a connection layer 242. The conductive layer 166 can be a conductive layer obtained by processing the same conductive film as a conductive film to be the conductive layer 171. On the top surface of the connection portion 204, the conductive layer 166 is exposed. Thus, the connection portion 204 and the FPC 177 can be electrically connected to each other through the connection layer 242.

The material that can be used for the substrate 120 can be used for each of the substrate 151 and the substrate 152.

The material that can be used for the resin layer 122 can be used for the adhesive layer 142.

As the connection layer 242, an anisotropic conductive film (ACF), an anisotropic conductive paste (ACP), or the like can be used.

### [Display Device 100I]

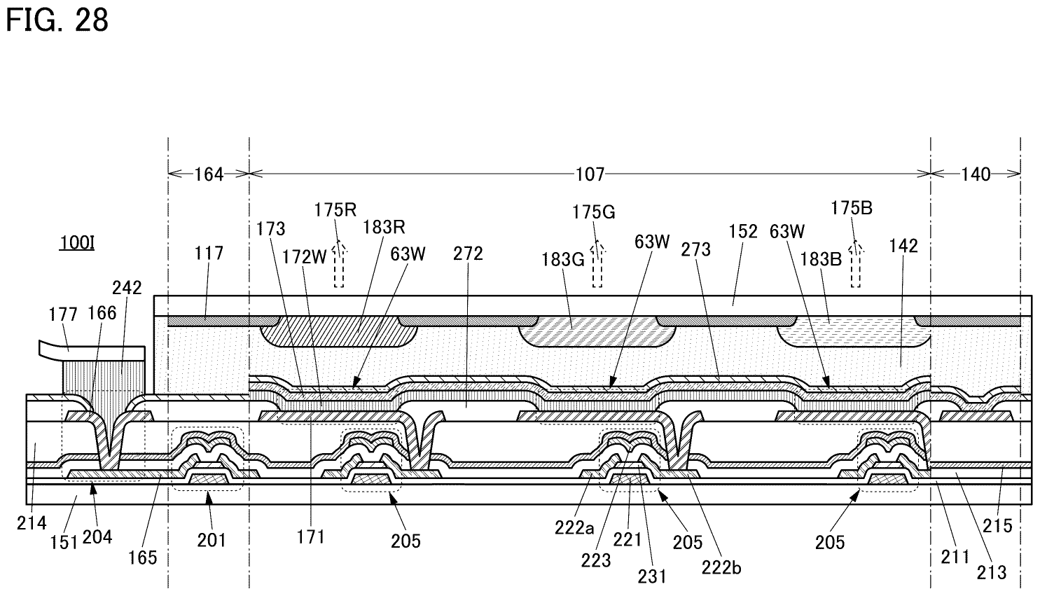

A display device 100I illustrated in FIG. 28 is a modification example of the display device 100H illustrated in FIG. 27A and differs from the display device 100H mainly in that the light-emitting elements 63W are provided as light-emitting elements and the coloring layer 183R, the coloring layer 183G, and the coloring layer 183B are included. FIG. 28 illustrates an example in which the light-emitting elements 63W each have the stacked-layer structure illustrated in FIG. 8B.

In the display device 100I, each of the light-emitting elements 63W includes a region overlapping with one of the coloring layer 183R, the coloring layer 183G, and the coloring layer 183B. The coloring layer 183R, the coloring layer 183G, and the coloring layer 183B can be provided on a surface of the substrate 152 on the substrate 151 side.

The light-blocking layer 117 is preferably provided in a region of the pixel portion 107 where the coloring layer 183R, the coloring layer 183G, and the coloring layer 183B are not provided. End portions of the coloring layer 183R, the coloring layer 183G, and the coloring layer 183B preferably overlap with the light-blocking layer 117. In this manner, light emitted from the light-emitting element 63W can be inhibited from being emitted from the substrate 152 without passing through the desired coloring layer 183. For example, light emitted from the light-emitting element 63W overlapping with the coloring layer 183R can be inhibited from being emitted from the substrate 152 without passing through the coloring layer 183R, light emitted from the light-emitting element 63W overlapping with the coloring layer 183G can be inhibited from being emitted from the substrate 152 without passing through the coloring layer 183G, and light emitted from the light-emitting element 63W overlapping with the coloring layer 183B can be inhibited from being emitted from the substrate 152 without passing through the coloring layer 183B. Accordingly, the display device 100I can be a display device with high display quality. As illustrated in FIG. 28, the light-blocking layer 117 can also be provided in the connection portion 140, the circuit 164, and the like.

The light-blocking layer 117 can also be provided in the display device 100H illustrated in FIG. 27A. In that case, light emitted from the light-emitting element 63R, the light-emitting element 63G, and the light-emitting element 63B can be inhibited from being reflected by the substrate 152 and diffusing inside the display device 100H, for example. Accordingly, the display device 100H can be a display device with high display quality. Meanwhile, when the light-blocking layer 117 is not provided, light extraction efficiency can be increased.

In the display device 100I, the light-emitting element 63W can emit white light, for example. For example, the coloring layer 183R can transmit red light, the coloring layer 183G can transmit green light, and the coloring layer 183B can transmit blue light. In this manner, the display device 100I can emit the red light 175R, the green light 175G, and the blue light 175B, for example, to perform full color display.

### [Display Device 100J]

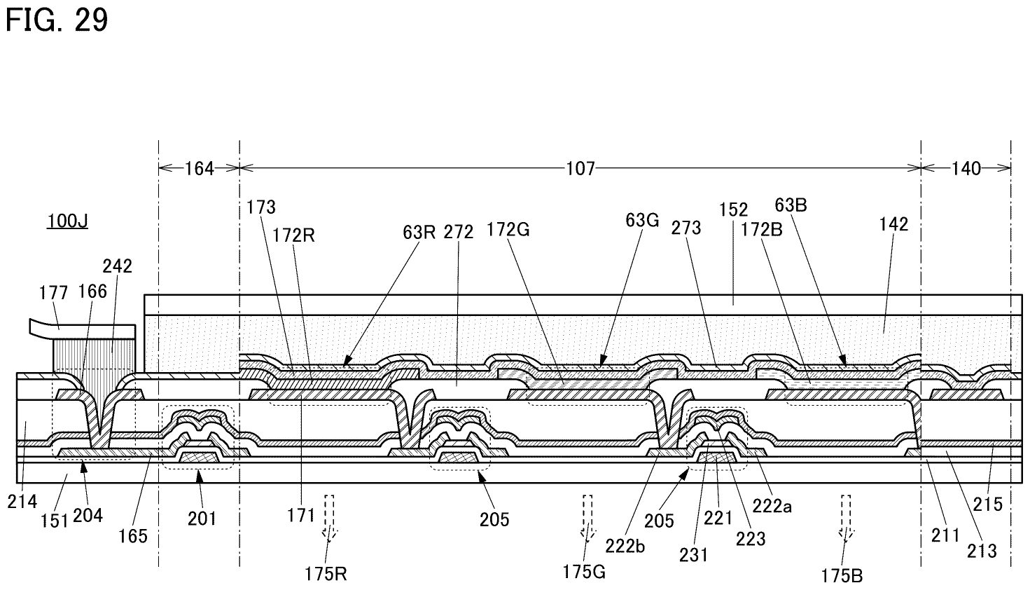

A display device 100J illustrated in FIG. 29 is a modification example of the display device 100H illustrated in FIG. 27A and differs from the display device 100H mainly in being a bottom-emission display device.

The light 175R, the light 175G, and the light 175B are emitted toward the substrate 151 side. For the substrate 151, a material having a high visible-light-transmitting property is preferably used. In contrast, there is no limitation on the light-transmitting property of a material used for the substrate 152. A material having a high visible-light-transmitting property is used for the conductive layer 171. In contract, a material reflecting visible light is preferably used for the conductive layer 173. Here, in the case where the display device 100J includes a light-emitting element that emits infrared light, a material having a high infrared-light-transmitting property is preferably used for the substrate 151, and a material having a high infrared-light-transmitting property is preferably used for the conductive layer 171. For the conductive layer 173, a material reflecting infrared light is preferably used.

### [Display Device 100K]

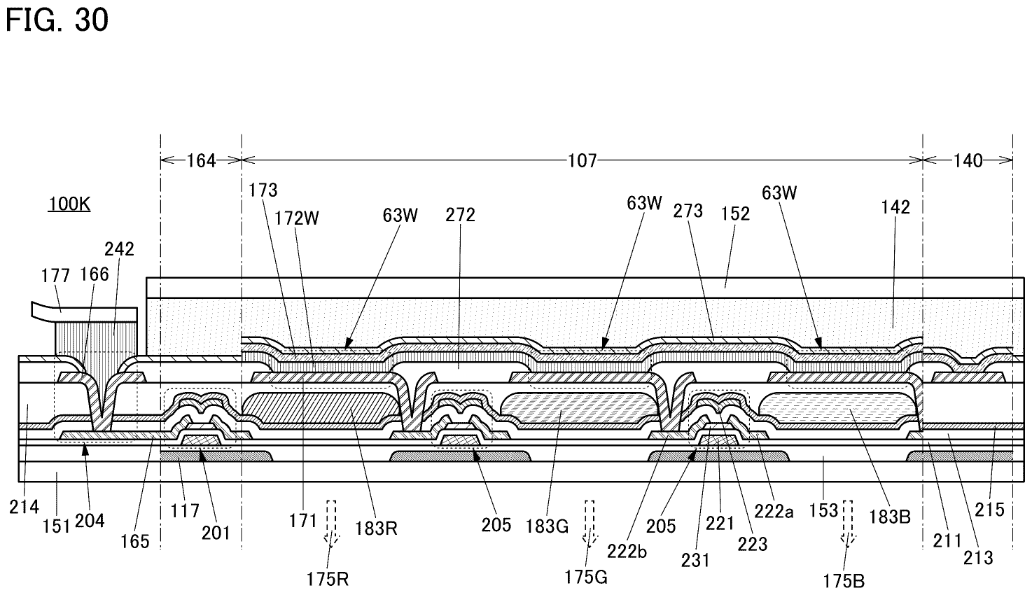

A display device 100K illustrated in FIG. 30 is a modification example of the display device 100I illustrated in FIG. 28 and differs from the display device 100I mainly in being a bottom-emission display device like the display device 100J illustrated in FIG. 29.

The coloring layer 183R, the coloring layer 183G, and the coloring layer 183B are each provided between the light-emitting element 63W and the substrate 151. FIG. 30 illustrates an example in which the coloring layer 183R, the coloring layer 183G, and the coloring layer 183B are each provided between the insulating layer 215 and the insulating layer 214.

The light-blocking layer 117 is preferably provided between the substrate 151 and the transistor 205. The light-blocking layer 117 can be provided in a region not overlapping with the light-emitting region of the light-emitting element 63W. Thus, light emitted from the light-emitting element 63W can be inhibited from being emitted from the substrate 151 without passing through the desired coloring layer 183. Accordingly, the display device 100K can be a display device with high display quality. FIG. 30 illustrates an example in which the light-blocking layer 117 is provided over the substrate 151, the insulating layer 153 is provided over the light-blocking layer 117, and the transistor 201, the transistor 205, and the like are provided over the insulating layer 153. As illustrated in FIG. 30, the light-blocking layer 117 can also be provided in the connection portion 140 and the circuit 164.

The light-blocking layer 117 can also be provided in the display device 100J illustrated in FIG. 29. In that case, light emitted from the light-emitting element 63R, the light-emitting element 63G, and the light-emitting element 63B can be inhibited from being reflected by the substrate 151 and diffusing inside the display device 100J, for example. Accordingly, the display device 100J can be a display device with high display quality. Meanwhile, when the light-blocking layer 117 is not provided, light extraction efficiency can be increased.

At least part of the structure examples, the drawings corresponding thereto, and the like described in this embodiment can be combined with the other structure examples, the other drawings, and the like as appropriate.

### Embodiment 4

In this embodiment, light-emitting elements that can be used for the display device of one embodiment of the present invention will be described with reference to drawings.

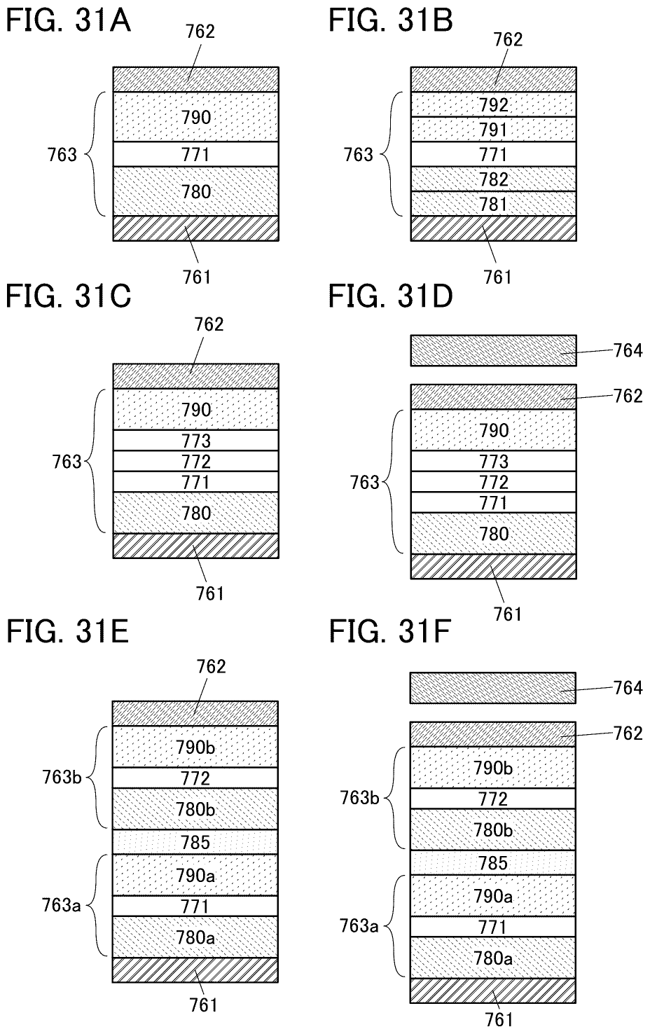

As illustrated in FIG. 31A, the light-emitting element includes an EL layer 763 between a pair of electrodes (a lower electrode 761 and an upper electrode 762). The EL layer 763 can be formed of a plurality of layers such as a layer 780, a light-emitting layer 771, and a layer 790.

The light-emitting layer 771 includes at least a light-emitting substance.

In the case where the lower electrode 761 is an anode and the upper electrode 762 is a cathode, the layer 780 includes one or more of a layer including a substance with a high hole-injection property (a hole-injection layer), a layer including a substance with a high hole-transport property (a hole-transport layer), and a layer including a substance with a high electron-blocking property (an electron-blocking layer). Furthermore, the layer 790 includes one or more of a layer including a substance with a high electron-injection property (an electron-injection layer), a layer including a substance with a high electron-transport property (an electron-transport layer), and a layer including a substance with a high hole-blocking property (a hole-blocking layer). In the case where the lower electrode 761 is a cathode and the upper electrode 762 is an anode, the above structures of the layer 780 and the layer 790 are replaced with each other.

The structure including the layer 780, the light-emitting layer 771, and the layer 790, which is provided between a pair of electrodes, can function as a single light-emitting unit, and the structure in FIG. 31A is referred to as a single structure in this specification and the like.

FIG. 31B is a modification example of the EL layer 763 included in the light-emitting element illustrated in FIG. 31A. Specifically, the light-emitting element illustrated in FIG. 31B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layer structure, carriers can be efficiently injected to the light-emitting layer 771, and the efficiency of the recombination of carriers in the light-emitting layer 771 can be increased.

Note that structures in which a plurality of light-emitting layers (the light-emitting layer 771, a light-emitting layer 772, and a light-emitting layer 773) are provided between the layer 780 and the layer 790 as illustrated in FIG. 31C and FIG. 31D are variations of the single structure. Although FIG. 31C and FIG. 31D illustrate the examples where three light-emitting layers are included, the light-emitting element having a single structure may include two or four or more light-emitting layers. In addition, the light-emitting element having a single structure may include a buffer layer between two light-emitting layers.

A structure in which a plurality of light-emitting units (a light-emitting unit 763a and a light-emitting unit 763b) are connected in series with a charge-generation layer 785 (also referred to as an intermediate layer) therebetween as illustrated in FIG. 31E and FIG. 31F is referred to as a tandem structure in this specification and the like. Note that the tandem structure may be referred to as a stack structure. The tandem structure enables a light-emitting element capable of high-luminance light emission. Furthermore, the tandem structure reduces the amount of current needed for obtaining the same luminance compared with a single structure, and thus can improve the reliability.

Note that FIG. 31D and FIG. 31F illustrate examples where the display device includes a layer 764 overlapping with the light-emitting element. FIG. 31D illustrates an example in which the layer 764 overlaps with the light-emitting element illustrated in FIG. 31C, and FIG. 31F illustrates an example in which the layer 764 overlaps with the light-emitting element illustrated in FIG. 31E. In FIG. 31D and FIG. 31F, a conductive film transmitting visible light is used for the upper electrode 762 to extract light to the upper electrode 762 side.

One or both of a color conversion layer and a color filter (coloring layer) can be used as the layer 764.

In FIG. 31C and FIG. 31D, light-emitting substances that emit light of the same color, or moreover, the same light-emitting substance may be used for the light-emitting layer 771, the light-emitting layer 772, and the light-emitting layer 773. For example, a light-emitting substance that emits blue light may be used for the light-emitting layer 771, the light-emitting layer 772, and the light-emitting layer 773. In a subpixel that emits blue light, blue light emitted from the light-emitting element can be extracted. In a subpixel that emits red light and a subpixel that emits green light, by providing a color conversion layer as the layer 764 illustrated in FIG. 31D, blue light emitted from the light-emitting element can be converted into light with a longer wavelength, and red light or green light can be extracted. As the layer 764, both a color conversion layer and a coloring layer are preferably used. In some cases, part of light emitted from the light-emitting element is transmitted through the color conversion layer without being converted. When light transmitted through the color conversion layer is extracted through the coloring layer, light other than light of the intended color can be absorbed by the coloring layer, and color purity of light exhibited by a subpixel can be improved.

Alternatively, in FIG. 31C and FIG. 31D, light-emitting substances emitting light of different colors may be used for the light-emitting layer 771, the light-emitting layer 772, and the light-emitting layer 773. White light emission can be obtained when the light-emitting layer 771, the light-emitting layer 772, and the light-emitting layer 773 emit light of complementary colors. The light-emitting element having a single structure preferably includes a light-emitting layer including a light-emitting substance emitting blue light and a light-emitting layer including a light-emitting substance emitting visible light with a longer wavelength than blue light, for example.

A color filter may be provided as the layer 764 illustrated in FIG. 31D. When white light passes through the color filter, light of a desired color can be obtained.

In the case where the light-emitting element having a single structure includes three light-emitting layers, for example, a light-emitting layer including a light-emitting substance emitting red (R) light, a light-emitting layer including a light-emitting substance emitting green (G) light, and a light-emitting layer including a light-emitting substance emitting blue (B) light are preferably included. The stacking order of the light-emitting layers can be RGB or RBG from an anode side, for example. In that case, a buffer layer may be provided between R and G or between R and B.

For example, in the case where the light-emitting element having a single structure includes two light-emitting layers, the light-emitting element preferably includes a light-emitting layer including a light-emitting substance that emits blue (B) light and a light-emitting layer including a light-emitting substance that emits yellow (Y) light. Such a structure may be referred to as a BY single structure.

In the light-emitting element that emits white light, two or more types of light-emitting substances are preferably contained. To obtain white light emission, two or more types of light-emitting substances are selected so as to emit light of complementary colors. For example, when emission colors of a first light-emitting layer and a second light-emitting layer are complementary colors, the light-emitting element can emit white light as a whole. The same applies to a light-emitting element including three or more light-emitting layers.

Also in FIG. 31C and FIG. 31D, the layer 780 and the layer 790 may each independently have a stacked-layer structure of two or more layers as illustrated in FIG. 31B.

In FIG. 31E and FIG. 31F, light-emitting substances that emit light of the same color, or moreover, the same light-emitting substance may be used for the light-emitting layer 771 and the light-emitting layer 772. For example, in light-emitting elements included in subpixels emitting light of different colors, a light-emitting substance that emits blue light can be used for each of the light-emitting layer 771 and the light-emitting layer 772. In a subpixel that emits blue light, blue light emitted from the light-emitting element can be extracted. In the subpixel that emits red light and the subpixel that emits green light, by providing a color conversion layer as the layer 764 illustrated in FIG. 31F, blue light emitted from the light-emitting element can be converted into light with a longer wavelength, and red light or green light can be extracted. As the layer 764, both a color conversion layer and a coloring layer are preferably used.

In the case where the light-emitting element having the structure illustrated in FIG. 31E or FIG. 31F is used for the subpixels emitting light of different colors, the subpixels may use different light-emitting substances. Specifically, in the light-emitting element included in the subpixel that emits red light, a light-emitting substance that emits red light can be used for each of the light-emitting layer 771 and the light-emitting layer 772. Similarly, in the light-emitting element included in the subpixel that emits green light, a light-emitting substance that emits green light can be used for each of the light-emitting layer 771 and the light-emitting layer 772. In the light-emitting element included in the subpixel that emits blue light, a light-emitting substance that emits blue light can be used for each of the light-emitting layer 771 and the light-emitting layer 772. A display device having such a structure can be regarded as employing a light-emitting element with the tandem structure and the SBS structure. Thus, advantages of both the tandem structure and the SBS structure can be achieved. Accordingly, a light-emitting element being capable of high-luminance light emission and having high reliability can be obtained.

In FIG. 31E and FIG. 31F, light-emitting substances that emit light of different colors may be used for the light-emitting layer 771 and the light-emitting layer 772. White light emission can be obtained when the light-emitting layer 771 and the light-emitting layer 772 emit light of complementary colors. A color filter may be provided as the layer 764 illustrated in FIG. 31F. When white light passes through the color filter, light of a desired color can be obtained.

Although FIG. 31E and FIG. 31F illustrate examples where the light-emitting unit 763a includes one light-emitting layer 771 and the light-emitting unit 763b includes one light-emitting layer 772, one embodiment of the present invention is not limited thereto. Each of the light-emitting unit 763a and the light-emitting unit 763b may include two or more light-emitting layers.

In addition, although FIG. 31E and FIG. 31F illustrate the light-emitting element including two light-emitting units, one embodiment of the present invention is not limited thereto. The light-emitting element may include three or more light-emitting units. Note that a structure including two light-emitting units and a structure including three light-emitting units may be referred to as a two-unit tandem structure and a three-unit tandem structure, respectively.

In FIG. 31E and FIG. 31F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, the layer 780a and the layer 780b each include one or more of a hole-injection layer, a hole-transport layer, and an electron-blocking layer. The layer 790a and the layer 790b each include one or more of an electron-injection layer, an electron-transport layer, and a hole-blocking layer. In the case where the lower electrode 761 is a cathode and the upper electrode 762 is an anode, the structures of the layer 780a and the layer 790a are replaced with each other, and the structures of the layer 780b and the layer 790b are also replaced with each other.

In the case where the lower electrode 761 is an anode and the upper electrode 762 is a cathode, for example, the layer 780a includes a hole-injection layer and a hole-transport layer over the hole-injection layer, and may further include an electron-blocking layer over the hole-transport layer. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 761 is a cathode and the upper electrode 762 is an anode, for example, the layer 780a includes an electron-injection layer and an electron-transport layer over the electron-injection layer, and may further include a hole-blocking layer over the electron-transport layer. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In the case of fabricating a light-emitting element with the tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes into the other when voltage is applied between the pair of electrodes.

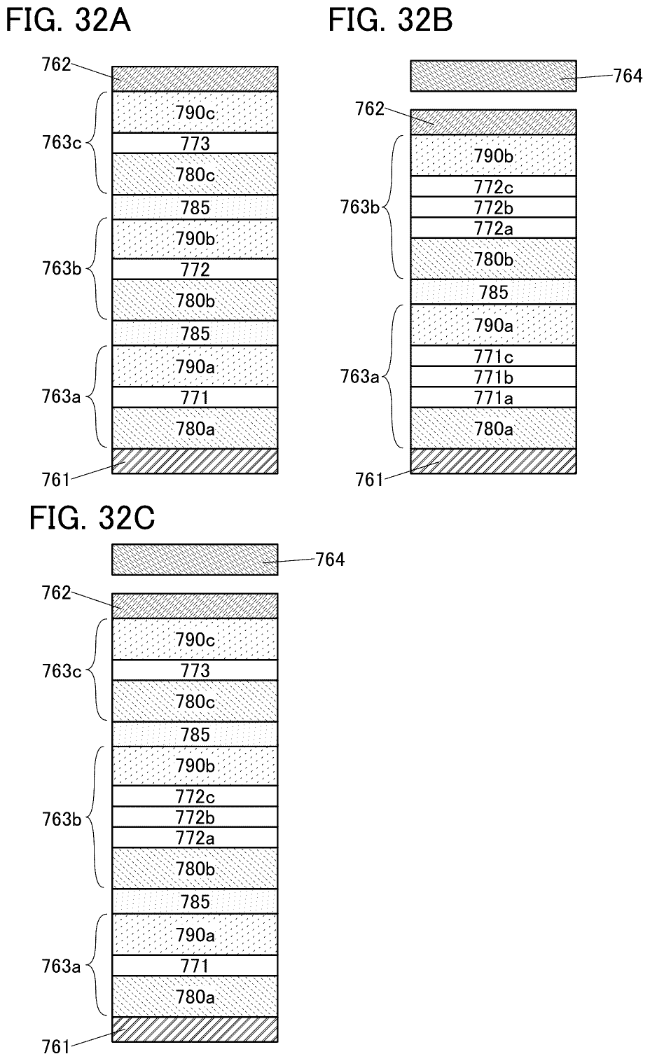

The structures illustrated in FIG. 32A to FIG. 32C can be given as examples of the light-emitting element having a tandem structure.

FIG. 32A illustrates a structure including three light-emitting units. As illustrated in FIG. 32A, a plurality of light-emitting units (the light-emitting unit 763a, the light-emitting unit 763b, and a light-emitting unit 763c) are connected in series through charge-generation layers 785. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. Note that the layer 780c can have a structure applicable to the layer 780a and the layer 780b, and the layer 790c can have a structure applicable to the layer 790a and the layer 790b.

In FIG. 32A, the light-emitting layer 771, the light-emitting layer 772, and the light-emitting layer 773 preferably include light-emitting substances that emit light of the same color. Specifically, the light-emitting layer 771, the light-emitting layer 772, and the light-emitting layer 773 can each include a light-emitting substance that emits red (R) light (a so-called R\R\R three-unit tandem structure); the light-emitting layer 771, the light-emitting layer 772, and the light-emitting layer 773 can each include a light-emitting substance that emits green (G) light (a so-called a G\G\G three-unit tandem structure); or the light-emitting layer 771, the light-emitting layer 772, and the light-emitting layer 773 can each include a light-emitting substance that emits blue (B) light (a so-called B\B\B three-unit tandem structure). Note that “a\b” means that a light-emitting unit including a light-emitting substance that emits light of b is provided over a light-emitting unit including a light-emitting substance that emits light of a with a charge-generation layer therebetween, where a and b represent colors.

In FIG. 32A, light-emitting substances that emit light of different colors may be used for some or all of the light-emitting layer 771, the light-emitting layer 772, and the light-emitting layer 773. Examples of a combination of emission colors for the light-emitting layer 771, the light-emitting layer 772, and the light-emitting layer 773 include blue (B) for two of them and yellow (Y) for the other; and red (R) for one of them, green (G) for another, and blue (B) for the other.

Note that the structure of the light-emitting unit is not limited to that in FIG. 32A. For example, a light-emitting element with a tandem structure may be employed in which light-emitting units each including a plurality of light-emitting layers are stacked as illustrated in FIG. 32B. FIG. 32B illustrates a structure in which two light-emitting units (the light-emitting unit 763a and the light-emitting unit 763b) are connected in series with the charge-generation layer 785 therebetween. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 32B, the light-emitting unit 763a is configured to emit white (W) light by selecting light-emitting substances for the light-emitting layer 771a, the light-emitting layer 771b, and the light-emitting layer 771c so that their emission colors are complementary colors. Furthermore, the light-emitting unit 763b is configured to emit white (W) light by selecting light-emitting substances for the light-emitting layer 772a, the light-emitting layer 772b, and the light-emitting layer 772c so that their emission colors are complementary colors. That is, the structure illustrated in FIG. 32B is a two-unit tandem structure of W\W. Note that there is no particular limitation on the stacking order of the light-emitting substances having complementary emission colors. The practitioner can select the optimal stacking order as appropriate. Although not illustrated, a three-unit tandem structure of W\W\W or a tandem structure with four or more units may be employed.

For a light-emitting element with a tandem structure, the following structure can be given: a B\Y or Y\B two-unit tandem structure including a light-emitting unit that emits yellow (Y) light and a light-emitting unit that emits blue (B) light; an R·G\B or B\R·G two-unit tandem structure including a light-emitting unit that emits red (R) light and green (G) light and a light-emitting unit that emits blue (B) light; a B\Y\B three-unit tandem structure including a light-emitting unit that emits blue (B) light, a light-emitting unit that emits yellow (Y) light, and a light-emitting unit that emits blue (B) light in this order; a B\YG\B three-unit tandem structure including a light-emitting unit that emits blue (B) light, a light-emitting unit that emits yellow green (YG) light, and a light-emitting unit that emits blue (B) light in this order; and a B\G\B three-unit tandem structure including a light-emitting unit that emits blue (B) light, a light-emitting unit that emits green (G) light, and a light-emitting unit that emits blue (B) light in this order. Note that “a·b” means that one light-emitting unit includes a light-emitting substance that emits light of a and a light-emitting substance that emits light of b.

As illustrated in FIG. 32C, a light-emitting unit including one light-emitting layer and a light-emitting unit including a plurality of light-emitting layers may be used in combination.

Specifically, in the structure illustrated in FIG. 32C, a plurality of light-emitting units (the light-emitting unit 763a, the light-emitting unit 763b, and the light-emitting unit 763c) are connected in series through the charge-generation layers 785. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

As the structure illustrated in FIG. 32C, for example, a three-unit tandem structure of B\R·G·YG\B in which the light-emitting unit 763a is a light-emitting unit that emits blue (B) light, the light-emitting unit 763b is a light-emitting unit that emits red (R), green (G), and yellow green (YG) light, and the light-emitting unit 763c is a light-emitting unit that emits blue (B) light can be employed.

Examples of the number of stacked light-emitting units and the order of colors from the anode side include a two-unit structure of B and Y; a two-unit structure of B and the light-emitting unit X; a three-unit structure of B, Y, and B; and a three-unit structure of B, X, and B. Examples of the number of light-emitting layers stacked in the light-emitting unit X and the order of colors from the anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

Next, materials that can be used for the light-emitting element will be described.

A conductive film transmitting visible light is used as the electrode through which light is extracted, which is either the lower electrode 761 or the upper electrode 762. A conductive film reflecting visible light is preferably used as the electrode through which light is not extracted. In the case where a display device includes a light-emitting element emitting infrared light, it is preferable that a conductive film transmitting visible light and infrared light be used as the electrode through which light is extracted and a conductive film reflecting visible light and infrared light be used as the electrode through which light is not extracted.

A conductive film transmitting visible light may be used as the electrode through which light is not extracted. In that case, the electrode is preferably placed between a reflective layer and the EL layer 763. In other words, light emitted from the EL layer 763 may be reflected by the reflective layer to be extracted from the display device.

As a material that forms the pair of electrodes of the light-emitting element, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide, indium tin oxide containing silicon, indium zinc oxide, and indium zinc oxide containing tungsten. Examples of the material include an aluminum-containing alloy such as an alloy of aluminum, nickel, and lanthanum (Al—Ni—La), an alloy of silver and magnesium, and an alloy containing silver such as an alloy of silver, palladium, and copper (APC). Other examples of the material include elements belonging to Group 1 or Group 2 of the periodic table, which are not exemplified above (e.g., lithium, cesium, calcium, and strontium), rare earth metals such as europium and ytterbium, an alloy containing any of these metals in appropriate combination, and graphene.

In addition, the light-emitting element preferably also employs a microcavity structure. Therefore, one of the pair of electrodes of the light-emitting element preferably includes an electrode having properties of transmitting and reflecting visible light (a transflective electrode), and the other preferably includes an electrode having a property of reflecting visible light (a reflective electrode), for example. When the light-emitting elements have a microcavity structure, light obtained from the light-emitting layers can be resonated between the electrodes, whereby light emitted from the light-emitting elements can be intensified.

Note that the transflective electrode can have a stacked-layer structure of a conductive layer that can be used as a reflective electrode and a conductive layer that can be used as an electrode having a visible-light-transmitting property (also referred to as a transparent electrode), for example.

The transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting element. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm.

The light-emitting element includes at least the light-emitting layer. The light-emitting element may further include, as a layer other than the light-emitting layer, a layer including a substance with a high hole-injection property, a substance with a high hole-transport property, a hole-blocking material, a substance with a high electron-transport property, an electron-blocking material, a substance with a high electron-injection property, a substance with a bipolar property (a substance with a high electron-transport property and a high hole-transport property), or the like. For example, the light-emitting element can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting element, and an inorganic compound may be included. Each layer included in the light-emitting element can be formed by any of the following methods: an evaporation method (including a vacuum evaporation method), a transfer method, a printing method, an ink-jet method, a coating method, and the like.

The light-emitting layer includes one or more kinds of light-emitting substances. As the light-emitting substance, a substance exhibiting an emission color of blue, violet, bluish violet, green, yellowish green, yellow, orange, red, or the like is used as appropriate. Alternatively, as the light-emitting substance, a substance that emits near-infrared light can be used.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may include one or more kinds of organic compounds (e.g., a host material and an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the hole-transport material, it is possible to use a material having a high hole-transport property which can be used for the hole-transport layer and will be described later. As the electron-transport material, it is possible to use a material having a high electron-transport property which can be used for the electron-transport layer and will be described later. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. Such a structure makes it possible to efficiently obtain light emission using ExTET (Exciplex-Triplet Energy Transfer), which is energy transfer from an exciplex to a light-emitting substance (a phosphorescent material). When a combination is selected to form an exciplex that exhibits light emission whose wavelength overlaps with the wavelength of the lowest-energy-side absorption band of the light-emitting substance, energy can be transferred smoothly and light emission can be obtained efficiently. With this structure, the high efficiency, low-voltage driving, and long lifetime of the light-emitting element can be achieved at the same time.

The hole-injection layer is a layer injecting holes from the anode to the hole-transport layer, and is a layer containing a material with a high hole-injection property. Examples of the material with a high hole-injection property include an aromatic amine compound and a composite material containing a hole-transport material and an acceptor material (electron-accepting material).

As the hole-transport material, it is possible to use a material having a high hole-transport property which can be used for the hole-transport layer and will be described later.

As the acceptor material, an oxide of a metal belonging to Group 4 to Group 8 of the periodic table can be used, for example. Specific examples include molybdenum oxide, vanadium oxide, niobium oxide, tantalum oxide, chromium oxide, tungsten oxide, manganese oxide, and rhenium oxide. Among these, molybdenum oxide is particularly preferable since it is stable in the air, has a low hygroscopic property, and is easy to handle. An organic acceptor material containing fluorine can be used. An organic acceptor material such as a quinodimethane derivative, a chloranil derivative, or a hexaazatriphenylene derivative can be used.

As the material having a high hole-injection property, a material that includes a hole-transport material and the above-described oxide of a metal belonging to any of Group 4 to Group 8 of the periodic table (typically, molybdenum oxide) may be used, for example.

The hole-transport layer is a layer transporting holes injected from the anode by the hole-injection layer, to the light-emitting layer. The hole-transport layer is a layer including a hole-transport material. As the hole-transport material, a substance having a hole mobility higher than or equal to 1×10⁻⁶ cm²/Vs is preferable. Note that other substances can also be used as long as the substances have a hole-transport property higher than an electron-transport property. As the hole-transport material, a material with a high hole-transport property, such as a π-electron rich heteroaromatic compound (e.g., a carbazole derivative, a thiophene derivative, or a furan derivative) or an aromatic amine (a compound having an aromatic amine skeleton), is preferable.

The electron-blocking layer is provided in contact with the light-emitting layer. The electron-blocking layer has a hole-transport property and includes a material capable of blocking electrons. Any of the materials having an electron-blocking property among the above hole-transport materials can be used for the electron-blocking layer.

The electron-blocking layer has a hole-transport property, and thus can also be referred to as a hole-transport layer. A layer having an electron-blocking property among the hole-transport layers can also be referred to as an electron-blocking layer.

The electron-transport layer is a layer transporting electrons injected from the cathode by the electron-injection layer, to the light-emitting layer. The electron-transport layer is a layer including an electron-transport material. As the electron-transport material, a substance having an electron mobility higher than or equal to 1×10⁻⁶ cm²/Vs is preferable. Note that other substances can also be used as long as the substances have an electron-transport property higher than a hole-transport property. As the electron-transport material, any of the following materials with a high electron-transport property can be used, for example: a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a r-electron deficient heteroaromatic compound such as a nitrogen-containing heteroaromatic compound.

The hole-blocking layer is provided in contact with the light-emitting layer. The hole-blocking layer has an electron-transport property and includes a material capable of blocking holes. Any of the materials having a hole-blocking property among the above electron-transport materials can be used for the hole-blocking layer.

The hole-blocking layer has an electron-transport property, and thus can also be referred to as an electron-transport layer. A layer having a hole-blocking property among the electron-transport layers can also be referred to as a hole-blocking layer.

The electron-injection layer is a layer injecting electrons from the cathode to the electron-transport layer, and is a layer containing a material with a high electron-injection property. As the material with a high electron-injection property, an alkali metal, an alkaline earth metal, or a compound thereof can be used. As the material with a high electron-injection property, a composite material containing an electron-transport material and a donor material (electron-donating material) can also be used.

The difference between the LUMO level of the substance with a high electron-injection property and the work function value of the material used for the cathode is preferably small (specifically, smaller than or equal to 0.5 eV).

The electron-injection layer can be formed using, for example, an alkali metal, an alkaline earth metal, or a compound thereof, such as lithium, cesium, ytterbium, lithium fluoride (LiF), cesium fluoride (CsF), calcium fluoride (Ca_{Fx}, where X is a given number), 8-(quinolinolato)lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiOₓ), or cesium carbonate. The electron-injection layer may have a stacked-layer structure of two or more layers. The stacked-layer structure can be, for example, a structure in which lithium fluoride is used for the first layer and ytterbium is used for the second layer.

The electron-injection layer may include an electron-transport material. For example, a compound having an unshared electron pair and an electron deficient heteroaromatic ring can be used as the electron-transport material. Specifically, a compound having at least one of a pyridine ring, a diazine ring (a pyrimidine ring, a pyrazine ring, and a pyridazine ring), and a triazine ring can be used.

Note that the lowest unoccupied molecular orbital (LUMO) level of the organic compound having an unshared electron pair is preferably higher than or equal to −3.6 eV and lower than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), 2,2-(1,3-phenylene)bis[9-phenyl-1,10-phenanthroline] (abbreviation: mPPhen2P), diquinoxalino[2,3-α:2′, 3′-c]phenazine (abbreviation: HATNA), 2,4,6-tris[3′-(pyridin-3-yl)biphenyl-3-yl]-1,3,5-triazine (abbreviation: TmPPPyTz), or the like can be used for the organic compound having an unshared electron pair. Note that NBPhen has a higher glass transition point (Tg) than BPhen and thus has high heat resistance.

As described above, the charge-generation layer includes at least a charge-generation region. The charge-generation region preferably contains an acceptor material, and for example, preferably contains a hole-transport material and an acceptor material which can be used for the hole-injection layer.

The charge-generation layer preferably includes a layer including a material having a high electron-injection property. The layer can also be referred to as an electron-injection buffer layer. The electron-injection buffer layer is preferably provided between the charge-generation region and the electron-transport layer. By provision of the electron-injection buffer layer, an injection barrier between the charge-generation region and the electron-transport layer can be lowered; thus, electrons generated in the charge-generation region can be easily injected into the electron-transport layer.

The electron-injection buffer layer preferably includes an alkali metal or an alkaline earth metal, and for example, can include an alkali metal compound or an alkaline earth metal compound. Specifically, the electron-injection buffer layer preferably includes an inorganic compound containing an alkali metal and oxygen or an inorganic compound containing an alkaline earth metal and oxygen, further preferably includes an inorganic compound containing lithium and oxygen (e.g., lithium oxide (Li₂O)). Alternatively, a material that can be used for the electron-injection layer can be suitably used for the electron-injection buffer layer.

The charge-generation layer preferably includes a layer including a material having a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing interaction between the charge-generation region and the electron-injection buffer layer (or the electron-transport layer) and smoothly transferring electrons.

A phthalocyanine-based material such as copper(II) phthalocyanine (abbreviation: CuPc) or a metal complex having a metal-oxygen bond and an aromatic ligand is preferably used for the electron-relay layer.

Note that the charge-generation region, the electron-injection buffer layer, and the electron-relay layer cannot be clearly distinguished from each other in some cases on the basis of the cross-sectional shapes or the characteristics, for example.

Note that the charge-generation layer may include a donor material instead of an acceptor material. For example, the charge-generation layer may include a layer including an electron-transport material and a donor material, which can be used for the electron-injection layer.

When the light-emitting units are stacked, provision of a charge-generation layer between two light-emitting units can inhibit an increase in driving voltage.

At least part of the structure examples, the drawings corresponding thereto, and the like described in this embodiment can be combined with the other structure examples, the other drawings, and the like as appropriate.

### REFERENCE NUMERALS

10: electronic device, 11: communication circuit, 12: detection circuit, 13: control circuit, 23: pixel, 24: light, 25: lens, 27a: pixel, 27b: pixel, 30: optical system, 31: housing, 32: fixing member, 33L: pixel portion, 33R: pixel portion, 33: pixel portion, 34a: light, 34b: light, 35L: lens, 35R: lens, 35: lens, 36L: frame, 36R: frame, 36: frame, 37a: region, 37b: region, 37L: pixel portion, 37R: pixel portion, 37: pixel portion, 38L: half mirror, 38R: half mirror, 38: half mirror, 39a: projected surface, 39b: projected surface, 39: projected surface, 41L: display device, 41R: display device, 41: display device, 42L: gate driver circuit, 42R: gate driver circuit, 42: gate driver circuit, 43L: source driver circuit, 43R: source driver circuit, 43: source driver circuit, 44L: display device, 44R: display device, 44: display device, 45L: gate driver circuit, 45R: gate driver circuit, 45: gate driver circuit, 46L: source driver circuit, 46R: source driver circuit, 46: source driver circuit, 47L: row driver circuit, 47R: row driver circuit, 47: row driver circuit, 48L: column driver circuit, 48R: column driver circuit, 48: column driver circuit, 50: eye, 51: pupil, 52: retina, 61B: light-emitting element, 61G: light-emitting element, 61R: light-emitting element, 61W: light-emitting element, 61: light-emitting element, 63B: light-emitting element, 63G: light-emitting element, 63IR: light-emitting element, 63R: light-emitting element, 63W: light-emitting element, 63: light-emitting element, 73: light-receiving element, 100A: display device, 100B: display device, 100C: display device, 100D: display device, 100E: display device, 100F: display device, 100G: display device, 100H: display device, 100I: display device, 100J: display device, 100K: display device, 107: pixel portion, 108: pixel, 117: light-blocking layer, 120: substrate, 122: resin layer, 124a: pixel, 124b: pixel, 140: connection portion, 142: adhesive layer, 151: substrate, 152: substrate, 153: insulating layer, 164: circuit, 165: wiring, 166: conductive layer, 171: conductive layer, 172B: EL layer, 172Bf: EL film, 172G: EL layer, 172Gf: EL film, 172IR: EL layer, 172R: EL layer, 172Rf: EL film, 172W: EL layer, 172: EL layer, 173: conductive layer, 174: common layer, 175B: light, 175G: light, 175IR: light, 175R: light, 175S: light, 176: IC, 177: FPC, 180B: resist mask, 180G: resist mask, 180R: resist mask, 181B: FMM, 181G: FMM, 181R: FMM, 181S: FMM, 181: FMM, 182: PD layer, 183B: coloring layer, 183G: coloring layer, 183R: coloring layer, 183S: coloring layer, 183: coloring layer, 201: transistor, 204: connection portion, 205: transistor, 209: transistor, 210: transistor, 211: insulating layer, 213: insulating layer, 214: insulating layer, 215: insulating layer, 218: insulating layer, 221: conductive layer, 222a: conductive layer, 222b: conductive layer, 223: conductive layer, 225: insulating layer, 231i: channel formation region, 231n: low-resistance region, 231: semiconductor layer, 240: capacitor, 241: conductive layer, 242: connection layer, 243: insulating layer, 245: conductive layer, 251: conductive layer, 252: conductive layer, 254: insulating layer, 255a: insulating layer, 255b: insulating layer, 256: plug, 261: insulating layer, 262: insulating layer, 263: insulating layer, 264: insulating layer, 265: insulating layer, 270B: sacrificial layer, 270Bf: sacrificial film, 270G: sacrificial layer, 270Gf: sacrificial film, 270R: sacrificial layer, 270Rf: sacrificial film, 270: sacrificial layer, 271f: protective film, 271: protective layer, 272: insulating layer, 273: protective layer, 274a: conductive layer, 274b: conductive layer, 274: plug, 275: plug, 276: insulating layer, 277: microlens array, 278f: insulating film, 278: insulating layer, 279B: sacrificial layer, 279Bf: sacrificial film, 279G: sacrificial layer, 279Gf: sacrificial film, 279R: sacrificial layer, 279Rf: sacrificial film, 280: display module, 281: pixel portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 301A: substrate, 301B: substrate, 301: substrate, 310A: transistor, 310B: transistor, 310: transistor, 311: conductive layer, 312: low-resistance region, 313: insulating layer, 314: insulating layer, 315: element isolation layer, 320A: transistor, 320B: transistor, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: adhesive layer, 363: insulating layer, 761: lower electrode, 762: upper electrode, 763a: light-emitting unit, 763b: light-emitting unit, 763c: light-emitting unit, 763: EL layer, 764: layer, 771a: light-emitting layer, 771b: light-emitting layer, 771c: light-emitting layer, 771: light-emitting layer, 772a: light-emitting layer, 772b: light-emitting layer, 772c: light-emitting layer, 772: light-emitting layer, 773: light-emitting layer, 780a: layer, 780b: layer, 780c: layer, 780: layer, 781: layer, 782: layer, 785: charge-generation layer, 790a: layer, 790b: layer, 790c: layer, 790: layer, 791: layer, 792: layer

1. (canceled)

2. An electronic device comprising:
a first pixel portion comprising a plurality of first pixels;
a second pixel portion comprising a first region where a plurality of second pixels are arranged and a second region where a plurality of third pixels are arranged; and
an optical combiner,
wherein the second region is provided to surround the first region,
wherein each of the plurality of first pixels comprises a first light-emitting element,
wherein each of the plurality of second pixels comprises a light-receiving element,
wherein each of the plurality of third pixels comprises a second light-emitting element,
wherein an area occupied by one of the plurality of first pixels is smaller than an area occupied by one of the plurality of third pixels, and
wherein the optical combiner is configured to reflect light emitted from the first light-emitting element and to transmit light emitted from the second light-emitting element.

3. The electronic device according to claim 2,
wherein the optical combiner is a half mirror.

4. The electronic device according to claim 2, further comprising a first lens and a second lens,
wherein the first lens is provided between the first region and the optical combiner, and
wherein the second lens is provided to overlap with the first region and the second region.

5. The electronic device according to claim 4,
wherein the second region comprises a region not overlapping with the first lens.

6. The electronic device according to claim 2, further comprising a communication circuit, a control circuit, a first source driver circuit, and a second source driver circuit,
wherein the first source driver circuit is electrically connected to one of the plurality of first pixels,
wherein the second source driver circuit is electrically connected to one of the plurality of third pixels,
wherein the communication circuit is configured to receive image data, and
wherein the control circuit is configured to generate first data representing luminance of the light emitted from the first light-emitting element and second data representing luminance of the light emitted from the second light-emitting element on the basis of the image data and to supply the first data to the first source driver circuit and the second data to the second source driver circuit.

7. The electronic device according to claim 6, further comprising a column driver circuit,
wherein the column driver circuit is configured to read imaging data obtained by the light-receiving element, and
wherein the control circuit is configured to generate at least one of the first data and the second data on the basis of the imaging data and the image data.

8. The electronic device according to claim 2,
wherein the first light-emitting element comprises a first pixel electrode and a first EL layer over the first pixel electrode,
wherein the first EL layer covers an end portion of the first pixel electrode,
wherein the second light-emitting element comprises a second pixel electrode and a second EL layer over the second pixel electrode,
wherein an insulating layer is provided between the second pixel electrode and the second EL layer, and
wherein the insulating layer covers an end portion of the second pixel electrode.

9. The electronic device according to claim 8,
wherein the light-receiving element comprises a third pixel electrode and a PD layer over the third pixel electrode,
wherein the insulating layer is provided between the third pixel electrode and the PD layer, and
wherein the insulating layer covers an end portion of the third pixel electrode.

10. The electronic device according to claim 2,
wherein each of the plurality of second pixels comprises a third light-emitting element, and
wherein the third light-emitting element is configured to emit infrared light.

11. An electronic device comprising:
a first pixel portion comprising a plurality of first pixels; and
a second pixel portion comprising a first region where a plurality of second pixels are arranged and a second region where a plurality of third pixels are arranged,
wherein the second region is provided to surround the first region,
wherein each of the plurality of first pixels comprises a first light-emitting element,
wherein each of the plurality of second pixels comprises a second light-emitting element configured to emit infrared light,
wherein each of the plurality of third pixels comprises a third light-emitting element and a first light-receiving element, and
wherein an area occupied by one of the plurality of first pixels is smaller than an area occupied by one of the plurality of third pixels.

12. The electronic device according to claim 11, further comprising an optical combiner,
wherein the optical combiner is configured to reflect light emitted from the first light-emitting element and to transmit light emitted from the second light-emitting element and light emitted from the third light-emitting element.

13. The electronic device according to claim 12,
wherein the optical combiner is a half mirror.

14. The electronic device according to claim 11, further comprising a communication circuit, a control circuit, a first source driver circuit, and a second source driver circuit,
wherein the first source driver circuit is electrically connected to one of the plurality of first pixels,
wherein the second source driver circuit is electrically connected to one of the plurality of third pixels,
wherein the communication circuit is configured to receive image data,
wherein the control circuit is configured to generate first data representing luminance of the light emitted from the first light-emitting element, second data representing luminance of the light emitted from the second light-emitting element, and third data representing luminance of the light emitted from the third light-emitting element,
wherein the first data and the third data are generated on the basis of the image data, and
wherein the control circuit is configured to supply the first data to the first source driver circuit and the second data and the third data to the second source driver circuit.

15. The electronic device according to claim 14, further comprising a column driver circuit,
wherein the column driver circuit is configured to read imaging data obtained by the first light-receiving element, and
wherein the control circuit is configured to generate at least one of the first data and the third data on the basis of the imaging data and the image data.

16. The electronic device according to claim 11,
wherein the first light-emitting element comprises a first pixel electrode and a first EL layer over the first pixel electrode,
wherein the first EL layer covers an end portion of the first pixel electrode,
wherein the second light-emitting element comprises a second pixel electrode and a second EL layer over the second pixel electrode,
wherein the third light-emitting element comprises a third pixel electrode and a third EL layer over the third pixel electrode,
wherein an insulating layer is provided between the second pixel electrode and the second EL layer and between the third pixel electrode and the third EL layer, and
wherein the insulating layer covers an end portion of the second pixel electrode and an end portion of the third pixel electrode.

17. The electronic device according to claim 16,
wherein the first light-receiving element comprises a fourth pixel electrode and a PD layer over the fourth pixel electrode,
wherein the insulating layer is provided between the fourth pixel electrode and the PD layer, and
wherein the insulating layer covers an end portion of the fourth pixel electrode.

18. The electronic device according to claim 11,
wherein each of the plurality of second pixels comprises a second light-receiving element.
